(19) United States
(12) Patent Application Publication
(10) Pub. No.: US 2026/0362962 A1
(43) Pub. Date: Nov. 12, 2026

(54) Light-Emitting Substrate and Method for Manufacturing the Same, and Light-Emitting Apparatus

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Shaoyong Lu, Beijing (CN); Zhuo Chen, Beijing (CN); Zhuo Li, Beijing (CN); Xu Yuan, Beijing (CN); Yichi Zhang, Beijing (CN)

(21) Appl. No.: 19/113,616

(22) PCT Filed: May 31, 2024
(86) PCT No.: PCT/CN2024/096800

§ 371 Date: Mar. 20, 2025

(30) Foreign Application Priority Data
Jun. 25, 2023 (CN) 202310754262.6

(51) Int. Cl. H10K 85/10; C09K 11/02; C09K 11/88; H10K 50/115; H10K 50/16; H10K 59/122; H10K 85/30

(52) U.S. Cl. CPC H10K 85/1135; C09K 11/025; C09K 11/883; H10K 85/151; H10K 85/361; H10K 85/381; H10K 50/115; H10K 50/16; H10K 59/122

(57) ABSTRACT

A light-emitting substrate includes a substrate and a plurality of light-emitting devices. Each of the plurality of light-emitting devices includes a first electrode, a second electrode, and a light-emitting pattern. The plurality of light-emitting devices include at least one first light-emitting device. Each first light-emitting device includes a first light-emitting pattern, and a first carrier transport layer and a first carrier injection layer that are arranged between the substrate and the first light-emitting pattern. The material of the first light-emitting pattern includes a first cross-linked light-emitting material. The material of the first carrier transport layer includes a first cross-linked carrier transport material. The material of the first carrier injection layer includes a first cross-linked carrier injection material.

### CROSS-REFERENCE TO RELATED APPLICATIONS

This application is the United States national phase of International Patent Application No. PCT/CN2024/096800, filed May 31, 2024, and claims priority to Chinese Patent Application No. 202310754262.6, filed Jun. 25, 2023, the disclosures of which are hereby incorporated by reference in their entireties.

### BACKGROUND OF THE INVENTION

### Field of the Invention

The present disclosure relates to the field of display technologies, and in particular, to a light-emitting substrate and a method for manufacturing the same, and a light-emitting apparatus.

### Description of Related Art

As a new type of light-emitting material, quantum dots (QD) have high light color purity, high luminous quantum efficiency, adjustable luminous color, long service life and other advantages, and have become a research hotspot for a new light-emitting diode (LED) light-emitting material currently. Therefore, quantum dot light-emitting diodes (QLED) with the quantum dot materials as light-emitting layers have become a main direction of research for new display devices.

### SUMMARY OF THE INVENTION

In an aspect, a light-emitting substrate is provided. The light-emitting substrate includes a substrate and a plurality of light-emitting devices. The plurality of light-emitting devices are disposed on the substrate and arranged in a first direction, and the first direction is parallel to a plane where the substrate is located. Each light-emitting device in the plurality of light-emitting devices includes a first electrode, a second electrode, and a light-emitting pattern disposed between the first electrode and the second electrode. The plurality of light-emitting devices include at least one first light-emitting device, and each first light-emitting device in the at least one first light-emitting device includes a first light-emitting pattern, and a first carrier transport layer and a first carrier injection layer that are disposed between the substrate and the first light-emitting pattern. The first carrier transport layer is closer to the first light-emitting pattern than the first carrier injection layer. A material of the first light-emitting pattern includes a first cross-linked light-emitting material; a material of the first carrier transport layer includes a first cross-linked carrier transport material; and a material of the first carrier injection layer includes a first cross-linked carrier injection material.

In some embodiments, the plurality of light-emitting devices further include at least one second light-emitting device. Each second light-emitting device in the at least one second light-emitting device includes a second light-emitting pattern, and a second sacrificial layer group disposed between the substrate and the second light-emitting pattern. The second sacrificial layer group includes a second carrier transport layer. A material of the second light-emitting pattern includes a second cross-linked light-emitting material; and a material of the second carrier transport layer includes a second cross-linked carrier transport material.

In some embodiments, the second sacrificial layer group further includes a second carrier injection layer. The second carrier injection layer is located on a side of the second carrier transport layer proximate to the substrate, and a material of the second carrier injection layer includes a second cross-linked carrier injection material.

In some embodiments, the plurality of light-emitting devices further include at least one third light-emitting device. Each third light-emitting device in the at least one third light-emitting device includes a third light-emitting pattern, and a third sacrificial layer group disposed between the substrate and the third light-emitting pattern. The third sacrificial layer group includes a third carrier transport layer. A material of the third light-emitting pattern includes a third cross-linked light-emitting material; and a material of the third carrier transport layer includes a third cross-linked carrier transport material.

In some embodiments, the third sacrificial layer group further includes a third carrier injection layer. The third carrier injection layer is located on a side of the third carrier transport layer proximate to the substrate, and a material of the third carrier injection layer includes a third cross-linked carrier injection material.

In some embodiments, the first cross-linked light-emitting material is generated by cross-linking of a first quantum dot material under light radiation, and a solubility of the first quantum dot material in a first solvent is greater than a solubility of the first cross-linked light-emitting material in the first solvent. Alternatively, the first cross-linked light-emitting material is generated by cross-linking of a first quantum dot material and a first photosensitive material under light radiation, and solubilities of the first quantum dot material and the first photosensitive material in a first solvent are greater than a solubility of the first cross-linked light-emitting material in the first solvent.

The first cross-linked carrier transport material is generated by cross-linking of a first carrier transport material under light radiation, and a solubility of the first carrier transport material in a second solvent is greater than a solubility of the first cross-linked carrier transport material in the second solvent. Alternatively, the first cross-linked carrier transport material is generated by cross-linking of a first carrier transport material and a second photosensitive material under light radiation, and solubilities of the first carrier transport material and the second photosensitive material in a second solvent are greater than a solubility of the first cross-linked carrier transport material in the second solvent.

The first cross-linked carrier injection material is generated by cross-linking of a first carrier injection material under light radiation, and a solubility of the first carrier injection material in a third solvent is greater than a solubility of the first cross-linked carrier injection material in the third solvent. Alternatively, the first cross-linked carrier injection material is generated by cross-linking of a first carrier injection material and a third photosensitive material under light radiation, and solubilities of the first carrier injection material and the third photosensitive material in a third solvent are greater than a solubility of the first cross-linked carrier injection material in the third solvent.

In some embodiments, the second cross-linked light-emitting material is generated by cross-linking of a second quantum dot material under light radiation, and a solubility of the second quantum dot material in a fourth solvent is greater than a solubility of the second cross-linked light-emitting material in the fourth solvent. Alternatively, the second cross-linked light-emitting material is generated by cross-linking of a second quantum dot material and a fourth photosensitive material under light radiation, and solubilities of the second quantum dot material and the fourth photosensitive material in a fourth solvent are greater than a solubility of the second cross-linked light-emitting material in the fourth solvent.

The second cross-linked carrier transport material is generated by cross-linking of a second carrier transport material under light radiation, and a solubility of the second carrier transport material in a fifth solvent is greater than a solubility of the second cross-linked carrier transport material in the fifth solvent. Alternatively, the second cross-linked carrier transport material is generated by cross-linking of a second carrier transport material and a fifth photosensitive material under light radiation, and solubilities of the second carrier transport material and the fifth photosensitive material in a fifth solvent are greater than a solubility of the second cross-linked carrier transport material in the fifth solvent.

In some embodiments, the second cross-linked carrier injection material is generated by cross-linking of a second carrier injection material under light radiation, and a solubility of the second carrier injection material in a sixth solvent is greater than a solubility of the second cross-linked carrier injection material in the sixth solvent. Alternatively, the second cross-linked carrier injection material is generated by cross-linking of a second carrier injection material and a sixth photosensitive material under light radiation, and solubilities of the second carrier injection material and the sixth photosensitive material in a sixth solvent are greater than a solubility of the second cross-linked carrier injection material in the sixth solvent.

In some embodiments, the third cross-linked light-emitting material is generated by cross-linking of a third quantum dot material under light radiation, and a solubility of the third quantum dot material in a seventh solvent is greater than a solubility of the third cross-linked light-emitting material in the seventh solvent. Alternatively, the third cross-linked light-emitting material is generated by cross-linking of a third quantum dot material and a seventh photosensitive material under light radiation, and solubilities of the third quantum dot material and the seventh photosensitive material in a seventh solvent are greater than a solubility of the third cross-linked light-emitting material in the seventh solvent.

The third cross-linked carrier transport material is generated by cross-linking of a third carrier transport material under light radiation, and a solubility of the third carrier transport material in an eighth solvent is greater than a solubility of the third cross-linked carrier transport material in the eighth solvent. Alternatively, the third cross-linked carrier transport material is generated by cross-linking of a third carrier transport material and an eighth photosensitive material under light radiation, and solubilities of the third carrier transport material and the eighth photosensitive material in an eighth solvent are greater than a solubility of the third cross-linked carrier transport material in the eighth solvent.

In some embodiments, the third cross-linked carrier injection material is generated by cross-linking of a third carrier injection material under light radiation, and a solubility of the third carrier injection material in a ninth solvent is greater than a solubility of the third cross-linked carrier injection material in the ninth solvent. Alternatively, the third cross-linked carrier injection material is generated by cross-linking of a third carrier injection material and a ninth photosensitive material under light radiation, and solubilities of the third carrier injection material and the ninth photosensitive material in a ninth solvent are greater than a solubility of the third cross-linked carrier injection material in the ninth solvent.

In some embodiments, the at least one first light-emitting device is configured to emit light of a first wavelength. Each first light-emitting device in the at least one first light-emitting device further includes a first pattern layer and a second pattern layer. The first pattern layer is disposed on a side of the first light-emitting pattern away from the substrate, the second pattern layer is disposed on a side of the first pattern layer away from the substrate, and the first light-emitting pattern, the first pattern layer and the second pattern layer are in contact in sequence.

In some embodiments, in a case where the second sacrificial layer group includes the second carrier transport layer, a thickness of the first pattern layer is less than a thickness of the second carrier transport layer. In a case where the second cross-linked carrier transport material is generated by cross-linking of a second carrier transport material under light radiation, a material of the first pattern layer includes the second carrier transport material. Alternatively, in a case where the second cross-linked carrier transport material is generated by cross-linking of a second carrier transport material and a fifth photosensitive material under light radiation, a material of the first pattern layer includes the second carrier transport material and the fifth photosensitive material.

Alternatively, in a case where the second sacrificial layer group includes the second carrier transport layer and the second carrier injection layer, a thickness of the first pattern layer is less than a thickness of the second carrier injection layer. In a case where the second cross-linked carrier injection material is generated by cross-linking of a second carrier injection material under light radiation, a material of the first pattern layer includes the second carrier injection material. Alternatively, in a case where the second cross-linked carrier injection material is generated by cross-linking of a second carrier injection material and a sixth photosensitive material under light radiation, a material of the first pattern layer includes the second carrier injection material and the sixth photosensitive material.

In some embodiments, in a case where the third sacrificial layer group includes the third carrier transport layer, a thickness of the second pattern layer is less than a thickness of the third carrier transport layer. In a case where the third cross-linked carrier transport material is generated by cross-linking of a third carrier transport material under light radiation, a material of the second pattern layer includes the third carrier transport material. Alternatively, in a case where the third cross-linked carrier transport material is generated by cross-linking of a third carrier transport material and an eighth photosensitive material under light radiation, a material of the second pattern layer includes the third carrier transport material and the eighth photosensitive material.

Alternatively, in a case where the third sacrificial layer group includes the third carrier transport layer and the third carrier injection layer, a thickness of the second pattern layer is less than a thickness of the third carrier injection layer. In a case where the third cross-linked carrier injection material is generated by cross-linking of a third carrier injection material under light radiation, a material of the second pattern layer includes the third carrier injection material. Alternatively, in a case where the third cross-linked carrier injection material is generated by cross-linking of a third carrier injection material and a ninth photosensitive material under light radiation, a material of the second pattern layer includes the third carrier injection material and the ninth photosensitive material.

In some embodiments, the at least one second light-emitting device is configured to emit light of a second wavelength. Each second light-emitting device in the at least one second light-emitting device further includes a third pattern layer and a fourth pattern layer, the third pattern layer is disposed on a side of the second sacrificial layer group proximate to the substrate, the fourth pattern layer is disposed on a side of the second light-emitting pattern away from the substrate, and the third pattern layer, the second sacrificial layer group, the second light-emitting pattern and the fourth pattern layer are in contact in sequence.

In some embodiments, a thickness of the third pattern layer is less than a thickness of the first carrier injection layer; and a material of the third pattern layer includes the first cross-linked carrier injection material.

In a case where the third sacrificial layer group includes the third carrier transport layer, a thickness of the fourth pattern layer is less than a thickness of the third carrier transport layer. In a case where the third cross-linked carrier transport material is generated by cross-linking of a third carrier transport material under light radiation, a material of the fourth pattern layer includes the third carrier transport material. Alternatively, in a case where the third cross-linked carrier transport material is generated by cross-linking of a third carrier transport material and an eighth photosensitive material under light radiation, a material of the fourth pattern layer includes the third carrier transport material and the eighth photosensitive material.

Alternatively, in a case where the third sacrificial layer group includes the third carrier transport layer and the third carrier injection layer, a thickness of the fourth pattern layer is less than a thickness of the third carrier injection layer. In a case where the third cross-linked carrier injection material is generated by cross-linking of a third carrier injection material under light radiation, a material of the fourth pattern layer includes the third carrier injection material. Alternatively, in a case where the third cross-linked carrier injection material is generated by cross-linking of a third carrier injection material and a ninth photosensitive material under light radiation, a material of the fourth pattern layer includes the third carrier injection material and the ninth photosensitive material.

In some embodiments, the at least one third light-emitting device is configured to emit light of a third wavelength. Each third light-emitting device in the at least one third light-emitting device further includes a fifth pattern layer and a sixth pattern layer, the sixth pattern layer is disposed on a side of the third sacrificial layer group proximate to the substrate, the fifth pattern layer is disposed on a side of the sixth pattern layer proximate to the substrate, and the third sacrificial layer group, the sixth pattern layer and the fifth pattern layer are in contact in sequence.

In some embodiments, a thickness of the fifth pattern layer is less than a thickness of the first carrier injection layer; and a material of the fifth pattern layer includes the first cross-linked carrier injection material. In a case where the second sacrificial layer group includes the second carrier transport layer, a thickness of the sixth pattern layer is less than a thickness of the second carrier transport layer; and a material of the sixth pattern layer includes the second cross-linked carrier transport material. Alternatively, in a case where the second sacrificial layer group includes the second carrier transport layer and the second carrier injection layer, a thickness of the sixth pattern layer is less than a thickness of the second carrier injection layer; and a material of the sixth pattern layer includes the second cross-linked carrier injection material.

In some embodiments, the at least one first light-emitting device is configured to emit light of a first wavelength, and the light of the first wavelength is red light. The at least one second light-emitting device is configured to emit light of a second wavelength, and the light of the second wavelength is green light. The at least one third light-emitting device is configured to emit light of a third wavelength, and the light of the third wavelength is blue light.

In some embodiments, the light-emitting substrate further includes a pixel defining layer, the pixel defining layer is provided with a plurality of openings therein, and the plurality of light-emitting devices are disposed in the plurality of openings in one-to-one correspondence. The light-emitting substrate further includes a seventh pattern layer, an eighth pattern layer and a ninth pattern layer that are disposed on a side of the pixel defining layer away from the substrate. The seventh pattern layer, the eighth pattern layer and the ninth pattern layer are disposed sequentially in a direction from the substrate to the pixel defining layer, and the seventh pattern layer, the eighth pattern layer and the ninth pattern layer are in contact in sequence.

In some embodiments, a thickness of the seventh pattern layer is less than a thickness of the first carrier injection layer. In a case where the first cross-linked carrier injection material is generated by cross-linking of a first carrier injection material under light radiation, a material of the seventh pattern layer includes the first carrier injection material. Alternatively, in a case where the first cross-linked carrier injection material is generated by cross-linking of a first carrier injection material and a third photosensitive material under light radiation, a material of the seventh pattern layer includes the first carrier injection material and the third photosensitive material.

In a case where the second sacrificial layer group includes the second carrier transport layer, a thickness of the eighth pattern layer is less than a thickness of the second carrier transport layer. In a case where the second cross-linked carrier transport material is generated by cross-linking of a second carrier transport material under light radiation, a material of the eighth pattern layer includes the second carrier transport material. Alternatively, in a case where the second cross-linked carrier transport material is generated by cross-linking of a second carrier transport material and a fifth photosensitive material under light radiation, a material of the eighth pattern layer includes the second carrier transport material and the fifth photosensitive material.

Alternatively, in a case where the second sacrificial layer group includes the second carrier transport layer and a second carrier injection layer, a thickness of the eighth pattern layer is less than a thickness of the second carrier injection layer. In a case where a second cross-linked carrier injection material is generated by cross-linking of a second carrier injection material under light radiation, a material of the eighth pattern layer includes the second carrier injection material. Alternatively, in a case where a second cross-linked carrier injection material is generated by cross-linking of a second carrier injection material and a sixth photosensitive material under light radiation, a material of the eighth pattern layer includes the second carrier injection material and the sixth photosensitive material.

In some embodiments, in a case where the third sacrificial layer group includes the third carrier transport layer, a thickness of the ninth pattern layer is less than a thickness of the third carrier transport layer. In a case where the third cross-linked carrier transport material is generated by cross-linking of a third carrier transport material under light radiation, a material of the ninth pattern layer includes the third carrier transport material. Alternatively, in a case where the third cross-linked carrier transport material is generated by cross-linking of a third carrier transport material and an eighth photosensitive material under light radiation, a material of the ninth pattern layer includes the third carrier transport material and the eighth photosensitive material.

Alternatively, in a case where the third sacrificial layer group includes the third carrier transport layer and a third carrier injection layer, a thickness of the ninth pattern layer is less than a thickness of the third carrier injection layer. In a case where a third cross-linked carrier injection material is generated by cross-linking of a third carrier injection material under light radiation, a material of the ninth pattern layer includes the third carrier injection material. Alternatively, in a case where a third cross-linked carrier injection material is generated by cross-linking of a third carrier injection material and a ninth photosensitive material under light radiation, a material of the ninth pattern layer includes the third carrier injection material and the ninth photosensitive material.

In some embodiments, any of the first cross-linked light-emitting material, the second cross-linked light-emitting material and the third cross-linked light-emitting material includes any of structures shown in a following general formula (I-A).

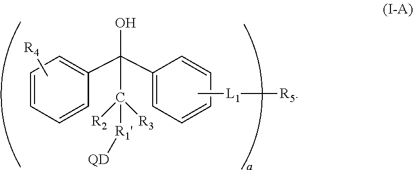

Alternatively, any of the first cross-linked light-emitting material, the second cross-linked light-emitting material and the third cross-linked light-emitting material includes any of structures shown in a following general formula (I-B).

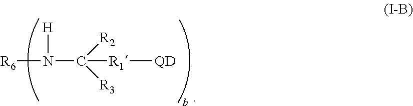

Alternatively, any of the first cross-linked light-emitting material, the second cross-linked light-emitting material and the third cross-linked light-emitting material includes any of structures shown in a following general formula (I-C).

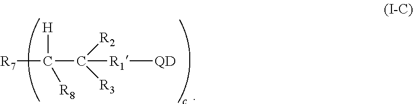

Here, L₁ is selected from any of a single bond, an ester bond, an ether bond and a thioether bond. R₂, R₃, R₄, R₅, R₆, R₇ and R₈ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40. QD represents any of quantum dot bodies, and the quantum dot bodies each include any of a II-VI group quantum dot, a III-V group quantum dot, a IV-VI group quantum dot, a quantum dot with core-shell structure and an ABX₃ type perovskite quantum dot. In the ABX₃ type perovskite quantum dot, A is one or more of CH₃NH₃⁺ (methylamine), NH₂CH═NH₂ (formamidine) and Cs⁺, B is one or two of Pb²⁺ and Sn²⁺, and X is one or more of Cl⁻, Br⁻ and I⁻; and the ABX₃ type perovskite quantum dot includes CH₃NH₃PbBr₃, CH₃NH₃PbCl₃, CH₃NH₃PbI₃, CsPbBr₃, CsPbCl₃ and CsPbI₃. R1′ is selected from a remaining structure of R₁ with one hydrogen removed from any of a carboxyl group, an amino group and a sulfhydryl group; R₁ is selected from any of a C1 to C40 carbon chain with a carboxyl group, a C1 to C40 carbon chain with an amino group, and a C1 to C40 carbon chain with a sulfhydryl group; and any of the carboxyl group, the amino group and the sulfhydryl group is connected to a quantum dot body by coordination; and a, b and c are each independently selected from positive integers greater than or equal to 2.

In some embodiments, any of the first cross-linked carrier transport material, the second cross-linked carrier transport material and the third cross-linked carrier transport material includes any of structures shown in a following general formula (II-A).

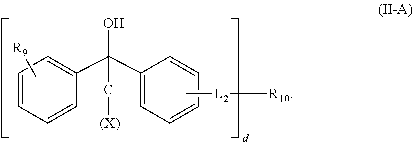

Alternatively, any of the first cross-linked carrier transport material, the second cross-linked carrier transport material and the third cross-linked carrier transport material includes any of structures shown in a following general formula (II-B).

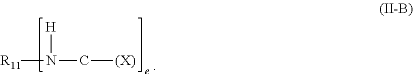

Alternatively, any of the first cross-linked carrier transport material, the second cross-linked carrier transport material and the third cross-linked carrier transport material includes any of structures shown in a following general formula (II-C).

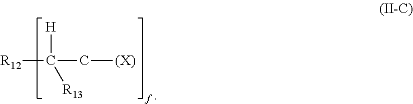

Here, L₂ is selected from any of a single bond, an ester bond, an ether bond and a thioether bond. R₉, R₁₀, R₁₁, R₁₂ and R₁₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40. X represents a remaining structure of any of a first carrier transport material, a second carrier transport material and a third carrier transport material with a C—H bond removed; the C—H bond is used to undergo a cross-linking reaction with a second photosensitive group of a second type of photosensitive material under light radiation, the second type of photosensitive material is one of a second photosensitive material, a fifth photosensitive material and an eighth photosensitive material; and d, e and f are each independently selected from positive integers greater than or equal to 2.

In some embodiments, any of the first cross-linked carrier injection material, the second cross-linked carrier injection material and the third cross-linked carrier injection material includes any of structures shown in a following general formula (III-A).

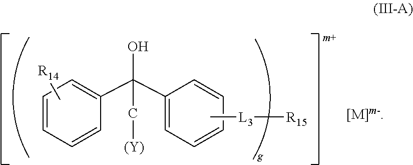

Alternatively, any of the first cross-linked carrier injection material, the second cross-linked carrier injection material and the third cross-linked carrier injection material includes any of structures shown in a following general formula (III-B).

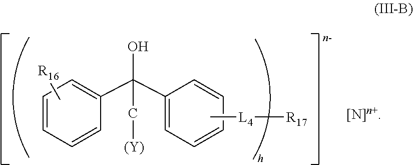

Alternatively, any of the first cross-linked carrier injection material, the second cross-linked carrier injection material and the third cross-linked carrier injection material includes any of structures shown in a following general formula (III-C).

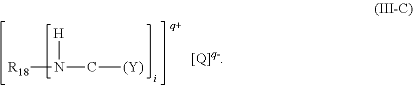

Alternatively, any of the first cross-linked carrier injection material, the second cross-linked carrier injection material and the third cross-linked carrier injection material includes any of structures shown in a following general formula (III-D).

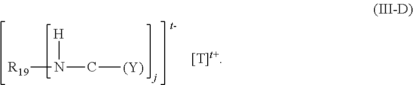

Alternatively, any of the first cross-linked carrier injection material, the second cross-linked carrier injection material and the third cross-linked carrier injection material includes any of structures shown in a following general formula (III-E).

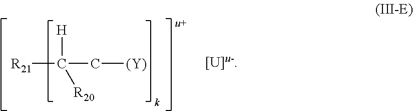

Alternatively, any of the first cross-linked carrier injection material, the second cross-linked carrier injection material and the third cross-linked carrier injection material includes any of structures shown in a following general formula (III-F).

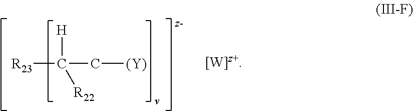

Here, L₃ and L₄ are each independently selected from any of a single bond, an ester bond, an ether bond and a thioether bond. R₁₄, R₁₅, R₁₆, R₁₇, R₁₈, R₁₉, R₂₀, R₂₁, R₂₂ and R₂₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40. Y represents a remaining structure of any of a first carrier injection material, a second carrier injection material and a third carrier injection material with a C—H bond removed; the C—H bond is used to undergo a cross-linking reaction with a third photosensitive group of a third type of photosensitive material under light radiation, and the third type of photosensitive material is one of a third photosensitive material, a sixth photosensitive material and a ninth photosensitive material. [M]^{m-}, [Q]^{q-} and [U]^{u-} are each independently selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions. [N]ⁿ⁺, [T]^{t+} and [W]^{z+} are each independently selected from any of organic cations and inorganic cations; the organic cations include methylammonium ions; and the inorganic cations include sodium ions and potassium ions. g, h, i, j, k and v are each independently selected from positive integers greater than or equal to 2; and m, n, q, t, u and z are each independently selected from positive integers greater than or equal to 1.

In some embodiments, a first photosensitive material, a fourth photosensitive material and a seventh photosensitive material are each independently selected from any of first type of photosensitive materials; a first type of photosensitive material includes a first photosensitive group, the first photosensitive group undergoes a cross-linking reaction with a quantum dot material under light radiation; and the quantum dot material is one of a first quantum dot material, a second quantum dot material and a third quantum dot material. A second photosensitive material, a fifth photosensitive material and a eighth photosensitive material are each independently selected from any of second type of photosensitive materials; a second type of photosensitive material includes a second photosensitive group, the second photosensitive group undergoes a cross-linking reaction with a carrier transport material under light radiation; and the carrier transport material is one of a first carrier transport material, a second carrier transport material and a third carrier transport material. A third photosensitive material, a sixth photosensitive material and a ninth photosensitive material are each independently selected from any of third type of photosensitive materials; a third type of photosensitive material includes a third photosensitive group, the third photosensitive group undergoes a cross-linking reaction with a carrier injection material under light radiation; and the carrier injection material is one of a first carrier injection material, a second carrier injection material and a third carrier injection material. Any two of the first photosensitive group, the second photosensitive group and the third photosensitive group are same or different.

In some embodiments, under ultraviolet light with a wavelength ranging from 200 nm to 400 nm, a molar extinction coefficient of the third type of photosensitive material is greater than 1 cm⁻¹ (mol/L)⁻¹.

In some embodiments, the first type of photosensitive material is selected from any of structures shown in a following general formula (IV-A).

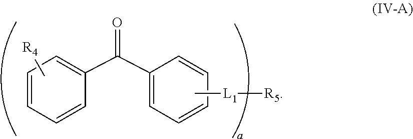

Alternatively, the first type of photosensitive material is selected from any of structures shown in a following general formula (IV-B).

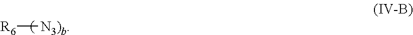

Alternatively, the first type of photosensitive material is selected from any of structures shown in a following general formula.

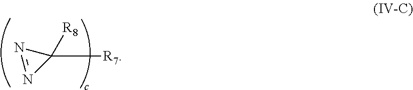

Here, in the general formula (IV-A), a benzophenone group is the first photosensitive group; in the general formula (IV-B), an azide group is the first photosensitive group; and in the general formula (IV-C), a diazirine group is the first photosensitive group. L₁ is selected from any of a single bond, an ester bond, an ether bond and a thioether bond. R₂, R₃, R₄, R₅, R₆, R₇ and R₈ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40. a, b and c are each independently selected from positive integers greater than or equal to 2.

In some embodiments, the second type of photosensitive material is selected from any of structures shown in a following general formula (V-A).

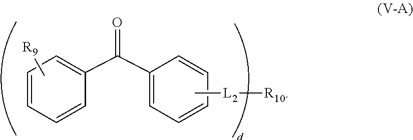

Alternatively, the second type of photosensitive material is selected from any of structures shown in a following general formula (V-B).

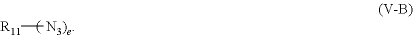

Alternatively, the second type of photosensitive material is selected from any of structures shown in a following general formula (V-C).

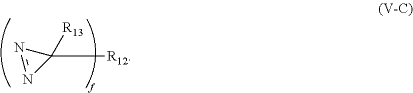

Here, in the general formula (V-A), a benzophenone group is the second photosensitive group; in the general formula (V-B), an azide group is the second photosensitive group; in the general formula (V-C), a diazirine group is the second photosensitive group. L₂ is selected from any of a single bond, an ester bond, an ether bond and a thioether bond. R₉, R₁₀, R₁₁, R₁₂ and R₁₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40. d, e and f are each independently selected from positive integers greater than or equal to 2.

In some embodiments, the third type of photosensitive material is selected from any of structures shown in a following general formula (VI-A).

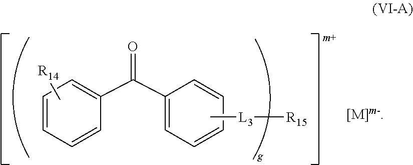

Alternatively, the third type of photosensitive material is selected from any of structures shown in a following general formula (VI-B).

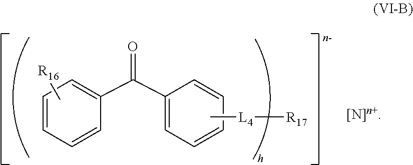

Alternatively, the third type of photosensitive material is selected from any of structures shown in a following general formula (VI-C).

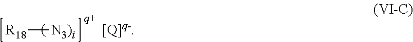

Alternatively, the third type of photosensitive material is selected from any of structures shown in a following general formula (VI-D).

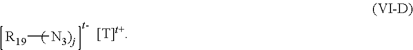

Alternatively, the third type of photosensitive material is selected from any of structures shown in a following general formula (VI-E).

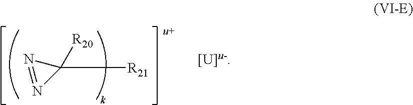

Alternatively, the third type of photosensitive material is selected from any of structures shown in a following general formula (VI-F).

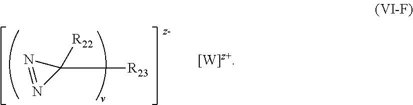

Here, in the general formula (VI-A) and the general formula (VI-B), a benzophenone group is the third photosensitive group; in the general formula (VI-C) and the general formula (VI-D), an azide group is the third photosensitive group; in the general formula (VI-E) and the general formula (VI-F), a diazirine group is the third photosensitive group. L₃ and L₄ are each independently selected from any of a single bond, an ester bond, an ether bond and a thioether bond. R₁₄, R₁₅, R₁₆, R₁₇, R₁₈, R₁₉, R₂₀, R₂₁, R₂₂ and R₂₃ are are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40. [M]^{m-}, [Q]^{q-} and [U]^{u-} are each independently selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions. [N]ⁿ⁺, [T]^{t+} and [W]^{z+} are each independently selected from any of organic cations and inorganic cations; the organic cations include methylammonium ions; and the inorganic cations include sodium ions and potassium ions. g, h, i, j, k and v are each independently selected from positive integers greater than or equal to 2; and m, n, q, t, u and z are each independently selected from positive integers greater than or equal to 1.

In some embodiments, R₅, R₆ and R₇ are each independently selected from any of a C1 to C30 saturated or unsaturated straight or branched alkyl group, a C1 to C30 saturated or unsaturated straight or branched alkyl group in which at least one hydrogen atom is replaced by a fluorine atom, and a C10 to C30 saturated or unsaturated straight or branched alkyl group containing at least one ether bond. And/or, R₁₀, R₁₁ and R₁₂ are each independently selected from C1 to C8 saturated or unsaturated straight or branched alkyl groups. And/or, R₁₅, R₁₇, R₁₈, R₁₉, R₂₁ and R₂₃ are each independently selected from any of a C1 to C40 carbon chain containing an ester bond, a C1 to C40 carbon chain containing an ether bond, a C1 to C40 carbon chain containing a carbonyl group, a C1 to C40 carbon chain containing an acylamino group, a C1 to C40 carbon chain containing a carboxyl group, a C1 to C40 carbon chain containing an amino group and a C1 to C40 carbon chain containing an aldehyde group.

In some embodiments, any of the first quantum dot material, the second quantum dot material and the third quantum dot material includes a quantum dot body and a first ligand material coordinated on the quantum dot body; the first ligand material contains a carbon-hydrogen insertion group ZH; and the carbon-hydrogen insertion group ZH is configured to undergo a carbon-hydrogen insertion reaction with the first photosensitive group under light radiation. And/or, any of the first carrier transport material, the second carrier transport material and the third carrier transport material includes a carbon-hydrogen insertion group ZH; and the carbon-hydrogen insertion group ZH is configured to undergo a carbon-hydrogen insertion reaction with the second photosensitive group under light radiation. And/or, any of the first carrier injection material, the second carrier injection material and the third carrier injection material includes a carbon-hydrogen insertion group ZH; and the carbon-hydrogen insertion group ZH is configured to undergo a carbon-hydrogen insertion reaction with the third photosensitive group under light radiation. In the carbon-hydrogen insertion group ZH, Z is any of primary carbon, secondary carbon and tertiary carbon.

In some embodiments, a polarity of a third solvent is greater than a polarity of a second solvent, and the polarity of the second solvent is greater than a polarity of a first solvent. And/or, a polarity of a sixth solvent is greater than a polarity of a fifth solvent, and the polarity of the fifth solvent is greater than a polarity of a fourth solvent. And/or, a polarity of a ninth solvent is greater than a polarity of an eighth solvent; and the polarity of the eighth solvent is greater than a polarity of a seventh solvent.

In some embodiments, a first-type solvent is at least one of octane and propylene glycol methyl ether acetate; and the first-type solvent is any of a first solvent, a fourth solvent and a seventh solvent. And/or, a second-type solvent is at least one of toluene, chlorobenzene and (dichloromethyl)benzene; and the second-type solvent is any of a second solvent, a fifth solvent and an eighth solvent. And/or, a third-type solvent is at least one of water, ethanol, methanol, N,N-dimethylformamide, N-methylformamide and thionyl chloride; and the third-type solvent is any of a third solvent, a sixth solvent and a ninth solvent.

In some embodiments, the first carrier injection layer, the second carrier injection layer and the third carrier injection layer are hole injection layers; and the first carrier transport layer, the second carrier transport layer and the third carrier transport layer are hole transport layers.

In another aspect, a method for manufacturing a light-emitting substrate is provided. The manufacturing method includes: forming a plurality of light-emitting devices on a substrate. The plurality of light-emitting devices are arranged in a first direction, and the first direction is parallel to a plane where the substrate is located. Each light-emitting device in the plurality of light-emitting devices includes a first electrode, a second electrode, and a light-emitting pattern disposed between the first electrode and the second electrode. The plurality of light-emitting devices include at least one first light-emitting device, and each first light-emitting device in the at least one first light-emitting device includes a first light-emitting pattern, and a first carrier transport layer and a first carrier injection layer that are disposed between the substrate and the first light-emitting pattern. The first carrier transport layer is closer to the first light-emitting pattern than the first carrier injection layer. A material of the first light-emitting pattern includes a first cross-linked light-emitting material; a material of the first carrier transport layer includes a first cross-linked carrier transport material; and a material of the first carrier injection layer includes a first cross-linked carrier injection material.

In some embodiments, forming the at least one first light-emitting device, includes: forming a first electrode layer on the substrate, the first electrode layer including a first electrode of at least one first light-emitting device; forming a first initial carrier injection layer, a first initial carrier transport layer and a first initial light-emitting pattern sequentially on a side of the first electrode layer away from the substrate, wherein a material of the first initial carrier injection layer includes a first carrier injection material, or includes a first carrier injection material and a third photosensitive material, a material of the first initial carrier transport layer includes a first carrier transport material, or includes a first carrier transport material and a second photosensitive material, and a material of the first initial light-emitting pattern includes a first quantum dot material, or includes a first quantum dot material and a first photosensitive material; exposing the first initial carrier injection layer, the first initial carrier transport layer and the first initial light-emitting pattern that are stacked to convert a material of an exposed portion of the first initial carrier injection layer into the first cross-linked carrier injection material, convert a material of an exposed portion of the first initial carrier transport layer into the first cross-linked carrier transport material, and convert a material of an exposed portion of the first initial light-emitting pattern into the first cross-linked light-emitting material; and developing the first initial carrier injection layer, the first initial carrier transport layer and the first initial light-emitting pattern that are stacked to form the first carrier injection layer, the first carrier transport layer and the first light-emitting pattern that are stacked.

In some embodiments, forming the at least one first light-emitting device, includes: forming a first electrode layer on the substrate, the first electrode layer including a first electrode of at least one first light-emitting device; forming a first initial carrier injection layer on a side of the first electrode layer away from the substrate, a material of the first initial carrier injection layer including a first carrier injection material, or including a first carrier injection material and a third photosensitive material; exposing the first initial carrier injection layer to convert a material of an exposed portion of the first initial carrier injection layer into the first cross-linked carrier injection material; forming a first initial carrier transport layer and a first initial light-emitting pattern sequentially on a side of the first initial carrier injection layer away from the substrate, wherein a material of the first initial carrier transport layer includes a first carrier transport material, or includes a first carrier transport material and a second photosensitive material, and a material of the first initial light-emitting pattern includes a first quantum dot material, or includes a first quantum dot material and a first photosensitive material; exposing the first initial carrier transport layer and the first initial light-emitting pattern that are stacked to convert a material of an exposed portion of the first initial carrier transport layer into the first cross-linked carrier transport material, and convert a material of an exposed portion of the first initial light-emitting pattern into the first cross-linked light-emitting material; and developing the first initial carrier injection layer, the first initial carrier transport layer and the first initial light-emitting pattern that are stacked to form the first carrier injection layer, the first carrier transport layer and the first light-emitting pattern that are stacked.

In some embodiments, the manufacturing method is used to form the light-emitting device (e.g., used to manufacturing the light-emitting substrate as shown in FIG. 3A) as described in some of the above embodiments. Forming the plurality of light-emitting devices on the substrate, further includes: forming at least one second light-emitting device, and forming at least one third light-emitting device.

In a case where the plurality of light-emitting devices further include at least one second light-emitting device, each second light-emitting device in the at least one second light-emitting device includes a second sacrificial layer group, and the second sacrificial layer group includes a second carrier transport layer, forming the at least one second light-emitting device, includes: forming a second initial carrier transport layer and a second initial light-emitting pattern sequentially on a side of the first electrode layer and the at least one first light-emitting device away from the substrate, wherein a material of the second initial carrier transport layer includes a second carrier transport material, or includes a second carrier transport material and a fifth photosensitive material, and a material of the second initial light-emitting pattern includes a second quantum dot material, or includes a second quantum dot material and a fourth photosensitive material; exposing the second initial carrier transport layer and the second initial light-emitting pattern that are stacked to convert a material of an exposed portion of the second initial carrier transport layer into a second cross-linked carrier transport material, and convert a material of an exposed portion of the second initial light-emitting pattern into a second cross-linked light-emitting material; and developing the second initial carrier transport layer and the second initial light-emitting pattern that are stacked to form the second carrier transport layer and a second light-emitting pattern that are stacked.

In a case where the plurality of light-emitting devices further include at least one third light-emitting device, each third light-emitting device in the at least one third light-emitting device includes a third sacrificial layer group, and the third sacrificial layer group includes a third carrier transport layer, forming the at least one third light-emitting device, includes: forming a third initial carrier transport layer and a third initial light-emitting pattern sequentially on a side of the first electrode layer, the at least one first light-emitting device and the at least one second light-emitting device away from the substrate, wherein a material of the third initial carrier transport layer includes a third carrier transport material, or includes a third carrier transport material and an eighth photosensitive material, and a material of the third initial light-emitting pattern includes a third quantum dot material, or includes a third quantum dot material and a seventh photosensitive material; exposing the third initial carrier transport layer and the third initial light-emitting pattern that are stacked to convert a material of an exposed portion of the third initial carrier transport layer into a third cross-linked carrier transport material, and convert a material of an exposed portion of the third initial light-emitting pattern into a third cross-linked light-emitting material; and developing the third initial carrier transport layer and the third initial light-emitting pattern that are stacked to form the third carrier transport layer and a third light-emitting pattern that are stacked.

In some embodiments, the manufacturing method is used to form the light-emitting device (e.g., used to manufacturing the light-emitting substrate as shown in FIG. 3B) as described in some of the above embodiments. Forming the plurality of light-emitting devices on the substrate, further includes: forming at least one second light-emitting device, and forming at least one third light-emitting device.

In a case where the plurality of light-emitting devices further include at least one second light-emitting device, each second light-emitting device in the at least one second light-emitting device includes a second sacrificial layer group, and the second sacrificial layer group includes a second carrier transport layer and a second carrier injection layer, forming the at least one second light-emitting device, includes: forming a second initial carrier injection layer, a second initial carrier transport layer and a second initial light-emitting pattern sequentially on a side of the first electrode layer and the at least one first light-emitting device away from the substrate, wherein a material of the second initial carrier injection layer includes a second carrier injection material, or includes a second carrier injection material and a sixth photosensitive material, a material of the second initial carrier transport layer includes a second carrier transport material, or includes a second carrier transport material and a fifth photosensitive material, and a material of the second initial light-emitting pattern includes a second quantum dot material, or includes a second quantum dot material and a fourth photosensitive material; exposing the second initial carrier injection layer, the second initial carrier transport layer and the second initial light-emitting pattern that are stacked to convert a material of an exposed portion of the second initial carrier injection layer into a second cross-linked carrier injection material, convert a material of an exposed portion of the second initial carrier transport layer into a second cross-linked carrier transport material, and convert a material of an exposed portion of the second initial light-emitting pattern into a second cross-linked light-emitting material; and developing the second initial carrier injection layer, the second initial carrier transport layer and the second initial light-emitting pattern that are stacked to form the second carrier injection layer, the second carrier transport layer and a second light-emitting pattern that are stacked.

In a case where the plurality of light-emitting devices further include at least one third light-emitting device, each third light-emitting device in the at least one third light-emitting device includes a third sacrificial layer group, and the third sacrificial layer group includes a third carrier transport layer and a third carrier injection layer, forming the at least one third light-emitting device, includes: forming a third initial carrier injection layer, a third initial carrier transport layer and a third initial light-emitting pattern sequentially on a side of the first electrode layer, the at least one first light-emitting device and the at least one second light-emitting device away from the substrate, wherein a material of the third initial carrier injection layer includes a third carrier injection material, or includes a third carrier injection material and a ninth photosensitive material, a material of the third initial carrier transport layer includes a third carrier transport material, or includes a third carrier transport material and an eighth photosensitive material, and a material of the third initial light-emitting pattern includes a third quantum dot material, or includes a third quantum dot material and a seventh photosensitive material; exposing the third initial carrier injection layer, the third initial carrier transport layer and the third initial light-emitting pattern that are stacked to convert a material of an exposed portion of the third initial carrier injection layer into a third cross-linked carrier injection material, convert a material of an exposed portion of the third initial carrier transport layer into a third cross-linked carrier transport material, and convert a material of an exposed portion of the third initial light-emitting pattern into a third cross-linked light-emitting material; and developing the third initial carrier injection layer, the third initial carrier transport layer and the third initial light-emitting pattern that are stacked to form the third carrier injection layer, the third carrier transport layer and a third light-emitting pattern that are stacked.

In some embodiments, the manufacturing method is used to form the light-emitting device (e.g., used to manufacturing the light-emitting substrate as shown in FIG. 3B) as described in some of the above embodiments. Forming the plurality of light-emitting devices on the substrate, further includes: forming at least one second light-emitting device, and forming at least one third light-emitting device.

In a case where the plurality of light-emitting devices further include at least one second light-emitting device, each second light-emitting device in the at least one second light-emitting device includes a second sacrificial layer group, and the second sacrificial layer group includes a second carrier transport layer and a second carrier injection layer, forming the at least one second light-emitting device, includes: forming a second initial carrier injection layer on a side of the first electrode layer and the at least one first light-emitting device away from the substrate, a material of the second initial carrier injection layer including a second carrier injection material, or including a second carrier injection material and a sixth photosensitive material; exposing the second initial carrier injection layer to convert a material of an exposed portion of the second initial carrier injection layer into a second cross-linked carrier injection material; forming a second initial carrier transport layer and a second initial light-emitting pattern sequentially on a side of the second initial carrier injection layer away from the substrate, wherein a material of the second initial carrier transport layer includes a second carrier transport material, or includes a second carrier transport material and a fifth photosensitive material, and a material of the second initial light-emitting pattern includes a second quantum dot material, or includes a second quantum dot material and a fourth photosensitive material; exposing the second initial carrier transport layer and the second initial light-emitting pattern that are stacked to convert a material of an exposed portion of the second initial carrier transport layer into a second cross-linked carrier transport material, and convert a material of an exposed portion of the second initial light-emitting pattern into a second cross-linked light-emitting material; and developing the second initial carrier injection layer, the second initial carrier transport layer and the second initial light-emitting pattern that are stacked to form the second carrier injection layer, the second carrier transport layer and a second light-emitting pattern that are stacked.

In a case where the plurality of light-emitting devices further include at least one third light-emitting device, each third light-emitting device in the at least one third light-emitting device includes a third sacrificial layer group, and the third sacrificial layer group includes a third carrier transport layer and a third carrier injection layer, forming the at least one third light-emitting device, includes: forming a third initial carrier injection layer on a side of the first electrode layer, the at least one first light-emitting device and the at least one second light-emitting device away from the substrate, a material of the third initial carrier injection layer including a third carrier injection material, or including a third carrier injection material and a ninth photosensitive material; exposing the third initial carrier injection layer to convert a material of an exposed portion of the third initial carrier injection layer into a third cross-linked carrier injection material; forming a third initial carrier transport layer and a third initial light-emitting pattern sequentially on a side of the third initial carrier injection layer away from the substrate, wherein a material of the third initial carrier transport layer includes a third carrier transport material, or includes a third carrier transport material and an eighth photosensitive material, and a material of the third initial light-emitting pattern includes a third quantum dot material, or includes a third quantum dot material and a seventh photosensitive material; exposing the third initial carrier transport layer and the third initial light-emitting pattern that are stacked to convert a material of an exposed portion of the third initial carrier transport layer into a third cross-linked carrier transport material, and convert a material of an exposed portion of the third initial light-emitting pattern into a third cross-linked light-emitting material; and developing the third initial carrier injection layer, the third initial carrier transport layer and the third initial light-emitting pattern that are stacked to form the third carrier injection layer, the third carrier transport layer and a third light-emitting pattern that are stacked.

In some embodiments, the manufacturing method is used to form the light-emitting device (e.g., used to manufacturing the light-emitting substrate as shown in FIG. 3A or 3B) as described in some of the above embodiments. In an initial light-emitting pattern, a ratio of a mass of a first type of photosensitive material to a mass of a quantum dot material is in a range of 0% to 30%, inclusive; the initial light-emitting pattern is one of a first initial light-emitting pattern, a second initial light-emitting pattern and a third initial light-emitting pattern. And/or, in an initial carrier transport layer, a ratio of a mass of a second type of photosensitive material to a mass of a carrier transport material is in a range of 0% to 30%, inclusive; the initial carrier transport layer is one of a first initial carrier transport layer, the second initial carrier transport layer and the third initial carrier transport layer. And/or, in an initial carrier injection layer, a ratio of a mass of a third type of photosensitive material to a mass of a carrier injection material is in a range of 0% to 30%, inclusive; the initial carrier injection layer is one of a first initial carrier injection layer, the second initial carrier injection layer and the third initial carrier injection layer.

In another aspect, a light-emitting apparatus is provided. The light-emitting apparatus includes the light-emitting substrate as described in any of the above embodiments, and a driver chip used for driving the light-emitting substrate to emit light.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a flow chart of a method for manufacturing a light-emitting substrate, in accordance with some embodiments of the present disclosure;

FIG. 2 is a structural diagram of a light-emitting substrate, in accordance with some embodiments of the present disclosure;

FIG. 3A is a structural diagram of a light-emitting substrate, in accordance with some embodiments of the present disclosure;

FIG. 3B is a structural diagram of another light-emitting substrate, in accordance with some embodiments of the present disclosure;

FIG. 4 is a diagram showing steps of a method for manufacturing a light-emitting substrate, in accordance with some embodiments of the present disclosure;

FIG. 5 is a diagram showing steps of another method for manufacturing a light-emitting substrate, in accordance with some embodiments of the present disclosure;

FIG. 6 is a diagram showing steps of yet another method for manufacturing a light-emitting substrate, in accordance with some embodiments of the present disclosure;

FIG. 7 is a diagram showing steps of yet another method for manufacturing a light-emitting substrate, in accordance with some embodiments of the present disclosure;

FIG. 8 is a diagram showing steps of yet another method for manufacturing a light-emitting substrate, in accordance with some embodiments of the present disclosure;

FIG. 9A is a diagram showing steps of yet another method for manufacturing a light-emitting substrate, in accordance with some embodiments of the present disclosure;

FIG. 9B is a diagram showing steps of yet another method for manufacturing a light-emitting substrate, in accordance with some embodiments of the present disclosure;

FIG. 10A is a diagram showing steps of yet another method for manufacturing a light-emitting substrate, in accordance with some embodiments of the present disclosure;

FIG. 10B is a diagram showing steps of yet another method for manufacturing a light-emitting substrate, in accordance with some embodiments of the present disclosure;

FIG. 11A is a diagram showing steps of yet another method for manufacturing a light-emitting substrate, in accordance with some embodiments of the present disclosure;

FIG. 11B is a diagram showing steps of yet another method for manufacturing a light-emitting substrate, in accordance with some embodiments of the present disclosure;

FIG. 12 is a structural diagram of a light-emitting apparatus, in accordance with some embodiments of the present disclosure;

FIG. 13 is a UV absorption spectrum map of a carrier injection layer, in accordance with some embodiments of the present disclosure;

FIG. 14 is another UV absorption spectrum map of a carrier injection layer, in accordance with some embodiments of the present disclosure;

FIG. 15 is a fluorescence microscopy image of a light-emitting device, in accordance with some embodiments of the present disclosure;

FIG. 16 is a curve graph of a current density of a light-emitting device changing with a voltage, in accordance with some embodiments of the present disclosure;

FIG. 17 is a curve graph of a brightness of a light-emitting device changing with a voltage, in accordance with some embodiments of the present disclosure;

FIG. 18 is a curve graph of a current efficiency of a light-emitting device changing with a voltage, in accordance with some embodiments of the present disclosure;

FIG. 19 is a curve graph of an external quantum efficiency of a light-emitting device changing with a voltage, in accordance with some embodiments of the present disclosure;

FIG. 20 is a fluorescence microscopy image of a light-emitting device, in accordance with some embodiments of the present disclosure;

FIG. 21 is a diagram showing a lighting test result of a light-emitting device, in accordance with some embodiments of the present disclosure;

FIG. 22 is a photo of electroluminescence fluorescence microscope of a light-emitting device, in accordance with some embodiments of the present disclosure; and

FIG. 23 is a curve graph of an electroluminescence intensity of a light-emitting device changing with a wave length, in accordance with some embodiments of the present disclosure.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°, and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

As mentioned in the background, based on a quantum confinement effect, quantum dots (QD) have broadband absorption, narrowband emission, continuously adjustable peak position and other excellent luminescence properties. Moreover, quantum dots have solution processability, and thus use of expensive vacuum equipment is avoided, so that the quantum dot light-emitting diodes (QLEDs) with quantum dots as light-emitting materials are widely used in display and lighting, solar cells, photoelectric detection, and other fields. Patterning is a process of pixelating quantum dots that are in a solution state, and is an only way to transform quantum dots into formed optoelectronic devices and even into commercial products. Using a traditional photoresist indirect method may achieve quantum dots patterning. However, due to incompatibility between a quantum dot solvent and a photoresist solvent, and reduction in luminescent properties of quantum dots themselves generally caused by introduction of photoresist, it is difficult to achieve quantum dots patterning using the traditional photoresist technology. The preparation technologies of light-emitting layers of quantum dot light-emitting diodes mainly include inkjet printing technology, photolithography technology, transfer technology, and the like, and the photolithography technology is a promising method for forming high-resolution quantum dot light-emitting diodes.

The light-responsive surface ligands give quantum dots a function of being directly patterned by photolithography. The main principle is to change colloidal stability of quantum dots before and after a photochemical reaction using photochemical reactions such as decomposition or cross-linking of photosensitive groups to achieve a purpose of selective patterning through development.

The photolithography technology is a technology of achieving quantum dots patterning by means of exposure and development.

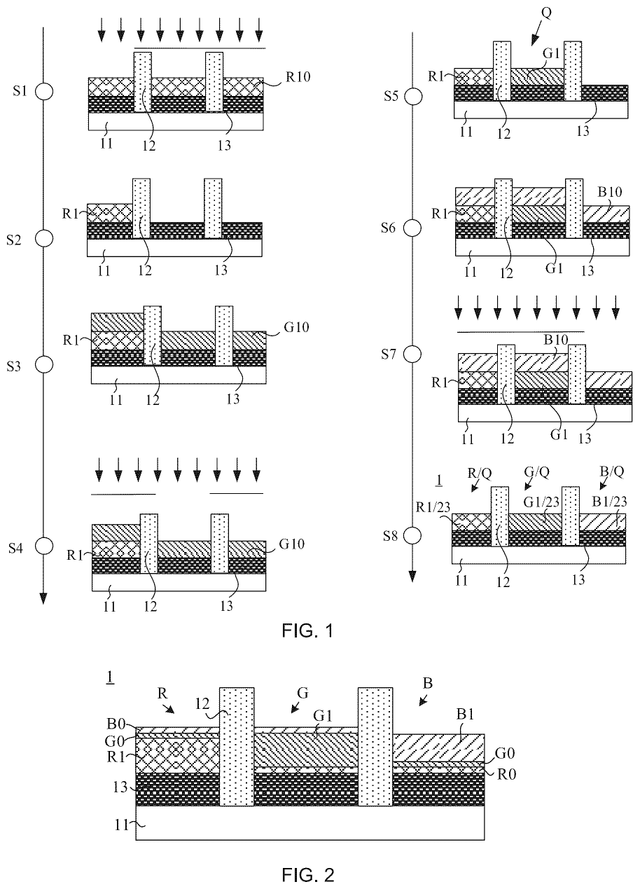

As shown in FIG. 1, a process for forming a light-emitting pattern 23 of a light-emitting substrate 1 is exemplarily introduced. Referring to the last sub-figure in FIG. 1 (i.e., a sub-figure corresponding to step S8), the light-emitting substrate 1 includes a substrate 11, and a pixel defining layer 12 and a plurality of light-emitting devices that are disposed on the substrate 11. Each light-emitting device includes a light-emitting pattern 23. The pixel defining layer 12 has a plurality of openings Q, and the plurality of light-emitting devices and the plurality of openings Q may be disposed in one-to-one correspondence.

For example, the plurality of light-emitting devices include a red light-emitting device R, a green light-emitting device G and a blue light-emitting device B. The following describes a process of sequentially forming a light-emitting pattern R1 of the red light-emitting device R, a light-emitting pattern G1 of the green light-emitting device G and a light-emitting pattern B1 of the blue light-emitting device B.

As shown in FIG. 1, the process includes steps S1 to S8.

In order to improve an efficiency of injecting electrons and holes into the light-emitting pattern 23, a front film layer 13 is further provided between the substrate 11 and the light-emitting pattern 23. The front film layer 13 is, for example, one or two of an electron injection layer, an electron transport layer, a hole injection layer and a hole transport layer.

In S1, a red quantum dot (RQD) light-emitting material is formed by coating on a side of the front film layer 13 away from the substrate 11 to form a red initial light-emitting pattern R10, and the red initial light-emitting pattern R10 is exposed, where a region for the red light-emitting device R to be formed is an exposed region.

In S2, the red initial light-emitting pattern R10 is developed, where a portion of the red initial light-emitting pattern R10 in the exposed region is retained to form the light-emitting pattern R1 of the red light-emitting device R.

In S3, a green quantum dot (GQD) light-emitting material is formed by coating on a side of the light-emitting pattern R1 of the red light-emitting device R and the front film layer 13 away from the substrate 11 to form a green initial light-emitting pattern G10.

In S4, the green initial light-emitting pattern G10 is exposed, where a region for the green light-emitting device G to be formed is an exposed region.

In S5, the green initial light-emitting pattern G10 is developed, where a portion of the green initial light-emitting pattern G10 in the exposed region is retained to form the light-emitting pattern G1 of the green light-emitting device G.

In S6, a blue quantum dot (BQD) light-emitting material is formed by coating on a side of the light-emitting pattern G1 of the green light-emitting device G, the light-emitting pattern R1 of the red light-emitting device R and the front film layer 13 away from the substrate 11 a blue initial light-emitting pattern B10.

In S7, the blue initial light-emitting pattern B10 is exposed, where a region for the blue light-emitting device B to be formed is an exposed region.

In S8, the blue initial light-emitting pattern B10 is developed, where a portion of the blue initial light-emitting pattern B10 in the exposed region is retained to form the light-emitting pattern B1 of the blue light-emitting device B.

However, in an actual process of forming the light-emitting pattern 23 of the light-emitting substrate 1, as shown in FIG. 2, since a certain interaction exists between a quantum dot light-emitting material and a material of an adjacent film layer, and the interaction includes, but is not limited to, van der Waals force, electrostatic force, gravity and capillary force, the patterning method has a problem of incomplete elution of the quantum dot light-emitting material of the former color (e.g., the red quantum dot light-emitting material), and thus there is a residue of the quantum dot light-emitting material of the former color (e.g., the red quantum dot light-emitting material) on a side of the light-emitting pattern of the latter color (e.g., the light-emitting pattern G1 of the green light-emitting device G) proximate to the substrate 11. Moreover, the patterning method further has a problem of incomplete elution of the quantum dot light-emitting material of the latter color (e.g., the blue quantum dot light-emitting material), and thus there is a residue of the quantum dot light-emitting material of the latter color (e.g., the blue quantum dot light-emitting material) on a side of the light-emitting pattern of the former color (e.g., the light-emitting pattern G1 of the green light-emitting device G) away from the substrate 11.

For example, as shown in FIG. 2, considering an example where the light-emitting pattern R1 of the red light-emitting device R, the light-emitting pattern G1 of the green light-emitting device G and the light-emitting pattern B1 of the blue light-emitting device B are sequentially forming, there will be a residual layer G0 formed by the green quantum dot light-emitting material and a residual layer B0 formed by the blue quantum dot light-emitting material on a side of the light-emitting pattern R1 of the red light-emitting device R away from the substrate 11; there will be a residual layer R0 formed by the red quantum dot light-emitting material on a side of the light-emitting pattern G1 of the green light-emitting device G proximate to the substrate 11, and there will be a residual layer B0 formed by the blue quantum dot light-emitting material on a side of the light-emitting pattern G1 of the green light-emitting device G away from the substrate 11; and there will be a residual layer R0 formed by the red quantum dot light-emitting material and a residual layer G0 formed by the green quantum dot light-emitting material on a side of the light-emitting pattern B1 of the blue light-emitting device B proximate to the substrate 11.

Such residual layers formed by the quantum dot light-emitting materials may cause color mixing. When the light-emitting devices are lit up, the luminescent spectrum is prone to impurity, thereby affecting the device performance.

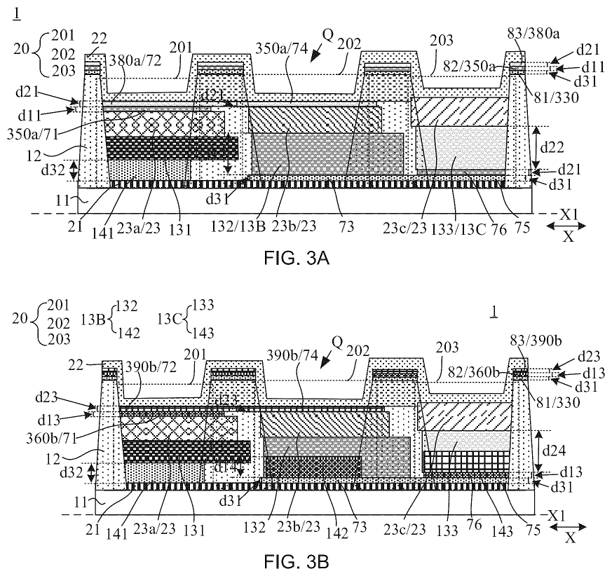

Based on the above problems, as shown in FIGS. 3A to 3B, some embodiments of the present disclosure provide a light-emitting substrate 1. The light-emitting substrate 1 includes a substrate 11 and a plurality of light-emitting devices 20. The plurality of light-emitting devices 20 are disposed on the substrate 11 and arranged in a first direction X, where the first direction X is parallel to a plane X1 where the substrate 11 is located. Each light-emitting device 20 in the plurality of light-emitting devices 20 includes a first electrode 21, a second electrode 22, and a light-emitting pattern 23 disposed between the first electrode 21 and the second electrode 22. The first electrode 21 is closer to the substrate 11 than the second electrode 22.

For example, as shown in FIGS. 3A to 3B, the light-emitting substrate 1 further includes a pixel defining layer 12 disposed on the substrate 11. The pixel defining layer 12 has a plurality of openings Q, and the plurality of light-emitting devices 20 may be disposed in one-to-one correspondence with the plurality of openings Q.

In some examples, the first electrode 21 may be an anode, and in this case, the second electrode 22 is a cathode. In some other examples, the first electrode 21 may be a cathode, and in this case, the second electrode 22 is an anode.

The light-emitting principle of the light-emitting device 20 is as follows: through a circuit connected to the anode and the cathode, holes from the anode are injected into the light-emitting pattern 23 and electrons from the cathode are injected into the light-emitting pattern 23, the electrons and the holes form excitons in the light-emitting pattern 23, and the excitons return to the ground state by radiative transitions to emit photons.

As shown in FIGS. 3A to 3B, the plurality of light-emitting devices 20 include at least one first light-emitting device 201. Each first light-emitting device 201 in the at least one first light-emitting device 201 includes a first light-emitting pattern 23a, and a first carrier transport layer 131 and a first carrier injection layer 141 that are disposed between the substrate 11 and the first light-emitting pattern 23a. The first carrier transport layer 131 is closer to the first light-emitting pattern 23a than the first carrier injection layer 141. A material of the first light-emitting pattern 23a includes a first cross-linked light-emitting material; a material of the first carrier transport layer 131 includes a first cross-linked carrier transport material; and a material of the first carrier injection layer 141 includes a first cross-linked carrier injection material.

For example, as shown in FIGS. 3A to 3B, the first carrier injection layer 141, the first carrier transport layer 131, and the first light-emitting pattern 23a are in contact in sequence.

For example, the first light-emitting device 201 is a light-emitting device for emitting red light, and a first quantum dot material may be a red quantum dot light-emitting material.

In some examples, the first cross-linked light-emitting material is generated by cross-linking of a first quantum dot material under light radiation, and in this case, the first quantum dot material is a cross-linkable organic material. For example, the first quantum dot material includes a first quantum dot body and a ligand material, and the ligand material is a cross-linkable organic material. That is, the first quantum dot material in a region where the first light-emitting device 201 is located is exposed to achieve self-crosslinking of the first quantum dot material to form the first cross-linked light-emitting material, where a solubility of the first quantum dot material in a first solvent is greater than a solubility of the first cross-linked light-emitting material in the first solvent; and then, development is carried out, where the first cross-linked light-emitting material is insoluble in a developer (e.g., the first solvent) and the first quantum dot material is soluble in the developer, to remove a portion of the first quantum dot material in a remaining region except the region where the first light-emitting device 201 is located, so as to form a patterned first light-emitting pattern 23a.

In some other examples, the first cross-linked light-emitting material is generated by cross-linking of a first quantum dot material and a first photosensitive material under light radiation. That is, the first quantum dot material and the first photosensitive material in a region where the first light-emitting device 201 is located are exposed to achieve crosslinking of the first quantum dot material and the first photosensitive material to form the first cross-linked light-emitting material, where solubilities of the first quantum dot material and the first photosensitive material in a first solvent are greater than a solubility of the first cross-linked light-emitting material in the first solvent; and then, development is carried out, where the first cross-linked light-emitting material is insoluble in a developer (e.g., the first solvent), and the first quantum dot material and the first photosensitive material are soluble in the developer, to remove portions of the first quantum dot material and the first photosensitive material in a remaining region except the region where the first light-emitting device 201 is located, so as to form a patterned first light-emitting pattern 23a.

For example, the first solvent is a first-type solvent, and the first-type solvent includes at least one of octane and propylene glycol methyl ether acetate (PMA).

For example, the first carrier transport layer 131 is an electron transport layer, and the first carrier injection layer 141 is an electron injection layer. In this case, the first electrode 21 is a cathode, and the second electrode 22 is an anode. The first light-emitting device 201 is an inverted light-emitting device.

For example, the first carrier transport layer 131 is a hole transport layer, and the first carrier injection layer 141 is a hole injection layer. In this case, the first electrode 21 is an anode, and the second electrode 22 is a cathode. The light-emitting device 201 is an upright light-emitting device.

In some examples, the first cross-linked carrier transport material is generated by cross-linking of a first carrier transport material under light radiation, and in this case, the first carrier transport material is a cross-linkable organic material. That is, the first carrier transport material in a region where the first light-emitting device 201 is located is exposed to achieve self-crosslinking of the first carrier transport material to form the first cross-linked carrier transport material, where a solubility of the first carrier transport material in a second solvent is greater than a solubility of the first cross-linked carrier transport material in the second solvent; and then, development is carried out, where the first cross-linked carrier transport material is insoluble in a developer (e.g., the second solvent) and the first carrier transport material is soluble in the developer, to remove a portion of the first carrier transport material in a remaining region except the region where the first light-emitting device 201 is located, so as to form a patterned first carrier transport layer 131.

In some other examples, the first cross-linked carrier transport material is generated by cross-linking of a first carrier transport material and a second photosensitive material under light radiation. That is, the first carrier transport material and the second photosensitive material in a region where the first light-emitting device 201 is located are exposed to achieve crosslinking of the first carrier transport material and the second photosensitive material to form the first cross-linked carrier transport material, where solubilities of the first carrier transport material and the second photosensitive material in a second solvent are greater than a solubility of the first cross-linked carrier transport material in the second solvent; and then, development is carried out, where the first cross-linked carrier transport material is insoluble in a developer (e.g., the second solvent), and the first carrier transport material and the second photosensitive material are soluble in the developer, to remove portions of the first carrier transport material and the second photosensitive material in a remaining region except the region where the first light-emitting device 201 is located, so as to form a patterned first carrier transport layer 131.

For example, the second solvent is a second-type solvent, and the second-type solvent includes at least one of toluene, chlorobenzene or (dichloromethyl)benzene.

In some examples, the first cross-linked carrier injection material is generated by cross-linking of a first carrier injection material under light radiation, and in this case, the first carrier injection material is a cross-linkable organic material. That is, the first carrier injection material in a region where the first light-emitting device 201 is located is exposed to achieve self-crosslinking of the first carrier injection material to form the first cross-linked carrier injection material, where a solubility of the first carrier injection material in a third solvent is greater than a solubility of the first cross-linked carrier injection material in the third solvent; and then, development is carried out, where the first cross-linked carrier injection material is insoluble in a developer (e.g., the third solvent) and the first carrier injection material is soluble in the developer, to remove a portion of the first carrier injection material in a remaining region except the region where the first light-emitting device 201 is located, so as to form a patterned first carrier injection layer 141.

In some other examples, the first cross-linked carrier injection material is generated by cross-linking of a first carrier injection material and a third photosensitive material under light radiation. That is, the first carrier injection material and the third photosensitive material in a region where the first light-emitting device 201 is located are exposed to achieve crosslinking of the first carrier injection material and the third photosensitive material to form the first cross-linked carrier injection material, where solubilities of the first carrier injection material and the third photosensitive material in a third solvent are greater than a solubility of the first cross-linked carrier injection material in the third solvent; and then, development is carried out, where the first cross-linked carrier injection material is insoluble in a developer (e.g., the third solvent), and the first carrier injection material and the third photosensitive material are soluble in the developer, to remove portions of the first carrier injection material and the third photosensitive material in a remaining region except the region where the first light-emitting device 201 is located, so as to form a patterned first carrier injection layer 141.

For example, the third solvent is a third-type solvent, and the third-type solvent includes at least one of water, ethanol, methanol, N,N-dimethylformamide, N-methylformamide and thionyl chloride.

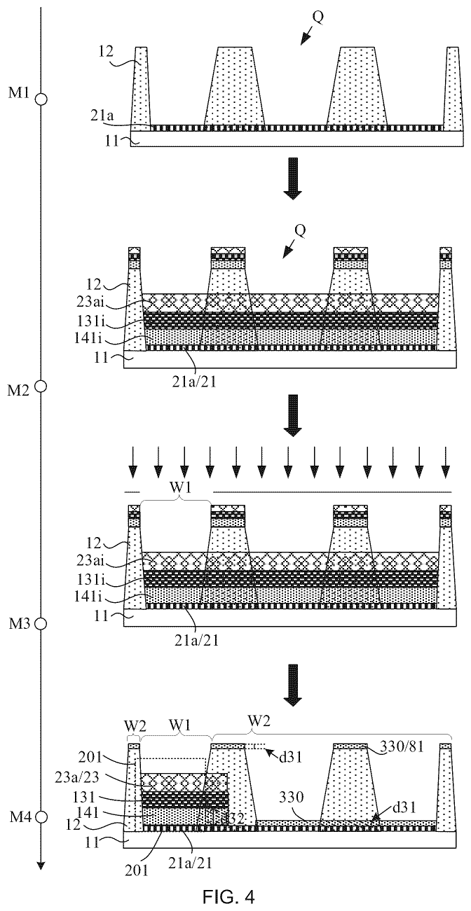

A method for forming at least one first light-emitting device is exemplarily introduced below. As shown in FIG. 4, the method includes M1 to M4.

In M1, a first electrode layer 21a is formed on the substrate 11; and the first electrode layer 21a includes a first electrode 21 of at least one first light-emitting device 201.

For example, a process for forming the first electrode layer 21a is magnetron sputtering.

For example, the first electrodes 21 and the openings Q in the pixel defining layer 12 are in one-to-one correspondence.

In M2, a first initial carrier injection layer 141i, a first initial carrier transport layer 131i and a first initial light-emitting pattern 23ai are sequentially formed on a side of the first electrode layer 21a away from the substrate 11.

For example, a process for forming the first initial carrier injection layer 141i is any of spin coating, screen printing, scraping coating and drip coating, and a process solution is a third solution, where a solvent of the third solution is the third solvent, and a solute of the third solution is a material for forming the first initial carrier injection layer 141i. It will be noted that in a case where the first cross-linked carrier injection material is formed by self-crosslinking of the first carrier injection material, the material for forming the first initial carrier injection layer 141i is the first carrier injection material. Alternatively, in a case where the first cross-linked carrier injection material is formed by crosslinking of the first carrier injection material and the third photosensitive material, the material for forming the first initial carrier injection layer 141i is the first carrier injection material and the third photosensitive material.

For example, a process for forming the first initial carrier transport layer 131i is any of spin coating, screen printing, scraping coating and drip coating, and a process solution is a second solution, where a solvent of the second solution is the second solvent, and a solute of the second solution is a material for forming the first initial carrier transport layer 131i. It will be noted that in a case where the first cross-linked carrier transport material is formed by self-crosslinking of the first carrier transport material, the material for forming the first initial carrier transport layer 131i is the first carrier transport material. Alternatively, in a case where the first cross-linked carrier transport material is formed by crosslinking of the first carrier transport material and the second photosensitive material, the material for forming the first initial carrier transport layer 131i is the first carrier transport material and the second photosensitive material.

For example, a process for forming the first initial light-emitting pattern 23ai is any of spin coating, screen printing, scraping coating and drip coating, and a process solution is a first solution, where a solvent of the first solution is the first solvent, and a solute of the first solution is a material for forming the first initial light-emitting pattern 23ai. It will be noted that in a case where the first cross-linked light-emitting material is formed by self-crosslinking of the first quantum dot material, the material for forming the first initial light-emitting pattern 23ai is the first quantum dot material. Alternatively, in a case where the first cross-linked light-emitting material is formed by crosslinking of the first quantum dot material and the first photosensitive material, the material for forming the first initial light-emitting pattern 23ai is the first quantum dot material and the first photosensitive material.

In M3, the first initial carrier injection layer 141i, the first initial carrier transport layer 131i and the first initial light-emitting pattern 23ai that are stacked are exposed to convert a material of an exposed portion of the first initial carrier injection layer 141i into the first cross-linked carrier injection material, convert a material of an exposed portion of the first initial carrier transport layer 131i into the first cross-linked carrier transport material, and convert a material of an exposed portion of the first initial light-emitting pattern 23ai into the first cross-linked light-emitting material.

It can be understood that the above exposed region is a region corresponding to at least one first light-emitting device 201. In this step, portions, in a region where the at least one first light-emitting device 201 is located, of the first initial carrier injection layer 141i, the first initial carrier transport layer 131i and the first initial light-emitting pattern 23ai are exposed, so that solubilities of materials, in the region where the at least one first light-emitting device 201 is located, of the first initial carrier injection layer 141i, the first initial carrier transport layer 131i and the first initial light-emitting pattern 23ai may be changed.

That is, in this case, a portion of the first initial carrier injection layer 141i located in the region where the first light-emitting device 201 is located is converted into the first cross-linked carrier injection material, and a material of a portion of the first initial carrier injection layer 141i located in the a remaining region except the region where the first light-emitting device 201 is located remains unchanged and is still the material for forming the first initial carrier injection layer 141i. The first cross-linked carrier injection material is insoluble in a developer (the third solvent), and the material for forming the first initial carrier injection layer 141i is soluble in the developer (the third solvent).

A portion of the first initial carrier transport layer 131i located in the region where the first light-emitting device 201 is located is converted into the first cross-linked carrier transport material, and a material of a portion of the first initial carrier transport layer 131i located in the a remaining region except the region where the first light-emitting device 201 is located remains unchanged and is still the material for forming the first initial carrier transport layer 131i. The first cross-linked carrier transport material is insoluble in a developer (the second solvent), and the material for forming the first initial carrier transport layer 131i is soluble in the developer (the second solvent).

A portion of the first initial light-emitting pattern 23ai located in the region where the first light-emitting device 201 is located is converted into the first cross-linked light-emitting material, and a material of a portion of the first initial light-emitting pattern 23ai located in the a remaining region except the region where the first light-emitting device 201 is located remains unchanged and is still the material for forming the first initial light-emitting pattern 23ai. The first cross-linked light-emitting material is insoluble in a developer (the first solvent), and the material for forming the first initial light-emitting pattern 23ai is soluble in the developer (the first solvent).

It will be noted that as shown in FIG. 4, the first initial carrier injection layer 141i, the first initial carrier transport layer 131i and the first initial light-emitting pattern 23ai are also formed on a side of the pixel defining layer 12 away from the substrate 11. Although FIG. 4 shows that thicknesses of the first initial carrier injection layer 141i, the first initial carrier transport layer 131i and the first initial light-emitting pattern 23ai on the side of the pixel defining layer 12 away from the substrate 11 are inconsistent with thicknesses of the first initial carrier injection layer 141i, the first initial carrier transport layer 131i and the first initial light-emitting pattern 23ai in the opening Q in the pixel defining layer 12, it is only indicated here that the first initial carrier injection layer 141i, the first initial carrier transport layer 131i and the first initial light-emitting pattern 23ai exist on the side of the pixel defining layer 12 away from the substrate 11, and the thicknesses thereof are not limited.

In M4, the first initial carrier injection layer 141i, the first initial carrier transport layer 131i and the first initial light-emitting pattern 23ai that are stacked are developed to form the first carrier injection layer 141, the first carrier transport layer 131 and the first light-emitting pattern 23a that are stacked.

For example, M4 may include the following three steps of development.

A portion of the first initial light-emitting pattern 23ai located in the remaining region, except the region where the first light-emitting device(s) 201 are located, in a region where the plurality of light-emitting devices 20 are located is removed using a developer (the first solvent) (a portion of the material for forming the first initial light-emitting pattern 23ai proximate to the substrate 11 has a residue to form a first temporary residual layer), while a portion of the first initial light-emitting pattern 23ai located in the region where the first light-emitting device(s) 201 are located is retained to obtain at least one first light-emitting pattern 23a.

A portion of the first initial carrier transport layer 131i located in the remaining region, except the region where the first light-emitting device(s) 201 are located, in a region where the plurality of light-emitting devices 20 are located is removed using a developer (the second solvent) (a portion of the material for forming the first initial carrier transport layer 131i proximate to the substrate 11 has a residue to form a second temporary residual layer), and a portion, located in the remaining region except the region where the first light-emitting device(s) 201 are located in a region where the plurality of light-emitting devices 20 are located, of the first temporary residual layer on the first initial carrier transport layer 131i is also removed, so as to avoid the residue of the material for forming the first initial light-emitting pattern 23ai in the remaining region, except the region where the first light-emitting device(s) 201 are located, in a region where the plurality of light-emitting devices 20 are located. Whereas, a portion of the first initial carrier transport layer 131i located in the region where the first light-emitting device(s) 201 are located is retained to obtain the first carrier transport layer 131 of at least one first light-emitting device 201.

A portion of the first initial carrier injection layer 141i located in the remaining region, except the region where the first light-emitting device(s) 201 are located, in a region where the plurality of light-emitting devices 20 are located is removed using a developer (the third solvent) (a portion of the material for forming the first initial carrier injection layer 141i proximate to the substrate 11 has a residue such as a first initial residual pattern 330 shown in FIG. 4, and an introduction to the first initial residual pattern 330 refers to subsequent contents and is not described in detail here), and a portion, located in the remaining region except the region where the first light-emitting device(s) 201 are located in a region where the plurality of light-emitting devices 20 are located, of the second temporary residual layer on the first initial carrier injection layer 141i is also removed, so as to avoid the residue of the material for forming the first carrier transport layer 131 in the remaining region, except the region where the first light-emitting device(s) 201 are located, in a region where the plurality of light-emitting devices 20 are located. Whereas, a portion of the first initial carrier injection layer 141i located in the region where the first light-emitting device(s) 201 are located is retained to obtain the first carrier injection layer 141 of at least one first light-emitting device 201.

It will be noted that after the first light-emitting pattern 23a is formed, the first initial residual pattern 330 also exists on the side of the pixel defining layer 12 away from the substrate 11.

Compared with the direct photolithography method used in the related art to achieve patterning of the quantum dot light-emitting materials, the materials that can undergo cross-linking reaction under light irradiation are provided as the materials of the two front film layers (i.e., the first carrier transport layer 131 and the first carrier injection layer 141). In this way, the two front film layers may be used as double sacrificial layers to remove the portion of the first quantum dot material located in the remaining region except the region where the first light-emitting device 201 is located, thereby preventing the first quantum dot material from forming residues in the remaining region except the region where the first light-emitting device 201 is located, and further solving the problem of color mixing caused by the residue of the quantum dot light-emitting material of the former color on a side of the light-emitting pattern of the latter color proximate to the substrate 11 in the related art. In addition, the second temporary residual layer is a portion of the first initial carrier transport layer 131i, and the first initial carrier transport layer 131i is a film layer in contact with the first initial light-emitting pattern 23ai. Therefore, the above step of developing using a developer (the third solvent) may avoid the residue of the second temporary residual layer in the remaining region, except the region where the first light-emitting device(s) 201 are located, in a region where the plurality of light-emitting devices 20 are located, and in particular, avoid the residue of the second temporary residual layer in a region where remaining light-emitting devices except the first light-emitting device(s) 201 in the plurality of light-emitting devices 20 is located. Thus, the problem of color mixing may be further solved to avoid the impure light-emitting spectrum, and the device performance may be effectively improved.

The above is an exemplary introduction to the plurality of light-emitting devices 20 including at least one first light-emitting device 201. The following is an exemplary introduction to the plurality of light-emitting devices 20 including at least one second light-emitting device 202.

In some embodiments, as shown in FIGS. 3A to 3B, the plurality of light-emitting devices 20 further include at least one second light-emitting device 202. Each second light-emitting device 202 in the at least one second light-emitting device 202 includes a second light-emitting pattern 23b, and a second sacrificial layer group 13B disposed between the substrate 11 and the second light-emitting pattern 23b. The second sacrificial layer group 13B includes a second carrier transport layer 132. A material of the second light-emitting pattern 23b includes a second cross-linked light-emitting material; and a material of the second carrier transport layer 132 includes a second cross-linked carrier transport material.

For example, as shown in FIG. 3A, the second sacrificial layer group 13B is a second carrier transport layer 132, and the second carrier transport layer 132 is in contact with the second light-emitting pattern 23b. It will be noted that a thickness of the second carrier transport layer 132 is not limited here. For example, a first thickness is defined as a sum of the thicknesses of the first carrier transport layer 131 and the first carrier injection layer 141; and with the first thickness as a reference, the thickness of the second carrier transport layer 132 may be less than the first thickness, or equal to the first thickness, or greater than the first thickness.

For example, the second light-emitting device 202 is a light-emitting device for emitting green light, and a second quantum dot material may be a green quantum dot light-emitting material.

In some examples, the second cross-linked light-emitting material is generated by cross-linking of a second quantum dot material under light radiation, and in this case, the second quantum dot material is a cross-linkable organic material. For example, the second quantum dot material includes a second quantum dot body and a ligand material, and the ligand material is a cross-linkable organic material. That is, the second quantum dot material in a region where the second light-emitting device 202 is located is exposed to achieve self-crosslinking of the second quantum dot material to form the second cross-linked light-emitting material, where a solubility of the second quantum dot material in a fourth solvent is greater than a solubility of the second cross-linked light-emitting material in the fourth solvent; and then, development is carried out, where the second cross-linked light-emitting material is insoluble in a developer (e.g., the fourth solvent) and the second quantum dot material is soluble in the developer, to remove a portion of the second quantum dot material in a remaining region except the region where the second light-emitting device 202 is located, so as to form a patterned second light-emitting pattern 23b.

In some other examples, the second cross-linked light-emitting material is generated by cross-linking of a second quantum dot material and a fourth photosensitive material under light radiation. That is, the second quantum dot material and the fourth photosensitive material in a region where the second light-emitting device 202 is located are exposed to achieve crosslinking of the second quantum dot material and the fourth photosensitive material to form the second cross-linked light-emitting material, where solubilities of the second quantum dot material and the fourth photosensitive material in a fourth solvent are greater than a solubility of the second cross-linked light-emitting material in the fourth solvent; and then, development is carried out, where the second cross-linked light-emitting material is insoluble in a developer (e.g., the fourth solvent), and the second quantum dot material and the fourth photosensitive material are soluble in the developer, to remove portions of the second quantum dot material and the fourth photosensitive material in a remaining region except the region where the second light-emitting device 202 is located, so as to form a patterned second light-emitting pattern 23b.

For example, the fourth solvent is a first-type solvent, and the first-type solvent includes at least one of octane and propylene glycol methyl ether acetate (PMA).

In some examples, the second cross-linked carrier transport material is generated by cross-linking of a second carrier transport material under light radiation, and in this case, the second carrier transport material is a cross-linkable organic material. That is, the second carrier transport material in a region where the second light-emitting device 202 is located is exposed to achieve self-crosslinking of the second carrier transport material to form the second cross-linked carrier transport material, where a solubility of the second carrier transport material in a fifth solvent is greater than a solubility of the second cross-linked carrier transport material in the fifth solvent; and then, development is carried out, where the second cross-linked carrier transport material is insoluble in a developer (e.g., the fifth solvent) and the second carrier transport material is soluble in the developer, to remove a portion of the second carrier transport material in a remaining region except the region where the second light-emitting device 202 is located, so as to form a patterned second carrier transport layer 132.

In some other examples, the second cross-linked carrier transport material is generated by cross-linking of a second carrier transport material and a fifth photosensitive material under light radiation. That is, the second carrier transport material and the fifth photosensitive material in a region where the second light-emitting device 202 is located are exposed to achieve crosslinking of the second carrier transport material and the fifth photosensitive material to form the second cross-linked carrier transport material, where solubilities of the second carrier transport material and the fifth photosensitive material in a fifth solvent are greater than a solubility of the second cross-linked carrier transport material in the fifth solvent; and then, development is carried out, where the second cross-linked carrier transport material is insoluble in a developer (e.g., the fifth solvent), and the second carrier transport material and the fifth photosensitive material are soluble in the developer, to remove portions of the second carrier transport material and the fifth photosensitive material in a remaining region except the region where the second light-emitting device 202 is located, so as to form a patterned second carrier transport layer 132.

For example, the fifth solvent is a second-type solvent, and the second-type solvent includes at least one of toluene, chlorobenzene or (dichloromethyl)benzene.

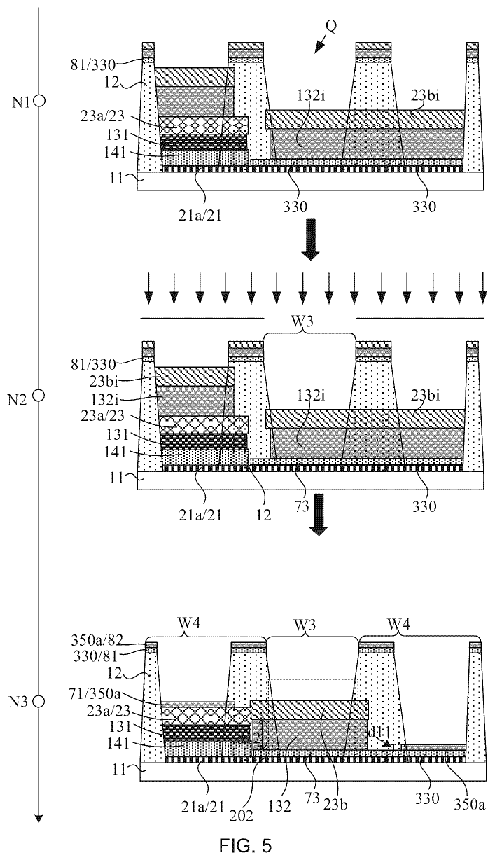

A method for forming at least one second light-emitting device 202 is exemplarily introduced below. As shown in FIG. 5, the method includes N1 to N3.

In N1, a second initial carrier transport layer 132i and a second initial light-emitting pattern 23bi are sequentially formed on a side of the first electrode layer 21a and the at least one first light-emitting device 201 away from the substrate 11.

For example, a process for forming the second initial carrier transport layer 132i is any of spin coating, screen printing, scraping coating and drip coating, and a process solution is a fifth solution, where a solvent of the fifth solution is the fifth solvent, and a solute of the fifth solution is a material for forming the second initial carrier transport layer 132i. It will be noted that in a case where the second cross-linked carrier transport material is formed by self-crosslinking of the second carrier transport material, the material for forming the second initial carrier transport layer 132i is the second carrier transport material. Alternatively, in a case where the second cross-linked carrier transport material is formed by crosslinking of the second carrier transport material and the fifth photosensitive material, the material for forming the second initial carrier transport layer 132i is the second carrier transport material and the fifth photosensitive material.

For example, a process for forming the second initial light-emitting pattern 23bi is any of spin coating, screen printing, scraping coating and drip coating, and a process solution is a fourth solution, where a solvent of the fourth solution is the fourth solvent, and a solute of the fourth solution is a material for forming the second initial light-emitting pattern 23bi. It will be noted that in a case where the second cross-linked light-emitting material is formed by self-crosslinking of the second quantum dot material, the material for forming the second initial light-emitting pattern 23bi is the second quantum dot material. Alternatively, in a case where the second cross-linked light-emitting material is formed by crosslinking of the second quantum dot material and the fourth photosensitive material, the material for forming the second initial light-emitting pattern 23bi is the second quantum dot material and the fourth photosensitive material.

For example, as shown in FIG. 5, in a case where the first initial residual pattern 330 is residual on a side of the first electrode layer 21a away from the substrate 11, the second initial carrier transport layer 132i located on a side of the first electrode layer 21a is formed on a surface of the first initial residual pattern 330.

For example, as shown in FIG. 5, in a case where the first initial residual pattern 330 is residual on a side of the pixel defining layer 12 away from the substrate 11, the second initial carrier transport layer 132i located on a side of the pixel defining layer 12 is formed on a surface of the first initial residual pattern 330.

In N2, the second initial carrier transport layer 132i and the second initial light-emitting pattern 23bi that are stacked are exposed to convert a material of an exposed portion of the second initial carrier transport layer 132i into the second cross-linked carrier transport material, and convert a material of an exposed portion of the second initial light-emitting pattern 23bi into the second cross-linked light-emitting material.

It can be understood that the above exposed region is a region corresponding to at least one second light-emitting device 202. In this step, portions, in a region where the at least one second light-emitting device 202 is located, of the second initial carrier transport layer 132i and the second initial light-emitting pattern 23bi are exposed, so that solubilities of materials, in the region where the at least one second light-emitting device 202 is located, of the second initial carrier transport layer 132i and the second initial light-emitting pattern 23bi may be changed.

That is, in this case, a portion of the second initial carrier transport layer 132i located in the region where the second light-emitting device 202 is located is converted into the second cross-linked carrier transport material, and a material of a portion of the second initial carrier transport layer 132i located in the remaining region except the region where the second light-emitting device 202 is located remains unchanged and is still the material for forming the second initial carrier transport layer 132i. The second cross-linked carrier transport material is insoluble in a developer (the fifth solvent), and the material for forming the second initial carrier transport layer 132i is soluble in the developer (the fifth solvent).

A portion of the second initial light-emitting pattern 23bi located in the region where the second light-emitting device 202 is located is converted into the second cross-linked light-emitting material, and a material of a portion of the second initial light-emitting pattern 23bi located in the remaining region except the region where the second light-emitting device 202 is located remains unchanged and is still the material for forming the second initial light-emitting pattern 23bi. The second cross-linked light-emitting material is insoluble in a developer (the fourth solvent), and the material for forming the second initial light-emitting pattern 23bi is soluble in the developer (the fourth solvent).

It will be noted that as shown in FIG. 5, the second initial carrier transport layer 132i and the second initial light-emitting pattern 23bi are also formed on a side of the pixel defining layer 12 away from the substrate 11. Although FIG. 5 shows that thicknesses of the second initial carrier transport layer 132i and the second initial light-emitting pattern 23bi on the side of the pixel defining layer 12 away from the substrate 11 are inconsistent with thicknesses of the second initial carrier transport layer 132i and the second initial light-emitting pattern 23bi in the opening Q in the pixel defining layer 12, it is only indicated here that the second initial carrier transport layer 132i and the second initial light-emitting pattern 23bi exist on the side of the pixel defining layer 12 away from the substrate 11, and the thicknesses thereof are not limited.

In N3, the second initial carrier transport layer 132i and the second initial light-emitting pattern 23bi that are stacked are developed to form the second carrier transport layer 132 and the second light-emitting pattern 23b that are stacked.

For example, N3 may include the following two steps of development.

A portion of the second initial light-emitting pattern 23bi located in the remaining region, except the region where the second light-emitting device(s) 202 are located, in a region where the plurality of light-emitting devices 20 are located is removed using a developer (the fourth solvent) (a portion of the material for forming the second initial light-emitting pattern 23bi proximate to the substrate 11 has a residue to form a fourth temporary residual layer), while a portion of the second initial light-emitting pattern 23bi located in the region where the second light-emitting device(s) 202 are located is retained to obtain at least one second light-emitting pattern 23b.

A portion of the second initial carrier transport layer 132i located in the remaining region, except the region where the second light-emitting device(s) 202 are located, in a region where the plurality of light-emitting devices 20 are located is removed using a developer (the fifth solvent) (a portion of the material for forming the second initial carrier transport layer 132i proximate to the substrate 11 has a residue such as a second initial residual pattern 350a shown in FIG. 5, and an introduction to the second initial residual pattern 350a refers to subsequent contents and is not described in detail here), and a portion, located in the remaining region except the region where the second light-emitting device(s) 202 are located in a region where the plurality of light-emitting devices 20 are located, of the fourth temporary residual layer on the second initial carrier transport layer 132i is also removed, so as to avoid the residue of the material for forming the second initial light-emitting pattern 23bi in the remaining region, except the region where the second light-emitting device(s) 202 are located, in a region where the plurality of light-emitting devices 20 are located. Whereas, a portion of the second initial carrier transport layer 132i located in the region where the second light-emitting device(s) 202 are located is retained to obtain the second carrier transport layer 132 of at least one second light-emitting device 202.

It will be noted that after the second light-emitting pattern 23b is formed, the second initial residual pattern 350a also exists on the side of the pixel defining layer 12 away from the substrate 11.

Compared with the direct photolithography method used in the related art to achieve patterning of the quantum dot light-emitting materials, the materials that can undergo cross-linking reaction under light irradiation are provided as the material of the second sacrificial layer group 13B (i.e., the second carrier transport layer 132), so that the second sacrificial layer group 13B may be used as a sacrificial layer to remove the portion of the second quantum dot material located in the remaining region except the region where the second light-emitting device 202 is located, thereby preventing the second quantum dot material from forming residues in the remaining region except the region where the second light-emitting device 202 is located. In this way, the problem of color mixing, caused by the residue of the quantum dot light-emitting material (e.g., the second quantum dot light-emitting material) of the former color on a side of the light-emitting pattern of the latter color (e.g., the third light-emitting pattern 23c) proximate to the substrate 11 in the related art, may be solved; and the problem of color mixing, caused by the residue of the quantum dot light-emitting material (e.g., the second quantum dot light-emitting material) of the latter color on a side of the light-emitting pattern of the former color (e.g., the first light-emitting pattern 23a) away from the substrate 11 in the related art, may be solved.

In some embodiments, as shown in FIG. 3B, in a case where the second light-emitting device 202 includes a second light-emitting pattern 23b and a second sacrificial layer group 13B, and the second sacrificial layer group 13B includes a second carrier transport layer 132, the second sacrificial layer group 13B further includes a second carrier injection layer 142. The second carrier injection layer 142 is located on a side of the second carrier transport layer 132 proximate to the substrate, and a material of the second carrier injection layer 142 includes a second cross-linked carrier injection material.

For example, as shown in FIG. 3B, the second sacrificial layer group 13B is composed of the second carrier injection layer 142 and the second carrier transport layer 132, and the second carrier injection layer 142, the second carrier transport layer 132 and the second light-emitting pattern 23b are in contact in sequence. It will be noted that a thickness of the second carrier injection layer 142 is not limited here. For example, with the first thickness as a reference, the thickness of the second carrier injection layer 142 may be less than the first thickness, or equal to the first thickness, or greater than the first thickness.

In some examples, the second cross-linked carrier injection material is generated by cross-linking of the second carrier injection material under light radiation, and in this case, the second carrier injection material is a cross-linkable organic material. That is, the second carrier injection material in a region where the second light-emitting device 202 is located is exposed to achieve self-crosslinking of the second carrier injection material to form the second cross-linked carrier injection material, where a solubility of the second carrier injection material in a sixth solvent is greater than a solubility of the second cross-linked carrier injection material in the sixth solvent; and then, development is carried out, where the second cross-linked carrier injection material is insoluble in a developer (e.g., the sixth solvent) and the second carrier injection material is soluble in the developer, to remove a portion of the second carrier injection material in a remaining region except the region where the second light-emitting device 202 is located, so as to form a patterned second carrier injection layer 142.

In some other examples, the second cross-linked carrier injection material is generated by cross-linking of a second carrier injection material and a sixth photosensitive material under light radiation. That is, the second carrier injection material and the sixth photosensitive material in a region where the second light-emitting device 202 is located are exposed to achieve crosslinking of the second carrier injection material and the sixth photosensitive material to form the second cross-linked carrier injection material, where solubilities of the second carrier injection material and the sixth photosensitive material in a sixth solvent are greater than a solubility of the second cross-linked carrier injection material in the sixth solvent; and then, development is carried out, where the second cross-linked carrier injection material is insoluble in a developer (e.g., the sixth solvent), and the second carrier injection material and the sixth photosensitive material are soluble in the developer, to remove portions of the second carrier injection material and the sixth photosensitive material in a remaining region except the region where the second light-emitting device 202 is located, so as to form a patterned second carrier injection layer 142.

For example, the sixth solvent is a third-type solvent, and the third-type solvent includes at least one of water, ethanol, methanol, N,N-dimethylformamide, N-methylformamide and thionyl chloride.

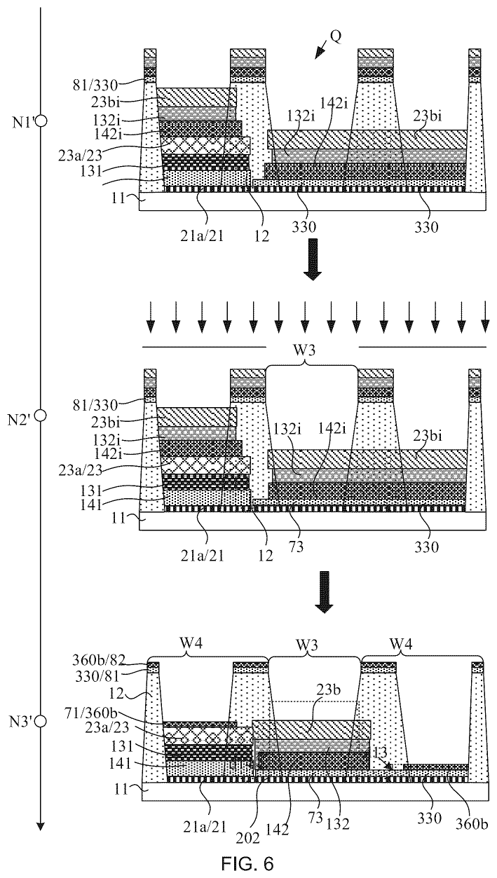

As shown in FIG. 6, in a case where the second sacrificial layer group 13B includes the second carrier transport layer 132 and the second carrier injection layer 142, a method for forming at least one second light-emitting device 202 includes, for example, N1′ to N3′.

In N1′, a second initial carrier injection layer 142i, a second initial carrier transport layer 132i and a second initial light-emitting pattern 23bi are sequentially formed on a side of the first electrode layer 21a and the at least one first light-emitting device 201 away from the substrate 11.

As for an exemplary introduction to the formation of the second initial carrier transport layer 132i and the second initial light-emitting pattern 23bi, reference may be made to the relevant contents of the aforementioned part N1, and details are not repeated here.

For example, a process for forming the second initial carrier injection layer 142i is any of spin coating, screen printing, scraping coating and drip coating, and a process solution is a sixth solution, where a solvent of the sixth solution is the sixth solvent, and a solute of the sixth solution is a material for forming the second initial carrier injection layer 142i. It will be noted that in a case where the second cross-linked carrier injection material is formed by self-crosslinking of the second carrier injection material, the material for forming the second initial carrier injection layer 142i is the second carrier injection material. Alternatively, in a case where the second cross-linked carrier injection material is formed by crosslinking of the second carrier injection material and the sixth photosensitive material, the material for forming the second initial carrier injection layer 142i is the second carrier injection material and the sixth photosensitive material.

For example, as shown in FIG. 6, in a case where the first initial residual pattern 330 is residual on a side of the first electrode layer 21a away from the substrate 11, the second initial carrier injection layer 142i located on a side of the first electrode layer 21a is formed on a surface of the first initial residual pattern 330.

For example, as shown in FIG. 6, in a case where the first initial residual pattern 330 is residual on a side of the pixel defining layer 12 away from the substrate 11, the second initial carrier injection layer 142i located on a side of the pixel defining layer 12 is formed on a surface of the first initial residual pattern 330.

In N2′, the second initial carrier injection layer 142i, the second initial carrier transport layer 132i and the second initial light-emitting pattern 23bi that are stacked are exposed to convert a material of an exposed portion of the second initial carrier injection layer 142i into the second cross-linked carrier injection material, convert a material of an exposed portion of the second initial carrier transport layer 132i into the second cross-linked carrier transport material, and convert a material of an exposed portion of the second initial light-emitting pattern 23bi into the second cross-linked light-emitting material.

It can be understood that the above exposed region is a region corresponding to at least one second light-emitting device 202. In this step, portions, in a region where the at least one second light-emitting device 202 is located, of the second initial carrier injection layer 142i, the second initial carrier transport layer 132i and the second initial light-emitting pattern 23bi are exposed, so that solubilities of materials, in the region where the at least one second light-emitting device 202 is located, of the second initial carrier injection layer 142i, the second initial carrier transport layer 132i and the second initial light-emitting pattern 23bi may be changed.

That is, in this case, a portion of the second initial carrier injection layer 142i located in the region where the second light-emitting device 202 is located is converted into the second cross-linked carrier injection material, and a material of a portion of the second initial carrier injection layer 142i located in the remaining region except the region where the second light-emitting device 202 is located remains unchanged and is still the material for forming the second initial carrier injection layer 142i. The second cross-linked carrier injection material is insoluble in a developer (the sixth solvent), and the material for forming the second initial carrier injection layer 142i is soluble in the developer (the sixth solvent). As for an exemplary introduction to the second initial carrier transport layer 132i and the second initial light-emitting pattern 23bi during exposure, reference may be made to the relevant contents of the aforementioned part N2, and details are not repeated here.

In N3′, the second initial carrier injection layer 142i, the second initial carrier transport layer 132i and the second initial light-emitting pattern 23bi that are stacked are developed to form the second carrier injection layer 142, the second carrier transport layer 132 and the second light-emitting pattern 23b that are stacked.

For example, N3′ may include the following three steps of development.

A portion of the second initial light-emitting pattern 23bi located in the remaining region, except the region where the second light-emitting device(s) 202 are located, in a region where the plurality of light-emitting devices 20 are located is removed using a developer (the fourth solvent) (a portion of the material for forming the second initial light-emitting pattern 23bi proximate to the substrate 11 has a residue to form a fourth temporary residual layer), while a portion of the second initial light-emitting pattern 23bi located in the region where the second light-emitting device(s) 202 are located is retained to obtain at least one second light-emitting pattern 23b.

A portion of the second initial carrier transport layer 132i located in the remaining region, except the region where the second light-emitting device(s) 202 are located, in a region where the plurality of light-emitting devices 20 are located is removed using a developer (the fifth solvent) (a portion of the material for forming the second initial carrier transport layer 132i proximate to the substrate 11 has a residue to form a fifth temporary residual layer), and a portion, located in the remaining region except the region where the second light-emitting device(s) 202 are located in a region where the plurality of light-emitting devices 20 are located, of the fourth temporary residual layer on the second initial carrier transport layer 132i is also removed, so as to avoid the residue of the material for forming the second initial light-emitting pattern 23bi in the remaining region, except the region where the second light-emitting device(s) 202 are located, in a region where the plurality of light-emitting devices 20 are located. Whereas, a portion of the second initial carrier transport layer 132i located in the region where the second light-emitting device(s) 202 are located is retained to obtain the second carrier transport layer 132 of at least one second light-emitting device 202.

A portion of the second initial carrier injection layer 142i located in the remaining region, except the region where the second light-emitting device(s) 202 are located, in a region where the plurality of light-emitting devices 20 are located is removed using a developer (the sixth solvent) (a portion of the material for forming the second initial carrier injection layer 142i proximate to the substrate 11 has a residue such as a second initial residual pattern 360b shown in FIG. 6, and an introduction to the second initial residual pattern 360b refers to subsequent contents and is not described in detail here), and the fifth temporary residual layer of the second carrier transport layer 132 located in the remaining region, except the region where the second light-emitting device(s) 202 are located, in a region where the plurality of light-emitting devices 20 are located is also removed, so as to avoid the residue of the material for forming the second carrier transport layer 132 in the remaining region, except the region where the second light-emitting device(s) 202 are located, in the region where the plurality of light-emitting devices 20 are located. Whereas, a portion of the second initial carrier injection layer 142i located in the region where the second light-emitting device(s) 202 are located is retained to obtain the second carrier injection layer 142 of at least one second light-emitting device 202.

It will be noted that after the second light-emitting pattern 23b is formed, the second initial residual pattern 360b also exists on the side of the pixel defining layer 12 away from the substrate 11.

Compared with the direct photolithography method used in the related art to achieve patterning of the quantum dot light-emitting materials, the materials that can undergo cross-linking reaction under light irradiation are provided as the material of the second sacrificial layer group 13B (i.e., the second carrier transport layer 132 and the second carrier injection layer 142). In this way, the second sacrificial layer group 13B may be used as double sacrificial layers to remove the portion of the second quantum dot material located in the remaining region except the region where the second light-emitting device 202 is located, thereby preventing the second quantum dot material from forming residues in the remaining region except the region where the second light-emitting device 202 is located. Thus, the problem of color mixing, caused by the residue of the quantum dot light-emitting material (e.g., the second quantum dot light-emitting material) of the former color on a side of the light-emitting pattern of the latter color (e.g., the third light-emitting pattern 23c) proximate to the substrate 11 in the related art, may be solved; and the problem of color mixing, caused by the residue of the quantum dot light-emitting material (e.g., the second quantum dot light-emitting material) of the latter color on a side of the light-emitting pattern of the former color (e.g., the first light-emitting pattern 23a) away from the substrate 11 in the related art, may be solved. In addition, the fifth temporary residual layer is a portion of the second initial carrier transport layer 132i, and the second initial carrier transport layer 132i is a film layer in contact with the second initial light-emitting pattern 23bi. Therefore, the above step of developing using a developer (the sixth solvent) may avoid the residue of the fifth temporary residual layer in the remaining region, except the region where the second light-emitting device(s) 202 are located, in a region where the plurality of light-emitting devices 20 are located, and in particular, avoid the residue of the fifth temporary residual layer in a region where remaining light-emitting devices except the second light-emitting device(s) 202 in the plurality of light-emitting devices 20 is located. Thus, the problem of color mixing may be further solved to avoid the impure light-emitting spectrum, and the device performance may be effectively improved.

The above is an exemplary introduction to the plurality of light-emitting devices 20 including at least one second light-emitting device 202. The following is an exemplary introduction to the plurality of light-emitting devices 20 including at least one third light-emitting device 203.

In some embodiments, as shown in FIGS. 3A to 3B, the plurality of light-emitting devices 20 further include at least one third light-emitting device 203. Each third light-emitting device 203 in the at least one third light-emitting device 203 includes a third light-emitting pattern 23c, and a third sacrificial layer group 13C disposed between the substrate 11 and the third light-emitting pattern 23c. The third sacrificial layer group 13C includes a third carrier transport layer 133. A material of the third light-emitting pattern 23c includes a third cross-linked light-emitting material; and a material of the third carrier transport layer 133 includes a third cross-linked carrier transport material.

For example, as shown in FIG. 3A, the third sacrificial layer group 13C is a third carrier transport layer 133, and the third carrier transport layer 133 is in contact with the third light-emitting pattern 23c. It will be noted that a thickness of the third carrier transport layer 133 is not limited here. For example, with the first thickness as a reference, the thickness of the third carrier transport layer 133 may be less than the first thickness, or equal to the first thickness, or greater than the first thickness.

For example, the third light-emitting device 203 is a light-emitting device for emitting blue light, and a third quantum dot material may be a blue quantum dot light-emitting material.

In some examples, the third cross-linked light-emitting material is generated by cross-linking of the third quantum dot material under light radiation, and in this case, the third quantum dot material is a cross-linkable organic material. For example, the third quantum dot material includes a third quantum dot body and a ligand material, and the ligand material is a cross-linkable organic material. That is, the third quantum dot material in a region where the third light-emitting device 203 is located is exposed to achieve self-crosslinking of the third quantum dot material to form the third cross-linked light-emitting material, where a solubility of the third quantum dot material in a seventh solvent is greater than a solubility of the third cross-linked light-emitting material in the seventh solvent; and then, development is carried out, where the third cross-linked light-emitting material is insoluble in a developer (e.g., the seventh solvent) and the third quantum dot material is soluble in the developer, to remove a portion of the third quantum dot material in a remaining region except the region where the third light-emitting device 203 is located, so as to form a patterned third light-emitting pattern 23c.

In some other examples, the third cross-linked light-emitting material is generated by cross-linking of a third quantum dot material and a seventh photosensitive material under light radiation. That is, the third quantum dot material and the seventh photosensitive material in a region where the third light-emitting device 203 is located are exposed to achieve crosslinking of the third quantum dot material and the seventh photosensitive material to form the third cross-linked light-emitting material, where solubilities of the third quantum dot material and the seventh photosensitive material in a seventh solvent are greater than a solubility of the third cross-linked light-emitting material in the seventh solvent; and then, development is carried out, where the third cross-linked light-emitting material is insoluble in a developer (e.g., the seventh solvent), and the third quantum dot material and the seventh photosensitive material are soluble in the developer, to remove portions of the third quantum dot material and the seventh photosensitive material in a remaining region except the region where the third light-emitting device 203 is located, so as to form a patterned third light-emitting pattern 23c.

For example, the seventh solvent is a first-type solvent, and the first-type solvent includes at least one of octane and propylene glycol methyl ether acetate (PMA).

In some examples, the third cross-linked carrier transport material is generated by cross-linking of a third carrier transport material under light radiation, and in this case, the third carrier transport material is a cross-linkable organic material. That is, the third carrier transport material in a region where the third light-emitting device 203 is located is exposed to achieve self-crosslinking of the third carrier transport material to form the third cross-linked carrier transport material, where a solubility of the third carrier transport material in an eighth solvent is greater than a solubility of the third cross-linked carrier transport material in the eighth solvent; and then, development is carried out, where the third cross-linked carrier transport material is insoluble in a developer (e.g., the eighth solvent) and the third carrier transport material is soluble in the developer, to remove a portion of the third carrier transport material in a remaining region except the region where the third light-emitting device 203 is located, so as to form a patterned third carrier transport layer 133.

In some other examples, the third cross-linked carrier transport material is generated by cross-linking of a third carrier transport material and an eighth photosensitive material under light radiation. That is, the third carrier transport material and the eighth photosensitive material in a region where the third light-emitting device 203 is located are exposed to achieve crosslinking of the third carrier transport material and the eighth photosensitive material to form the third cross-linked carrier transport material, where solubilities of the third carrier transport material and the eighth photosensitive material in an eighth solvent are greater than a solubility of the third cross-linked carrier transport material in the eighth solvent; and then, development is carried out, where the third cross-linked carrier transport material is insoluble in a developer (e.g., the eighth solvent), and the third carrier transport material and the eighth photosensitive material are soluble in the developer, to remove portions of the third carrier transport material and the eighth photosensitive material in a remaining region except the region where the third light-emitting device 203 is located, so as to form a patterned third carrier transport layer 133.

For example, the eighth solvent is a second-type solvent, and the second-type solvent includes at least one of toluene, chlorobenzene or (dichloromethyl)benzene.

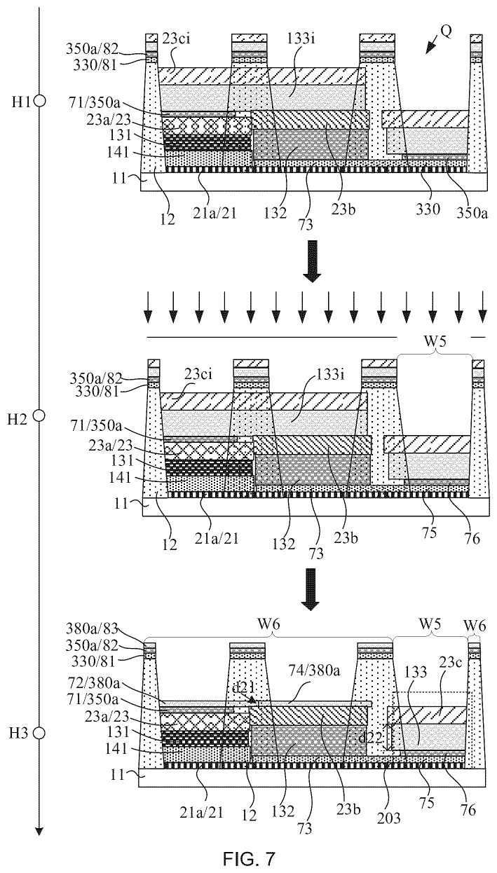

A method for forming at least one third light-emitting device 203 is exemplarily introduced below. As shown in FIG. 7, the method includes H1 to H3.

In H1, a third initial carrier transport layer 133i and a third initial light-emitting pattern 23ci are sequentially formed on a side of the first electrode layer 21a, the at least one first light-emitting device 201 and the at least one second light-emitting device 202 away from the substrate 11.

For example, a process for forming the third initial carrier transport layer 133i is any of spin coating, screen printing, scraping coating and drip coating, and a process solution is an eighth solution, where a solvent of the eighth solution is the eighth solvent, and a solute of the eighth solution is a material for forming the third initial carrier transport layer 133i. It will be noted that in a case where the third cross-linked carrier transport material is formed by self-crosslinking of the third carrier transport material, the material for forming the third initial carrier transport layer 133i is the third carrier transport material. Alternatively, in a case where the third cross-linked carrier transport material is formed by crosslinking of the third carrier transport material and the eighth photosensitive material, the material for forming the third initial carrier transport layer 133i is the third carrier transport material and the eighth photosensitive material.

For example, a process for forming the third initial light-emitting pattern 23ci is any of spin coating, screen printing, scraping coating and drip coating, and a process solution is a seventh solution, where a solvent of the seventh solution is the seventh solvent, and a solute of the seventh solution is a material for forming the third initial light-emitting pattern 23ci. It will be noted that in a case where the third cross-linked light-emitting material is formed by self-crosslinking of the third quantum dot material, the material for forming the third initial light-emitting pattern 23ci is the third quantum dot material. Alternatively, in a case where the third cross-linked light-emitting material is formed by crosslinking of the third quantum dot material and the seventh photosensitive material, the material for forming the third initial light-emitting pattern 23ci is the third quantum dot material and the seventh photosensitive material.

For example, as shown in FIG. 7, in a case where the second initial residual pattern 350a is residual on a side of the first electrode layer 21a and the at least one first light-emitting device 201 away from the substrate 11, the third initial carrier transport layer 133i located on a side of the first electrode layer 21a and the at least one first light-emitting device 201 is formed on a surface of the second initial residual pattern 350a.

For example, as shown in FIG. 7, in a case where the second initial residual pattern 350a is residual on a side of the pixel defining layer 12 away from the substrate 11, the third initial carrier transport layer 133i located on a side of the pixel defining layer 12 is formed on a surface of the second initial residual pattern 350a.

In H2, the third initial carrier transport layer 133i and the third initial light-emitting pattern 23ci that are stacked are exposed to convert a material of an exposed portion of the third initial carrier transport layer 133i into the third cross-linked carrier transport material, and convert a material of an exposed portion of the third initial light-emitting pattern 23ci into the third cross-linked light-emitting material.

It can be understood that the above exposed region is a region corresponding to at least one third light-emitting device 203. In this step, portions, in a region where the at least one third light-emitting device 203 is located, of the third initial carrier transport layer 133i and the third initial light-emitting pattern 23ci are exposed, so that solubilities of materials, in the region where the at least one third light-emitting device 203 is located, of the third initial carrier transport layer 133i and the third initial light-emitting pattern 23ci may be changed.

That is, in this case, a portion of the third initial carrier transport layer 133i located in the region where the third light-emitting device 203 is located is converted into the third cross-linked carrier transport material, and a material of a portion of the third initial carrier transport layer 133i located in the remaining region except the region where the third light-emitting device 203 is located remains unchanged and is still the material for forming the third initial carrier transport layer 133i. The third cross-linked carrier transport material is insoluble in a developer (the eighth solvent), and the material for forming the third initial carrier transport layer 133i is soluble in the developer (the fifth solvent).

A portion of the third initial light-emitting pattern 23ci located in the region where the third light-emitting device 203 is located is converted into the third cross-linked light-emitting material, and a material of a portion of the third initial light-emitting pattern 23ci located in the remaining region except the region where the third light-emitting device 203 is located remains unchanged and is still the material for forming the third initial light-emitting pattern 23ci. The third cross-linked light-emitting material is insoluble in a developer (the seventh solvent), and the material for forming the third initial light-emitting pattern 23ci is soluble in the developer (the seventh solvent).

It will be noted that as shown in FIG. 7, the third initial carrier transport layer 133i and the third initial light-emitting pattern 23ci are also formed on a side of the pixel defining layer 12 away from the substrate 11. Although FIG. 7 shows that thicknesses of the third initial carrier transport layer 133i and the third initial light-emitting pattern 23ci on the side of the pixel defining layer 12 away from the substrate 11 are inconsistent with thicknesses of the third initial carrier transport layer 133i and the third initial light-emitting pattern 23ci in the opening Q in the pixel defining layer 12, it is only indicated here that the third initial carrier transport layer 133i and the third initial light-emitting pattern 23ci exist on the side of the pixel defining layer 12 away from the substrate 11, and the thicknesses thereof are not limited.

In H3, the third initial carrier transport layer 133i and the third initial light-emitting pattern 23ci that are stacked are developed to form the third carrier transport layer 133 and the third light-emitting pattern 23b that are stacked.

For example, H3 may include the following two steps of development.

A portion of the third initial light-emitting pattern 23ci located in the remaining region, except the region where the third light-emitting device(s) 203 are located, in a region where the plurality of light-emitting devices 20 are located is removed using a developer (the seventh solvent) (a portion of the material for forming the third initial light-emitting pattern 23ci proximate to the substrate 11 has a residue to form a seventh temporary residual layer), while a portion of the third initial light-emitting pattern 23ci located in the region where the third light-emitting device(s) 203 are located is retained to obtain at least one third light-emitting pattern 23c.

A portion of the third initial carrier transport layer 133i located in the remaining region, except the region where the third light-emitting device(s) 203 are located, in a region where the plurality of light-emitting devices 20 are located is removed using a developer (the eighth solvent) (a portion of the material for forming the third initial carrier transport layer 133i proximate to the substrate 11 has a residue such as a third initial residual pattern 380a shown in FIG. 7, and an introduction to the third initial residual pattern 380a refers to subsequent contents and is not described in detail here), and a portion, located in the remaining region except the region where the third light-emitting device(s) 203 are located in a region where the plurality of light-emitting devices 20 are located, of the seventh temporary residual layer on the third initial carrier transport layer 133i is also removed, so as to avoid the residue of the material for forming the third initial light-emitting pattern 23ci in the remaining region, except the region where the third light-emitting device(s) 203 are located, in a region where the plurality of light-emitting devices 20 are located. Whereas, a portion of the third initial carrier transport layer 133i located in the region where the third light-emitting device(s) 203 are located is retained to obtain the third carrier transport layer 133 of at least one third light-emitting device 203.

It will be noted that after the third light-emitting pattern 23c is formed, the third initial residual pattern 380a also exists on the side of the pixel defining layer 12 away from the substrate 11.

Compared with the direct photolithography method used in the related art to achieve patterning of the quantum dot light-emitting materials, the materials that can undergo cross-linking reaction under light irradiation are provided as the material of the third sacrificial layer group 13C (i.e., the third carrier transport layer 133), so that the third sacrificial layer group 13C may be used as a sacrificial layer to remove the portion of the third quantum dot material located in the remaining region except the region where the third light-emitting device 203 is located, thereby preventing the third quantum dot material from forming residues in the remaining region except the region where the third light-emitting device 203 is located. In this way, the problem of color mixing, caused by the residue of the quantum dot light-emitting material (e.g., the third quantum dot light-emitting material) of the latter color on a side of the light-emitting pattern of the former color (e.g., the first light-emitting pattern 23a or the second light-emitting pattern 23b) away from the substrate 11 in the related art, may be solved.

In some embodiments, as shown in FIG. 3B, in a case where the third light-emitting device 203 includes a third light-emitting pattern 23c and a third sacrificial layer group 13C, and the third sacrificial layer group 13C includes a third carrier transport layer 133, the third sacrificial layer group 13C further includes a third carrier injection layer 143. The third carrier injection layer 143 is located on a side of the third carrier transport layer 133 proximate to the substrate 11, and a material of the third carrier injection layer 143 includes a third cross-linked carrier injection material.

For example, as shown in FIG. 3B, the third sacrificial layer group 13C is composed of the third carrier injection layer 143 and the third carrier transport layer 133, and the third carrier injection layer 143, the third carrier transport layer 133 and the third light-emitting pattern 23c are in contact in sequence. It will be noted that a thickness of the third carrier injection layer 143 is not limited here. For example, with the first thickness as a reference, the thickness of the third carrier injection layer 143 may be less than the first thickness, or equal to the first thickness, or greater than the first thickness.

In some examples, the third cross-linked carrier injection material is generated by cross-linking of the third carrier injection material under light radiation, and in this case, the third carrier injection material is a cross-linkable organic material. That is, the third carrier injection material in a region where the third light-emitting device 203 is located is exposed to achieve self-crosslinking of the third carrier injection material to form the third cross-linked carrier injection material, where a solubility of the third carrier injection material in a ninth solvent is greater than a solubility of the third cross-linked carrier injection material in the ninth solvent; and then, development is carried out, where the third cross-linked carrier injection material is insoluble in a developer (e.g., the ninth solvent) and the third carrier injection material is soluble in the developer, to remove a portion of the third carrier injection material in a remaining region except the region where the third light-emitting device 203 is located, so as to form a patterned third carrier injection layer 143.

In some other examples, the third cross-linked carrier injection material is generated by cross-linking of a third carrier injection material and a ninth photosensitive material under light radiation. That is, the third carrier injection material and the ninth photosensitive material in a region where the third light-emitting device 203 is located are exposed to achieve crosslinking of the third carrier injection material and the ninth photosensitive material to form the third cross-linked carrier injection material, where solubilities of the third carrier injection material and the ninth photosensitive material in a ninth solvent are greater than a solubility of the third cross-linked carrier injection material in the ninth solvent; and then, development is carried out, where the third cross-linked carrier injection material is insoluble in a developer (e.g., the ninth solvent), and the third carrier injection material and the ninth photosensitive material are soluble in the developer, to remove portions of the third carrier injection material and the ninth photosensitive material in a remaining region except the region where the third light-emitting device 203 is located, so as to form a patterned third carrier injection layer 143.

For example, the ninth solvent is a third-type solvent, and the third-type solvent includes at least one of water, ethanol, methanol, N,N-dimethylformamide, N-methylformamide and thionyl chloride.

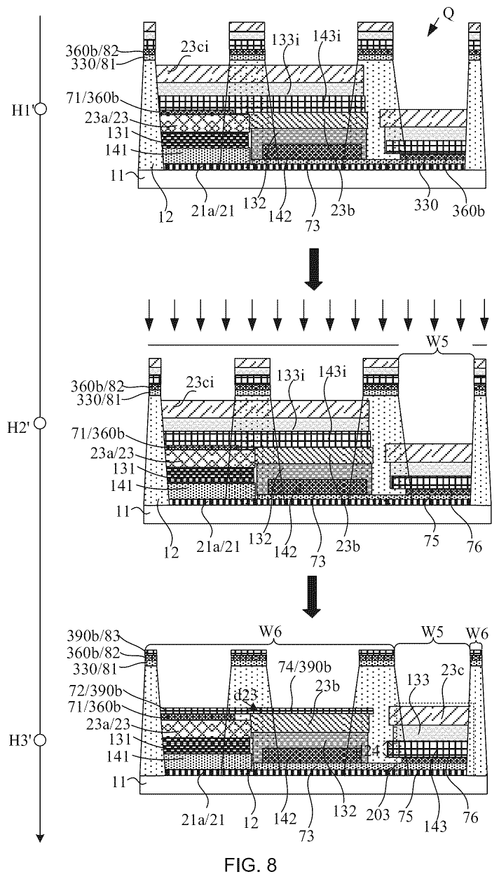

As shown in FIG. 8, in a case where the third sacrificial layer group 13C includes the third carrier transport layer 133 and the third carrier injection layer 143, a method for forming at least one third light-emitting device 203 includes, for example, H1′ to H3′.

In H1′, a third initial carrier injection layer 143i, a third initial carrier transport layer 133i and a third initial light-emitting pattern 23ci are sequentially formed on a side of the first electrode layer 21a, the at least one first light-emitting device 201 and the at least one second light-emitting device 202 away from the substrate 11.

As for an exemplary introduction to the formation of the third initial carrier transport layer 133i and the third initial light-emitting pattern 23ci, reference may be made to the relevant contents of the aforementioned part H1, and details are not repeated here.

For example, a process for forming the third initial carrier injection layer 143i is any of spin coating, screen printing, scraping coating and drip coating, and a process solution is a ninth solution, where a solvent of the ninth solution is the ninth solvent, and a solute of the ninth solution is a material for forming the third initial carrier injection layer 143i. It will be noted that in a case where the third cross-linked carrier injection material is formed by self-crosslinking of the third carrier injection material, the material for forming the third initial carrier injection layer 143i is the third carrier injection material. Alternatively, in a case where the third cross-linked carrier injection material is formed by crosslinking of the third carrier injection material and the ninth photosensitive material, the material for forming the third initial carrier injection layer 143i is the third carrier injection material and the ninth photosensitive material.

For example, as shown in FIG. 8, in a case where the second initial residual pattern 360b is residual on a side of the first electrode layer 21a and the at least one first light-emitting device 201 away from the substrate 11, the third initial carrier injection layer 143i located on a side of the first electrode layer 21a and the at least one first light-emitting device 201 is formed on a surface of the second initial residual pattern 360b.

For example, as shown in FIG. 8, in a case where the second initial residual pattern 360b is residual on a side of the pixel defining layer 12 away from the substrate 11, the third initial carrier injection layer 143i located on a side of the pixel defining layer 12 is formed on a surface of the second initial residual pattern 360b.

In H2′, the third initial carrier injection layer 143i, the third initial carrier transport layer 133i and the third initial light-emitting pattern 23ci that are stacked are exposed to convert a material of an exposed portion of the third initial carrier injection layer 143i into the third cross-linked carrier injection material, convert a material of an exposed portion of the third initial carrier transport layer 133i into the third cross-linked carrier transport material, and convert a material of an exposed portion of the third initial light-emitting pattern 23ci into the third cross-linked light-emitting material.

It can be understood that the above exposed region is a region corresponding to at least one third light-emitting device 203. In this step, portions, in a region where the at least one third light-emitting device 203 is located, of the third initial carrier injection layer 143i, the third initial carrier transport layer 133i and the third initial light-emitting pattern 23ci are exposed, so that solubilities of materials, in the region where the at least one third light-emitting device 203 is located, of the third initial carrier injection layer 143i, the third initial carrier transport layer 133i and the third initial light-emitting pattern 23ci may be changed.

That is, in this case, a portion of the third initial carrier injection layer 143i located in the region where the third light-emitting device 203 is located is converted into the third cross-linked carrier injection material, and a material of a portion of the third initial carrier injection layer 143i located in the remaining region except the region where the third light-emitting device 203 is located remains unchanged and is still the material for forming the third initial carrier injection layer 143i. The third cross-linked carrier injection material is insoluble in a developer (the ninth solvent), and the material for forming the third initial carrier injection layer 143i is soluble in the developer (the ninth solvent). As for an exemplary introduction to the third initial carrier transport layer 133i and the third initial light-emitting pattern 23ci during exposure, reference may be made to the relevant contents of the aforementioned part H2, and details are not repeated here.

In H3′, the third initial carrier injection layer 143i, the third initial carrier transport layer 133i and the third initial light-emitting pattern 23ci that are stacked are developed to form the third carrier injection layer 143, the third carrier transport layer 133 and the third light-emitting pattern 23c that are stacked.

For example, H3′ may include the following three steps of development.

A portion of the third initial light-emitting pattern 23ci located in the remaining region, except the region where the third light-emitting device(s) 203 are located, in a region where the plurality of light-emitting devices 20 are located is removed using a developer (the seventh solvent) (a portion of the material for forming the third initial light-emitting pattern 23ci proximate to the substrate 11 has a residue to form a seventh temporary residual layer), while a portion of the third initial light-emitting pattern 23ci located in the region where the third light-emitting device(s) 203 are located is retained to obtain at least one third light-emitting pattern 23c.

A portion of the third initial carrier transport layer 133i located in the remaining region, except the region where the third light-emitting device(s) 203 are located, in a region where the plurality of light-emitting devices 20 are located is removed using a developer (the eighth solvent) (a portion of the material for forming the third initial carrier transport layer 133i proximate to the substrate 11 has a residue to form an eighth temporary residual layer), and a portion, located in the remaining region except the region where the third light-emitting device(s) 203 are located in a region where the plurality of light-emitting devices 20 are located, of the seventh temporary residual layer on the third initial carrier transport layer 133i is also removed, so as to avoid the residue of the material for forming the third initial light-emitting pattern 23ci in the remaining region, except the region where the third light-emitting device(s) 203 are located, in a region where the plurality of light-emitting devices 20 are located. Whereas, a portion of the third initial carrier transport layer 133i located in the region where the third light-emitting device(s) 203 are located is retained to obtain the third carrier transport layer 133 of at least one third light-emitting device 203.

A portion of the third initial carrier injection layer 143i located in the remaining region, except the region where the third light-emitting device(s) 203 are located, in a region where the plurality of light-emitting devices 20 are located is removed using a developer (the ninth solvent) (a portion of the material for forming the third initial carrier injection layer 143i proximate to the substrate 11 has a residue such as a third initial residual pattern 390b shown in FIG. 8, and an introduction to the third initial residual pattern 390b refers to subsequent contents and is not described in detail here), and the eighth temporary residual layer of the third carrier transport layer 133 located in the remaining region, except the region where the third light-emitting device(s) 203 are located, in a region where the plurality of light-emitting devices 20 are located is also removed, so as to avoid the residue of the material for forming the third carrier transport layer 133 in the remaining region, except the region where the third light-emitting device(s) 203 are located, in the region where the plurality of light-emitting devices 20 are located. Whereas, a portion of the third initial carrier injection layer 143i located in the region where the third light-emitting device(s) 203 are located is retained to obtain the third carrier injection layer 143 of at least one third light-emitting device 203.

It will be noted that after the third light-emitting pattern 23c is formed, the third initial residual pattern 390b also exists on the side of the pixel defining layer 12 away from the substrate 11.

Compared with the direct photolithography method used in the related art to achieve patterning of the quantum dot light-emitting materials, the materials that can undergo cross-linking reaction under light irradiation are provided as the material of the third sacrificial layer group 13C (i.e., the third carrier transport layer 133 and the third carrier injection layer 143). In this way, the third sacrificial layer group 13C may be used as double sacrificial layers to remove the portion of the third quantum dot material located in the remaining region except the region where the third light-emitting device 203 is located, thereby preventing the third quantum dot material from forming residues in the remaining region except the region where the third light-emitting device 203 is located. Thus, the problem of color mixing, caused by the residue of the quantum dot light-emitting material (e.g., the third quantum dot light-emitting material) of the latter color on a side of the light-emitting pattern of the former color (e.g., the first light-emitting pattern 23a or the second light-emitting pattern 23c) away from the substrate 11 in the related art, may be solved. In addition, the eighth temporary residual layer is a portion of the third initial carrier transport layer 133i, and the third initial carrier transport layer 133i is a film layer in contact with the third initial light-emitting pattern 23ci. Therefore, the above step of developing using a developer (the ninth solvent) may avoid the residue of the eighth temporary residual layer in the remaining region, except the region where the third light-emitting device(s) 203 are located, in a region where the plurality of light-emitting devices 20 are located, and in particular, avoid the residue of the eighth temporary residual layer in a region where remaining light-emitting devices except the third light-emitting device(s) 203 in the plurality of light-emitting devices 20 is located. Thus, the problem of color mixing may be further solved to avoid the impure light-emitting spectrum, and the device performance may be effectively improved.

In some embodiments, the first carrier transport layer 131, the second carrier transport layer 132 and the third carrier transport layer 133 are hole transport layers, and the first carrier injection layer 141, the second carrier injection layer 142 and the third carrier injection layer 143 are hole injection layers. In this case, the first electrode 21 is an anode and the second electrode 22 is a cathode. The light-emitting device 20 is an “upright” light-emitting device. In this case, the front film layer of the hole injection layer is the anode. The anode formed by magnetron sputtering has a high density and is insoluble in organic solvents. In this way, tolerance of the “upright” light-emitting device to solvent immersion and development during formation may be improved.

In some other embodiments, the first carrier transport layer 131, the second carrier transport layer 132 and the third carrier transport layer 133 are electron transport layers, and the first carrier injection layer 141, the second carrier injection layer 142 and the third carrier injection layer 143 are electron injection layers. In this case, the first electrode 21 is a cathode and the second electrode 22 is an anode. The light-emitting device 20 is an “inverted” light-emitting device.

In some embodiments, as shown in FIGS. 3A to 3B, at least one first light-emitting device 201 is configured to emit light of a first wavelength. For example, the light of the first wavelength is red light. Each first light-emitting device 201 of the at least one first light-emitting devices 201 further includes a first pattern layer 71 and a second pattern layer 72. The first pattern layer 71 is disposed on a side of the first light-emitting pattern 23a away from the substrate 11, the second pattern layer 72 is disposed on a side of the first pattern layer 71 away from the substrate 11, and the first light-emitting pattern 23a, the first pattern layer 71 and the second pattern layer 72 are in contact in sequence.

For example, as shown in FIG. 5, in a case where the second sacrificial layer group 13B is the second carrier transport layer 132, the first pattern layer 71 is a second initial residual pattern 350a formed by developing a portion of the second initial carrier transport layer 132i in a region where the first light-emitting device 201 is located. Therefore, a material for forming the first pattern layer 71 is the same as the material of the second initial residual pattern 350a. Moreover, as shown in FIGS. 5 and 7, since a portion of the second initial carrier transport layer 132i corresponding to the first pattern layer 71 is not exposed during formation of at least one second light-emitting device 202 and at least one third light-emitting device 203, the material of the first pattern layer 71 is also the same as the material of the second initial carrier transport layer 132i.

That is, in a case where the second cross-linked carrier transport material is generated by cross-linking of the second carrier transport material under light radiation, the material of the first pattern layer 71 includes the second carrier transport material. In a case where the second cross-linked carrier transport material is generated by cross-linking of the second carrier transport material and the fifth photosensitive material under light radiation, the material of the first pattern layer 71 includes the second carrier transport material and the fifth photosensitive material.

A portion, after exposure and development, of the second initial carrier transport layer 132i located in a region where the second light-emitting device 202 is located forms the second carrier transport layer 132 of the second light-emitting device 202; and a portion of the second initial carrier transport layer 132i located in a region where the first light-emitting device 201 is located is washed away during development to form the second initial residual pattern 350a. Therefore, a thickness d11 of the second initial residual pattern 350a is smaller than a thickness d12 of the second carrier transport layer 132. Therefore, a thickness of the first pattern layer 71 (which is equal to the thickness d11 of the second initial residual pattern 350a) is smaller than the thickness d12 of the second carrier transport layer 132.

For example, as shown in FIG. 6, in a case where the second sacrificial layer group 13B is the second carrier transport layer 132 and the second carrier injection layer 142, the first pattern layer 71 is a second initial residual pattern 360b formed by developing a portion of the second initial carrier injection layer 142i in a region where the first light-emitting device 201 is located. Therefore, a material for forming the first pattern layer 71 is the same as the material of the second initial residual pattern 360b. Moreover, as shown in FIGS. 6 and 8, since a portion of the second initial carrier injection layer 142i corresponding to the first pattern layer 71 is not exposed during formation of at least one second light-emitting device 202 and at least one third light-emitting device 203, the material of the first pattern layer 71 is also the same as the material of the second initial carrier injection layer 142i.

That is, in a case where the second cross-linked carrier injection material is generated by cross-linking of the second carrier injection material under light radiation, the material of the first pattern layer 71 includes the second carrier injection material. In a case where the second cross-linked carrier injection material is generated by cross-linking of the second carrier injection material and the sixth photosensitive material under light radiation, the material of the first pattern layer 71 includes the second carrier injection material and the sixth photosensitive material.

A portion, after exposure and development, of the second initial carrier injection layer 142i located in a region where the second light-emitting device 202 is located forms the second carrier injection layer 142 of the second light-emitting device 202; and a portion of the second initial carrier injection layer 142i located in a region where the first light-emitting device 201 is located is washed away during development to form the second initial residual pattern 360b. Therefore, a thickness d13 of the second initial residual pattern 360b is smaller than a thickness d14 of the second carrier injection layer 142. Therefore, a thickness of the first pattern layer 71 (which is equal to the thickness d13 of the second initial residual pattern 360b) is smaller than the thickness d14 of the second carrier injection layer 142.

For example, as shown in FIG. 7, in a case where the third sacrificial layer group 13C is the third carrier transport layer 133, the second pattern layer 72 is a third initial residual pattern 380a formed by developing a portion of the third initial carrier transport layer 133i in a region where the first light-emitting device 201 is located. Therefore, a material for forming the second pattern layer 72 is the same as the material of the third initial residual pattern 380a. Moreover, as shown in FIG. 7, since a portion of the third initial carrier transport layer 133i corresponding to the third initial residual pattern 380a is not exposed during formation of at least one third light-emitting device 203, a material of the second pattern layer 72 is also the same as the material of the third initial carrier transport layer 133i.

That is, in a case where the third cross-linked carrier transport material is generated by cross-linking of the third carrier transport material under light radiation, the material of the second pattern layer 72 includes the third carrier transport material. In a case where the third cross-linked carrier transport material is generated by cross-linking of the third carrier transport material and the eighth photosensitive material under light radiation, the material of the second pattern layer 72 includes the third carrier transport material and the eighth photosensitive material.

A portion, after exposure and development, of the third initial carrier transport layer 133i located in a region where the third light-emitting device 203 is located forms the third carrier transport layer 133 of the third light-emitting device 203; and a portion of the third initial carrier transport layer 133i located in a region where the first light-emitting device 201 is located is washed away during development to form a third initial residual pattern 380a. Therefore, a thickness d21 of the third initial residual pattern 380a is smaller than a thickness d22 of the third carrier transport layer 133. Therefore, a thickness of the second pattern layer 72 (which is equal to the thickness d21 of the third initial residual pattern 380a) is smaller than the thickness d22 of the third carrier transport layer 133.

It will be noted that in a case where the second sacrificial layer group 13B is the second carrier transport layer 132, and the third sacrificial layer group 13C is the third carrier transport layer 133, if a second carrier transport material of the first pattern layer 71 is the same as a third carrier transport material of the second pattern layer 72, and a fifth photosensitive material of the first pattern layer 71 is the same as an eighth photosensitive material of the second pattern layer 72, the first pattern layer 71 and the second pattern layer 72 have the same materials in the region where the first light-emitting device 201 is located, the first pattern layer 71 and the second pattern layer 72 may be regarded as one layer, and the thickness of the layer is (d11+d21).

It can be understood that as shown in FIG. 3A, in a case where the second carrier transport layer 132 and the third carrier transport layer 133 are hole transport layers, in the region where the first light-emitting device 201 is located, the first pattern layer 71 and the second pattern layer 72 may serve as an electron blocking layer of the first light-emitting device 201 and are used to improve electron injection of the first light-emitting device 201 and enhance an efficiency of the light-emitting device 20.

For example, as shown in FIG. 8, in a case where the third sacrificial layer group 13C is the third carrier transport layer 133 and the third carrier injection layer 143, the second pattern layer 72 is a third initial residual pattern 390b formed by developing a portion of the third initial carrier injection layer 143i in a region where the first light-emitting device 201 is located. Therefore, a material for forming the second pattern layer 72 is the same as the material of the third initial residual pattern 390b. Moreover, as shown in FIG. 8, since a portion of the third initial carrier injection layer 143i corresponding to the third initial residual pattern 390b is not exposed during formation of at least one third light-emitting device 203, the material of the second pattern layer 72 is also the same as the material of the third initial carrier injection layer 143i.

That is, in a case where the third cross-linked carrier injection material is generated by cross-linking of the third carrier injection material under light radiation, the material of the second pattern layer 72 includes the third carrier injection material. In a case where the third cross-linked carrier injection material is generated by cross-linking of the third carrier injection material and the ninth photosensitive material under light radiation, the material of the second pattern layer 72 includes the third carrier injection material and the ninth photosensitive material.

A portion, after exposure and development, of the third initial carrier injection layer 143i located in a region where the third light-emitting device 203 is located forms the third carrier injection layer 143 of the third light-emitting device 203; and a portion of the third initial carrier injection layer 143i located in a region where the first light-emitting device 201 is located is washed away during development to form a third initial residual pattern 390b. Therefore, a thickness d23 of the third initial residual pattern 390b is smaller than a thickness d24 of the third carrier injection layer 143. Therefore, a thickness of the second pattern layer 72 (which is equal to the thickness d23 of the third initial residual pattern 390b) is smaller than the thickness d24 of the third carrier injection layer 143.

It will be noted that in a case where the second sacrificial layer group 13B is the second carrier transport layer 132 and the second carrier injection layer 142, and the third sacrificial layer group 13C is the third carrier transport layer 133 and the third carrier injection layer 143, if a second carrier injection material of the first pattern layer 71 is the same as a third carrier injection material of the second pattern layer 72, and a sixth photosensitive material of the first pattern layer 71 is the same as a ninth photosensitive material of the second pattern layer 72, the first pattern layer 71 and the second pattern layer 72 have the same materials in the region where the first light-emitting device 201 is located, the first pattern layer 71 and the second pattern layer 72 may be regarded as one layer, and the thickness of the layer is (d13+d23).

It can be understood that as shown in FIG. 3B, in a case where the second carrier injection layer 142 and the third carrier injection layer 143 are hole injection layers, in the region where the first light-emitting device 201 is located, the first pattern layer 71 and the second pattern layer 72 may serve as an electron blocking layer of the first light-emitting device 201, and are used to improve electron injection of the first light-emitting device 201 and enhance an efficiency of the light-emitting device 20.

For example, since differences between HOMO (highest occupied molecular orbital) energy levels of the red quantum dot light-emitting material, the green quantum dot light-emitting material and the blue quantum dot light-emitting material and the HOMO energy level of the carrier transport material increase, the hole injection capability is expressed as red light-emitting device R>green light-emitting device G>blue light-emitting device B, and the electron injection capability is expressed as red light-emitting device R=green light-emitting device G>blue light-emitting device B. The electron injection capability of the red light-emitting device R is greater than the hole injection capability of the red light-emitting device R. Therefore, in a case where at least one first light-emitting device 201 is configured to emit light of a first wavelength, and the light of the first wavelength is red light, as shown in FIGS. 3A and 3B, the first pattern layer 71 and the second pattern layer 72 residual on the side of the first light-emitting device 201 away from the substrate 11 may effectively block injection of electrons, so that transmission of carriers (including electrons and holes) of the first light-emitting device 201 (the red light-emitting device R) may be balanced, which is beneficial to improving an external quantum efficiency of the light-emitting device 20.

In some embodiments, as shown in FIGS. 3A to 3B, at least one second light-emitting device 202 is configured to emit light of a second wavelength. For example, the light of the second wavelength is green light. At least one second light-emitting device 202 further includes a third pattern layer 73 and a fourth pattern layer 74. The third pattern layer 73 is disposed on a side of the second sacrificial layer group 13B proximate to the substrate 11, the fourth pattern layer 74 is disposed on a side of the second light-emitting pattern 23b away from the substrate 11, and the third pattern layer 73, the second sacrificial layer group 13B, the second light-emitting pattern 23b and the fourth pattern layer 74 are in contact in sequence.

For example, as shown in FIG. 4, the third pattern layer 73 is formed by exposing (exposure of the second light-emitting device 202) a first initial residual pattern 330 that is formed by developing a portion of the first initial carrier injection layer 141i in a region where the second light-emitting device 202 is located. Therefore, the third pattern layer 73 and the first carrier injection layer 141 are made of the same materials, which are the first cross-linked carrier injection material.

A portion, after exposure and development, of the first initial carrier injection layer 141i located in a region where the first light-emitting device 201 is located forms the first carrier injection layer 141 of the first light-emitting device 201; and a portion of the first initial carrier injection layer 141i located in a region where the second light-emitting device 202 is located is washed away during development to form the first initial residual pattern 330. Therefore, a thickness d31 of the first initial residual pattern 330 is smaller than a thickness d32 of the first carrier injection layer 141. Therefore, a thickness of the third pattern layer 73 (which is equal to the thickness d31 of the first initial residual pattern 330) is smaller than the thickness d32 of the first carrier injection layer 141.

It can be understood that as shown in FIG. 3B, in the region where the second light-emitting device 202 is located, since the third pattern layer 73 is the first initial residual pattern 330 formed by developing the first initial carrier injection layer 141i, the third pattern layer 73 may serve as at least part of a hole injection layer of the second light-emitting device 202, and is used to improve hole injection of the second light-emitting device 202 and enhance an efficiency of the light-emitting device 20.

For example, as shown in FIG. 7, in a case where the third sacrificial layer group 13C is the third carrier transport layer 133, the fourth pattern layer 74 is a third initial residual pattern 380a formed by developing a portion of the third initial carrier transport layer 133i in a region where the second light-emitting device 202 is located. Therefore, a material for forming the fourth pattern layer 74 is the same as the material of the third initial residual pattern 380a. Moreover, as shown in FIG. 7, since a portion of the third initial carrier transport layer 133i corresponding to the third initial residual pattern 380a is not exposed during formation of at least one third light-emitting device 203, the material of the fourth pattern layer 74 is also the same as the material of the third initial carrier transport layer 133i.

That is, in a case where the third cross-linked carrier transport material is generated by cross-linking of the third carrier transport material under light radiation, the material of the fourth pattern layer 74 includes the third carrier transport material. In a case where the third cross-linked carrier transport material is generated by cross-linking of the third carrier transport material and the eighth photosensitive material under light radiation, the material of the fourth pattern layer 74 includes the third carrier transport material and the eighth photosensitive material.

A portion, after exposure and development, of the third initial carrier transport layer 133i located in a region where the third light-emitting device 203 is located forms the third carrier transport layer 133 of the third light-emitting device 203; and a portion of the third initial carrier transport layer 133i located in a region where the second light-emitting device 202 is located is washed away during development to form the third initial residual pattern 380a. Therefore, a thickness d21 of the third initial residual pattern 380a is smaller than a thickness d22 of the third carrier transport layer 133. Therefore, a thickness of the fourth pattern layer 74 (which is equal to the thickness d21 of the third initial residual pattern 380a) is smaller than a thickness d22 of the third carrier transport layer 133.

It can be understood that as shown in FIG. 3A, in a case where the third carrier transport layer 133 is a hole transport layer, in the region where the second light-emitting device 202 is located, the fourth pattern layer 74 may serve as an electron blocking layer of the second light-emitting device 202, and is used to improve electron injection of the second light-emitting device 202 and enhance an efficiency of the light-emitting device 20.

For example, as shown in FIG. 8, in a case where the third sacrificial layer group 13C is the third carrier transport layer 133 and the third carrier injection layer 143, the fourth pattern layer 74 is a third initial residual pattern 390b formed by developing a portion of the third initial carrier injection layer 143i in a region where the second light-emitting device 202 is located. Therefore, a material for forming the fourth pattern layer 74 is the same as the material of the third initial residual pattern 390b. Moreover, as shown in FIG. 8, since a portion of the third initial carrier injection layer 143i corresponding to the third initial residual pattern 390b is not exposed during formation of at least one third light-emitting device 203, the material of the fourth pattern layer 74 is also the same as the material of the third initial carrier injection layer 143i.

That is, in a case where the third cross-linked carrier injection material is generated by cross-linking of the third carrier injection material under light radiation, the material of the fourth pattern layer 74 includes the third carrier injection material. In a case where the third cross-linked carrier injection material is generated by cross-linking of the third carrier injection material and the ninth photosensitive material under light radiation, the material of the fourth pattern layer 74 includes the third carrier injection material and the ninth photosensitive material.

A portion, after exposure and development, of the third initial carrier injection layer 143i located in a region where the third light-emitting device 203 is located forms the third carrier injection layer 143 of the third light-emitting device 203; and a portion of the third initial carrier injection layer 143i located in a region where the second light-emitting device 202 is located is washed away during development to form the third initial residual pattern 390b. Therefore, a thickness d23 of the third initial residual pattern 390b is smaller than a thickness d24 of the third carrier injection layer 143. Therefore, a thickness of the fourth pattern layer 74 (which is equal to the thickness d23 of the third initial residual pattern 390b) is smaller than a thickness d24 of the third carrier injection layer 143.

It can be understood that as shown in FIG. 3B, in a case where the third carrier injection layer 143 is a hole injection layer, in the region where the second light-emitting device 202 is located, the fourth pattern layer 74 may serve as an electron blocking layer of the second light-emitting device 202, and is used to improve electron injection of the second light-emitting device 202 and enhance an efficiency of the light-emitting device 20.

In some embodiments, as shown in FIGS. 3A to 3B, at least one third light-emitting device 203 is configured to emit light of a third wavelength. For example, the light of the third wavelength is blue light. At least one third light-emitting device 203 further includes a fifth pattern layer 75 and a sixth pattern layer 76. The sixth pattern layer 76 is disposed on a side of the third sacrificial layer group 13C proximate to the substrate 11, the fifth pattern layer 75 is disposed on a side of the sixth pattern layer 76 proximate to the substrate, and the third sacrificial layer group 13C, the sixth pattern layer 76 and the fifth pattern layer 75 are in contact in sequence.

For example, as shown in FIG. 4, the fifth pattern layer 75 is formed by exposing (exposure of the third light-emitting device 203) a first initial residual pattern 330 that is formed by developing a portion of the first initial carrier injection layer 141i in a region where the third light-emitting device 203 is located. Therefore, the fifth pattern layer 75 and the first carrier injection layer 141 are made of the same materials, which are the first cross-linked carrier injection material.

A portion, after exposure and development, of the first initial carrier injection layer 141i located in a region where the first light-emitting device 201 is located forms the first carrier injection layer 141 of the first light-emitting device 201; and a portion of the first initial carrier injection layer 141i located in a region where the third light-emitting device 203 is located is washed away during development to form the first initial residual pattern 330. Therefore, a thickness d31 of the first initial residual pattern 330 is smaller than a thickness d32 of the first carrier injection layer 141. Therefore, a thickness of the fifth pattern layer 75 (which is equal to the thickness d31 of the first initial residual pattern 330) is smaller than the thickness d32 of the first carrier injection layer 141.

For example, as shown in FIG. 5, in a case where the second sacrificial layer group 13B is the second carrier transport layer 132, the sixth pattern layer 76 is formed by exposing (exposure of the third light-emitting device 203) a second initial residual pattern 350a formed by developing a portion of the second initial carrier transport layer 132i in a region where the third light-emitting device 203 is located. Therefore, the sixth pattern layer 76 and the second carrier transport layer 132 are made of the same materials, which are the second cross-linked carrier transport material.

A portion, after exposure and development, of the second initial carrier transport layer 132i located in a region where the second light-emitting device 202 is located forms the second carrier transport layer 132 of the second light-emitting device 202; and a portion of the second initial carrier transport layer 132i located in a region where the third light-emitting device 203 is located is washed away during development to form the second initial residual pattern 350a. Therefore, a thickness d11 of the second initial residual pattern 350a is smaller than a thickness d12 of the second carrier transport layer 132. Therefore, a thickness of the sixth pattern layer 76 (which is equal to the thickness d11 of the second initial residual pattern 350a) is smaller than the thickness d12 of the second carrier transport layer 132.

For example, as shown in FIG. 6, in a case where the second sacrificial layer group 13B is the second carrier transport layer 132 and the second carrier injection layer 142, the sixth pattern layer 76 is formed by exposing (exposure of the third light-emitting device 203) a second initial residual pattern 360b formed by developing a portion of the second initial carrier injection layer 142i in a region where the third light-emitting device 203 is located. Therefore, the sixth pattern layer 76 and the second carrier injection layer 142 are made of the same materials, which are the second cross-linked carrier injection material.

A portion, after exposure and development, of the second initial carrier injection layer 142i located in a region where the second light-emitting device 202 is located forms the second carrier injection layer 142 of the second light-emitting device 202; and a portion of the second initial carrier injection layer 142i located in a region where the third light-emitting device 203 is located is washed away during development to form the second initial residual pattern 360b. Therefore, a thickness d13 of the second initial residual pattern 360b is smaller than a thickness d14 of the second carrier injection layer 142. Therefore, a thickness of the sixth pattern layer 76 (which is equal to the thickness d13 of the second initial residual pattern 360b) is smaller than the thickness d14 of the second carrier injection layer 142.

It can be understood that as shown in FIG. 3B, in the region where the third light-emitting device 203 is located, in a case where the material of the fifth pattern layer 75 is the first carrier injection material and the material of the sixth pattern layer 76 is the second carrier injection material, the fifth pattern layer 75 and the sixth pattern layer 76 may serve as part of a hole injection layer of the third light-emitting device 203, and is used to improve hole injection of the third light-emitting device 203 and enhance an efficiency of the light-emitting device 20.

In some embodiments, the light-emitting substrate 1 further includes a pixel defining layer 12. The pixel defining layer 12 is provided with a plurality of openings Q therein, and the plurality of light-emitting devices 20 are disposed in the plurality of openings Q in one-to-one correspondence. A seventh pattern layer 81, an eighth pattern layer 82 and a ninth pattern layer 83 are provided on a side of the pixel defining layer 12 away from the substrate 11. The seventh pattern layer 81, the eighth pattern layer 82 and the ninth pattern layer 83 are sequentially disposed in a direction from the substrate 11 to the pixel defining layer 12, and the seventh pattern layer 81, the eighth pattern layer 82 and the ninth pattern layer 83 are in contact in sequence.

For example, as shown in FIG. 4, the seventh pattern layer 81 is a first initial residual pattern 330 formed by developing a portion of the first initial carrier injection layer 141i located in a region where the pixel defining layer 12 is located. Therefore, a material for forming the seventh pattern layer 81 is the same as the material of the first initial residual pattern 330. Moreover, as shown in FIGS. 5 to 8, since a portion of the first initial carrier injection layer 141i corresponding to the seventh pattern layer 81 is not exposed during formation of at least one second light-emitting device 202 and at least one third light-emitting device 203, the material of the seventh pattern layer 81 is also the same as the material of the first initial carrier injection layer 141i.

That is, in a case where the first cross-linked carrier injection material is generated by cross-linking of the first carrier injection material under light radiation, the material of the seventh pattern layer 81 includes the first carrier injection material. In a case where the first cross-linked carrier injection material is generated by cross-linking of the first carrier injection material and the third photosensitive material under light radiation, the material of the seventh pattern layer 81 includes the first carrier injection material and the third photosensitive material.

A portion, after exposure and development, of the first initial carrier injection layer 141i located in a region where the first light-emitting device 201 is located forms the first carrier injection layer 141 of the first light-emitting device 201; and a portion of the first initial carrier injection layer 141i located in a region where the pixel defining layer 12 is located is washed away during development to form the first initial residual pattern 330 (the seventh pattern layer 81). Therefore, a thickness d31 of the first initial residual pattern 330 is smaller than a thickness d32 of the first carrier injection layer 141. Therefore, a thickness of the seventh pattern layer 81 (which is equal to the thickness d31 of the first initial residual pattern 330) is smaller than the thickness d32 of the first carrier injection layer 141.

For example, as shown in FIG. 5, in a case where the second sacrificial layer group 13B is the second carrier transport layer 132, the eighth pattern layer 82 is a second initial residual pattern 350a formed by developing a portion of the second initial carrier transport layer 132i located in a region where the pixel defining layer 12 is located. Therefore, a material for forming the eighth pattern layer 82 is the same as the material of the second initial residual pattern 350a. Moreover, as shown in FIGS. 5 and 7, since a portion of the second initial carrier transport layer 132i corresponding to the eighth pattern layer 82 is not exposed during formation of at least one second light-emitting device 202 and at least one third light-emitting device 203, the material of the eighth pattern layer 82 is also the same as the material of the second initial carrier transport layer 132i.

That is, in a case where the second cross-linked carrier transport material is generated by cross-linking of the second carrier transport material under light radiation, the material of the eighth pattern layer 82 includes the second carrier transport material. In a case where the second cross-linked carrier transport material is generated by cross-linking of the second carrier transport material and the fifth photosensitive material under light radiation, the material of the eighth pattern layer 82 includes the second carrier transport material and the fifth photosensitive material.

A portion, after exposure and development, of the second initial carrier transport layer 132i located in a region where the second light-emitting device 202 is located forms the second carrier transport layer 132 of the second light-emitting device 202; and a portion of the second initial carrier transport layer 132i located in a region where the pixel defining layer 12 is located is washed away during development to form the second initial residual pattern 350a (the eighth pattern layer 82). Therefore, a thickness d11 of the second initial residual pattern 350a is smaller than a thickness d12 of the second carrier transport layer 132. Therefore, a thickness of the eighth pattern layer 82 (which is equal to the thickness d11 of the second initial residual pattern 350a) is smaller than the thickness d12 of the second carrier transport layer 132.

For example, as shown in FIG. 6, in a case where the second sacrificial layer group 13B is the second carrier transport layer 132 and the second carrier injection layer 142, the eighth pattern layer 82 is a second initial residual pattern 360b formed by developing a portion of the second initial carrier injection layer 142i located in a region where the pixel defining layer 12 is located. Therefore, a material for forming the eighth pattern layer 82 is the same as the material of the second initial residual pattern 360b. Moreover, as shown in FIGS. 6 and 8, since a portion of the second initial carrier injection layer 142i corresponding to the eighth pattern layer 82 is not exposed during formation of at least one second light-emitting device 202 and at least one third light-emitting device 203, the material of the eighth pattern layer 82 is also the same as the material of the second initial carrier injection layer 142i.

That is, in a case where the second cross-linked carrier injection material is generated by cross-linking of the second carrier injection material under light radiation, the material of the eighth pattern layer 82 includes the second carrier injection material. In a case where the second cross-linked carrier injection material is generated by cross-linking of the second carrier injection material and the sixth photosensitive material under light radiation, the material of the eighth pattern layer 82 includes the second carrier injection material and the sixth photosensitive material.

A portion, after exposure and development, of the second initial carrier injection layer 142i located in a region where the second light-emitting device 202 is located forms the second carrier injection layer 142 of the second light-emitting device 202; and a portion of the second initial carrier injection layer 142i located in a region where the pixel defining layer 12 is located is washed away during development to form the second initial residual pattern 360b (the eighth pattern layer 82). Therefore, a thickness d13 of the second initial residual pattern 360b is smaller than a thickness d14 of the second carrier injection layer 142. Therefore, a thickness of the eighth pattern layer 82 (which is equal to the thickness d13 of the second initial residual pattern 360b) is smaller than the thickness d14 of the second carrier injection layer 142.

For example, as shown in FIG. 7, in a case where the third sacrificial layer group 13C is the third carrier transport layer 133, the ninth pattern layer 83 is a third initial residual pattern 380a formed by developing a portion of the third initial carrier transport layer 133i located in a region where the pixel defining layer 12 is located. Therefore, a material for forming the ninth pattern layer 83 is the same as the material of the third initial residual pattern 380a. Moreover, as shown in FIG. 7, since a portion of the third initial carrier transport layer 133i corresponding to the third initial residual pattern 380a is not exposed during formation of at least one third light-emitting device 203, the material of the ninth pattern layer 83 is also the same as the material of the third initial carrier transport layer 133i.

That is, in a case where the third cross-linked carrier transport material is generated by cross-linking of the third carrier transport material under light radiation, the material of the ninth pattern layer 83 includes the third carrier transport material. In a case where the third cross-linked carrier transport material is generated by cross-linking of the third carrier transport material and the eighth photosensitive material under light radiation, the material of the ninth pattern layer 83 includes the third carrier transport material and the eighth photosensitive material.

A portion, after exposure and development, of the third initial carrier transport layer 133i located in a region where the third light-emitting device 203 is located forms the third carrier transport layer 133 of the third light-emitting device 203; and a portion of the third initial carrier transport layer 133i located in a region where the pixel defining layer 12 is located is washed away during development to form the third initial residual pattern 380a (the ninth pattern layer 83). Therefore, a thickness d21 of the third initial residual pattern 380a is smaller than a thickness d22 of the third carrier transport layer 133. Therefore, a thickness of the ninth pattern layer 83 (which is equal to the thickness d21 of the third initial residual pattern 380a) is smaller than a thickness d22 of the third carrier transport layer 133.

It will be noted that in a case where the second sacrificial layer group 13B is the second carrier transport layer 132, and the third sacrificial layer group 13C is the third carrier transport layer 133, if the second carrier transport material of the eighth pattern layer 82 is the same as the third carrier transport material of the ninth pattern layer 83, and the fifth photosensitive material of the eighth pattern layer 82 is the same as the eighth photosensitive material of the ninth pattern layer 83, the eighth pattern layer 82 and the ninth pattern layer 83 have the same materials in the region where the pixel defining layer 12 is located, the eighth pattern layer 82 and the ninth pattern layer 83 may be regarded as one layer, and the thickness of the layer is (d11+d21).

For example, as shown in FIG. 8, in a case where the third sacrificial layer group 13C is the third carrier transport layer 133 and the third carrier injection layer 143, the ninth pattern layer 83 is a third initial residual pattern 390b formed by developing a portion of the third initial carrier injection layer 143i in a region where the pixel defining layer 12 is located. Therefore, a material for forming the ninth pattern layer 83 is the same as the material of the third initial residual pattern 390b. Moreover, as shown in FIG. 8, since a portion of the third initial carrier injection layer 143i corresponding to the third initial residual pattern 390b is not exposed during formation of at least one third light-emitting device 203, the material of the ninth pattern layer 83 is also the same as the material of the third initial carrier injection layer 143i.

That is, in a case where the third cross-linked carrier injection material is generated by cross-linking of the third carrier injection material under light radiation, the material of the ninth pattern layer 83 includes the third carrier injection material. In a case where the third cross-linked carrier injection material is generated by cross-linking of the third carrier injection material and the ninth photosensitive material under light radiation, the material of the ninth pattern layer 83 includes the third carrier injection material and the ninth photosensitive material.

A portion, after exposure and development, of the third initial carrier injection layer 143i located in a region where the third light-emitting device 203 is located forms the third carrier injection layer 143 of the third light-emitting device 203; and a portion of the third initial carrier injection layer 143i located in a region where the pixel defining layer 12 is located is washed away during development to form the third initial residual pattern 390b (the ninth pattern layer 83). Therefore, a thickness d23 of the third initial residual pattern 390b is smaller than a thickness d24 of the third carrier injection layer 143. Therefore, a thickness of the ninth pattern layer 83 (which is equal to the thickness d23 of the third initial residual pattern 390b) is smaller than a thickness d24 of the third carrier injection layer 143.

It will be noted that in a case where the second sacrificial layer group 13B is the second carrier transport layer 132 and the second carrier injection layer 142, and the third sacrificial layer group 13C is the third carrier transport layer 133 and the third carrier injection layer 143, if a first carrier injection material of the seventh pattern layer 81, a second carrier injection material of the eighth pattern layer 82 and a third carrier injection material of the ninth pattern layer 83 are the same, and a third photosensitive material of the seventh pattern layer 81, a sixth photosensitive material of the eighth pattern layer 82 and a ninth photosensitive material of the ninth pattern layer 83 are the same, the seventh pattern layer 81, the eighth pattern layer 82 and the ninth pattern layer 83 have the same materials in the region where the pixel defining layer 12 is located, the seventh pattern layer 81, the eighth pattern layer 82 and the ninth pattern layer 83 may be regarded as one layer, and the thickness of the layer is (d13+d23+d31).

It will be noted that in the first pattern layer 71, the second pattern layer 72, the third pattern layer 73, the fourth pattern layer 74, the fifth pattern layer 75, the sixth pattern layer 76, the seventh pattern layer 81, the eighth pattern layer 82 and the ninth pattern layer 83, not all the pattern layers exist, and only part of the pattern layers may exist. For example, the first initial carrier injection layer 141i is removed cleanly after development, and there is no residue of the first initial residual pattern 330. Then, the third pattern layer 73, the fifth pattern layer 75 and the seventh pattern layer 81 may not exist.

The above is an exemplary introduction to the residual pattern layer in the first light-emitting device 201, the second light-emitting device 202, the third light-emitting device 203 and the pixel defining layer 12. The following is an exemplary introduction to the structures of the cross-linked materials in the first light-emitting device 201, the second light-emitting device 202 and the third light-emitting device 203 and the structures of the photosensitive materials for forming the cross-linked materials.

In some embodiments, the first photosensitive material, the fourth photosensitive material and the seventh photosensitive material are the same or different, and are each independently selected from any of first type of photosensitive materials. The first type of photosensitive material includes a first photosensitive group, the first photosensitive group undergoes a cross-linking reaction with a quantum dot material under light radiation; and the quantum dot material is one of the first quantum dot material, the second quantum dot material and the third quantum dot material.

In some embodiments, any of the first quantum dot material, the second quantum dot material and the third quantum dot material includes a quantum dot body and a first ligand material coordinated on the quantum dot body. The quantum dot body includes any of a II-VI group quantum dot, a III-V group quantum dot, a IV-VI group quantum dot, a quantum dot with core-shell structure and an ABX₃ type perovskite quantum dot. In the ABXs type perovskite quantum dot, A is one or more of CH₃NH₃⁺ (methylamine), NH₂CH═NH₂ (formamidine) and Cs⁺, B is one or two of Pb²⁺ and Sn²⁺, and X is one or more of Cl⁻, Br⁻ and I⁻. The ABX₃ type perovskite quantum dots include CH₃NH₃PbBr₃, CH₃NH₃PbCl₃, CH₃NH₃PbI₃, CsPbBr₃, CsPbCl₃ and CsPbI₃.

For example, the first ligand material coordinated on the quantum dot body is used to be cross-linked with the first type of photosensitive material (the first photosensitive material, the fourth photosensitive material and the seventh photosensitive material). The first ligand material contains a carbon-hydrogen insertion group ZH, and as shown in the following formula, the carbon-hydrogen insertion group ZH and the first photosensitive group may undergo a carbon-hydrogen insertion reaction under light radiation, where T is an active intermediate free radical generated by the first photosensitive group under light radiation. In the carbon-hydrogen insertion group ZH, Z is any of primary carbon, secondary carbon and tertiary carbon. Specific reference may be made to the subsequent contents and details are not described here.

(T)+Z—H [symbol] Z-(T)-H

For example, the II-VI group quantum dot is selected from binary compounds such as one or more of CdS, CdSe, CdTe, ZnS, ZnSe, ZnTe, HgSe, HgTe and HgS; ternary compounds such as one or more of HgₓCd₁₋ₓTe, HgₓCd₁₋ₓS, HgₓCd₁₋ₓSe, HgₓZn₁₋ₓTe, CdₓZn₁₋ₓSe and CdₓZn₁₋ₓS, where x is greater than 0 and less than 1 (0<x<1), but is not limited thereto.

The III-V group quantum dot is selected from InP, InAs, InSb, GaAs, GaP, GaN, GaSb, InN, AlP, AlN, AlAs or a mixture thereof, but is not limited thereto.

The IV-VI group quantum dot is selected from PbS, PbSe, PbTe or a mixture thereof, but is not limited thereto.

The quantum dot with core-shell structure refers to a quantum dot in which one material is a core material and the other is a shell material. For example, a quantum dot of CdS@ZnS means that a core material of the quantum dot is CdS and a shell material thereof is ZnS. The quantum dot with core-shell structure is selected from one or more of CdS@ZnS, CdSe@CdS, InP@ZnS, CdTe@CdSe, CdSe@ZnTe, ZnTe@CdSe, ZnSe@CdS and Cd₁₋ₓZnₓS@ZnS, where x is greater than 0 and less than 1 (0<x<1), but is not limited thereto.

In the ABX₃ type perovskite quantum dot, A is one or more of CH₃NH₃⁺ (methylamine), NH₂CH═NH₂ (formamidine) and Cs⁺, B is one or two of Pb²⁺ and Sn²⁺, and X is one or more of Cl⁻, Br⁻ and I⁻. The ABX₃ type perovskite quantum dots include CH₃NH₃PbBr₃, CH₃NH₃PbCl₃, CH₃NH₃PbI₃, CsPbBr₃, CsPbCl₃ and CsPbI₃, but are not limited to there to.

In some other embodiments, the quantum dot body may be any of other nanoscale materials, such as a nanorod, a nanosheet, or the like. Components of other nanoscale materials may include at least one of CuInS₂, CuInSe₂, AgInS₂ and the like, but are not limited thereto.

It will be noted that the structural formulas listed above are examples of the structure of the quantum dot body, but are not limitations on the structure of the quantum dot body. The structure of the quantum dot body is not limited here, as long as the requirement of the first ligand material being coordinated on the quantum dot body is met.

For example, the first ligand material may be an organic molecule containing a hydrocarbon chain. For example, the first ligand material is selected from any of an organic acid, an organic amine, an organophosphorus and an organic thiol, and includes, but is not limited to, oleic acid, oleylamine, 1-dodecanethiol, n-tetradecylphosphonic acid, tri-n-octylphosphine, hexadecyltrimethylammonium bromide, polyethylene glycol or polyvinylpyrrolidone.

For example, the first ligand material contains a C—H bond, and the first ligand material is cross-linked with the first type of photosensitive material through a carbon-hydrogen (C—H) insertion reaction. For convenience of representation, the first ligand material may be represented by the following formula:

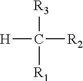

Where R₂ and R₃ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

R₁ is selected from any of a C1 to C40 carbon chain with a carboxyl group, a C1 to C40 carbon chain with an amino group, and a C1 to C40 carbon chain with a sulfhydryl group; and any of the carboxyl group, the amino group and the sulfhydryl group is connected to the quantum dot body by coordination.

It will be noted that a Cx carbon chain refers to a carbon chain containing x carbon (C) atoms, and the same applies below.

The C—H bond in the first ligand material may be cross-linked with the first type of photosensitive material (the first photosensitive material, the fourth photosensitive material and the seventh photosensitive material) under light radiation. A specific introduction to the cross-linking reaction refers to subsequent contents and is not described in detail here.

In some embodiments, the first type of photosensitive material is selected from any of structures shown in the following general formula (IV-A).

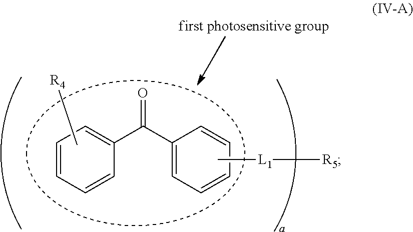

Where a benzophenone group is the first photosensitive group.

L₁ is selected from any of a single bond, an ester bond, an ether bond and a thioether bond.

R₄ and R₅ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

a is selected from positive integers greater than or equal to 2.

It will be noted that a represents the number of the corresponding groups. The value of a is a positive integer greater than or equal to 2, that is, a may take a value of an integer of 2, 3, 4, or greater than 4.

If there are a lot of C atoms in R₅, a may take a large value, for example, a positive integer greater than 6. However, a large value of a may lead to difficulties in synthesis and purification during preparation of the first type of photosensitive material. However, in theory, the larger the value of a, the more reaction sites the first type of photosensitive material has. In addition, a large number of reaction sites of the first type of photosensitive material will increase molecular steric hindrance. Therefore, a may take a value of a positive integer greater than or equal to 2 and less than or equal to 6.

The first type of photosensitive material having a structure as shown in the general formula (IV-A) contains a benzophenone group. The first type of photosensitive material containing a benzophenone group may be cross-linked with the first ligand material coordinated on the quantum dot body. For example, benzophenone is photolyzed to form a triplet ketone intermediate under light radiation (hν), with a structure shown in the following formula, in which the C^{•}—O^{•} in the triplet ketone intermediate will attack a C—H bond nearby to undergo a cross-linking reaction.

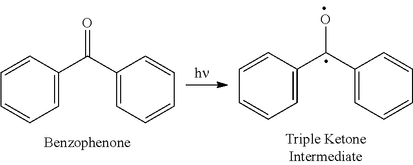 [SMILES: O=C(c1ccccc1)c1ccccc1 ; OC(c1ccccc1)c1ccccc1]

In some embodiments, a reaction principle of the first type of photosensitive material and the quantum dot material (including the first quantum dot material, the second quantum dot material and the third quantum dot material) is as shown in the following formula. The active intermediate free radical C^{•}—O^{•} (carbon-oxygen free radical) contained in the triplet ketone intermediate in the first type of photosensitive material attacks the C—H bond nearby, that is, the C^{•}—O^{•} contained in the triplet ketone intermediate in the first type of photosensitive material attacks the C—H bond in the first ligand material coordinated on the quantum dot body (QD), so that the C—H bond in the first ligand material is broken.

After the C—H bond in the first ligand material is broken, a carbon free radical (C^{•}) and a hydrogen free radical (H^{•}) are formed. An oxygen free radical (O^{•}) in the first type of photosensitive material will attack the hydrogen free radical (H^{•}) to form a hydrogen-oxygen bond (—OH), and a carbon free radical (C^{•}) in the first type of photosensitive material will attack the carbon free radical (C^{•}) in the first ligand material to form a carbon-carbon bond, so that the first type of photosensitive material and the quantum dot material (including the first quantum dot material, the second quantum dot material and the third quantum dot material) are cross-linked to form a cross-linked light-emitting material (including the first cross-linked light-emitting material, the second cross-linked light-emitting material and the third cross-linked light-emitting material).

Here, “X” represents a linking group connecting two benzophenone groups. The linking group includes, for example, R₅ and at least two L₁.

In some embodiments, any of the first cross-linked light-emitting material, the second cross-linked light-emitting material and the third cross-linked light-emitting material includes any of structures shown in the following general formula (I-A).

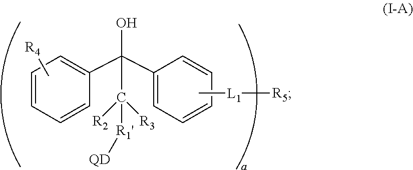

Where R′₁ is selected from a remaining structure of R₁ with one hydrogen removed from any of a carboxyl group, an amino group and a sulfhydryl group therein.

It will be noted that as for description of L₁, reference may be made to the above description of L₁. As for description of R₁, reference may be made to the above description of R₁. As for description of R₂, R₃ and R₄, reference may be made to the above description of R₂, R₃ and R₄, and any two of R₂, R₃ and R₄ are the same or different. As for description of R₅, reference may be made to the above description of R₅. QD represents any of quantum dot bodies, and the quantum dot body includes any of the II-VI group quantum dot, the III-V group quantum dot, the IV-VI group quantum dot, the quantum dot with core-shell structure and the ABX₃ type perovskite quantum dot. As for description of the quantum dot body, reference may be made to the above description of the quantum dot. As for description of a, reference may be made to the above description of a. Details are not repeated here.

For example, a takes a value of 2, 3, 4, 5 or 6, which is not limited here. By setting the value of a to a positive integer greater than or equal to 2, each benzophenone group in the first type of photosensitive material may be connected to a first ligand material molecule. Therefore, the first type of photosensitive material molecule containing benzophenone groups with the number of a may achieve connection of quantum dot material (including the first quantum dot material, the second quantum dot material and the third quantum dot material) molecules with the number of a to form a cross-linked light-emitting material (including the first cross-linked light-emitting material, the second cross-linked light-emitting material and the third cross-linked light-emitting material).

In some examples, the first type of photosensitive material is selected from the following structural formula (1,2-ethanediyl bis(3-benzoylbenzoate)).

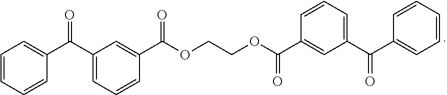 [SMILES: O=C(OCCOC(=O)c1cccc(C(=O)c2ccccc2)c1)c1cccc(C(=O)c2ccccc2)c1]

In some embodiments, the first type of photosensitive material is selected from any of structures shown in the following general formula (IV-B).

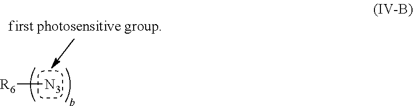

Where an azide group is the first photosensitive group.

R₆ is selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

b is selected from positive integers greater than or equal to 2.

It will be noted that b represents the number of the corresponding groups. The value of b is a positive integer greater than or equal to 2, that is, b may take a value of an integer of 2, 3, 4, or greater than 4.

If there are a lot of C atoms in R₆, b may take a large value, for example, a positive integer greater than 6. However, a large value of b may lead to difficulties in synthesis and purification during preparation of the first type of photosensitive material. However, in theory, the larger the value of b, the more reaction sites the first type of photosensitive material has. In addition, a large number of reaction sites of the first type of photosensitive material will increase molecular steric hindrance. Therefore, b may take a value of a positive integer greater than or equal to 2 and less than or equal to 6.

The first type of photosensitive material having a structure as shown in the general formula (IV-B) contains an azide group. The first type of photosensitive material containing an azide group may be cross-linked with the first ligand material coordinated on the quantum dot body. For example, the azide group is photolyzed to form an active intermediate free radical nitrene —\ddot{N}: under light radiation (hν), in which nitrene will attack a C—H bond nearby to undergo a cross-linking reaction.

For example, the first type of photosensitive material containing an azide group (—N₃) and the C—H bond in the first ligand material undergo a cross-linking reaction under light irradiation, and the cross-linking reaction is shown in the following formula. Here, b takes a value of 2, the first type of photosensitive material contains 2 azide groups (—N₃), each azide group (—N₃) will produce a nitrene, and each nitrene attacks a first ligand material molecule. The first type of photosensitive material and the quantum dot material are cross-linked through a C—H insertion reaction to form a cross-linked light-emitting material (including the first cross-linked light-emitting material, the second cross-linked light-emitting material and the third cross-linked light-emitting material). The solubilities of the first cross-linked light-emitting material, the second cross-linked light-emitting material and the third cross-linked light-emitting material in the first-type solvent decrease, that is, the first cross-linked light-emitting material, the second cross-linked light-emitting material and the third cross-linked light-emitting material are each insoluble in a respective developer (e.g., the first solvent, the fourth solvent or the seventh solvent) during development.

In some embodiments, any of the first cross-linked light-emitting material, the second cross-linked light-emitting material and the third cross-linked light-emitting material includes any of structures shown in the following general formula (I-B).

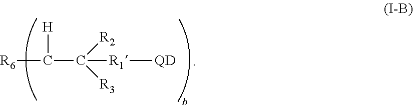

It will be noted that as for description of R₁, reference may be made to the above description of R₁. As for description of R₁′, reference may be made to the above description of R₁′. As for description of R₂ and R₃, reference may be made to the above description of R₂ and R₃, and R₂ and R₃ are the same or different. As for description of R₆, reference may be made to the above description of R₆. QD represents any of quantum dot bodies, and the quantum dot body includes any of the II-VI group quantum dot, the III-V group quantum dot, the IV-VI group quantum dot, the quantum dot with core-shell structure and the ABX₃ type perovskite quantum dot. As for description of the quantum dot body, reference may be made to the above description of the quantum dot. As for description of b, reference may be made to the above description of b. Details are not repeated here.

For example, b takes a value of 2, 3, 4, 5 or 6, which is not limited here. By setting the value of b to a positive integer greater than or equal to 2, each azide group in the first type of photosensitive material may be connected to a first ligand material molecule. Therefore, the first type of photosensitive material molecule containing azide groups with the number of b may achieve connection of quantum dot material (including the first quantum dot material, the second quantum dot material and the third quantum dot material) molecules with the number of b to form a cross-linked light-emitting material (including the first cross-linked light-emitting material, the second cross-linked light-emitting material and the third cross-linked light-emitting material).

In some examples, the first type of photosensitive material is selected from any of the following structural formulas.

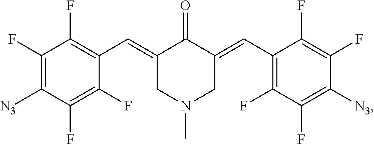 [SMILES: CN1C/C(=C\c2c(F)c(F)c(N=[N+]=[N-])c(F)c2F)C(=O)/C(=C/c2c(F)c(F)c(N=[N+]=[N-])c(F)c2F)C1]

### 3,5-bis[(4-azido-2,3,5,6-tetrafluorophenyl)methylene]-1-methyl-(3E,5E)-4-piperidinone

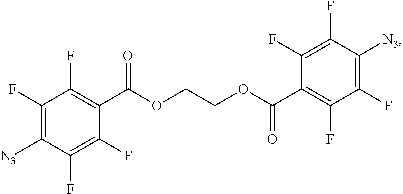 [SMILES: [N-]=[N+]=Nc1c(F)c(F)c(C(=O)OCCOC(=O)c2c(F)c(F)c(N=[N+]=[N-])c(F)c2F)c(F)c1F]

### ethane-1,2-diyl bis(4-azido-2,3,5,6-tetrafluorobenzoate)

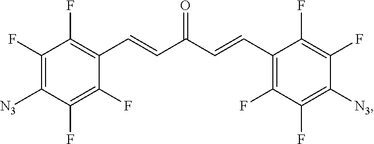 [SMILES: [N-]=[N+]=Nc1c(F)c(F)c(/C=C/C(=O)/C=C/c2c(F)c(F)c(N=[N+]=[N-])c(F)c2F)c(F)c1F]

### (1E,4E)-1,5-bis(4-azido-2,3,5,6-tetrafluorophenyl)penta-1,4-dien-3-one

In some embodiments, the first type of photosensitive material is selected from any of structures shown in the following general formula (IV-C).

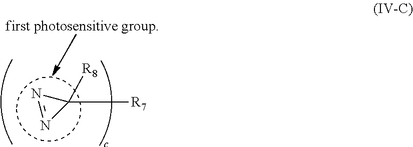

Where a diazirine group is the first photosensitive group.

R₇ and R₈ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

c is selected from positive integers greater than or equal to 2.

It will be noted that c represents the number of the corresponding groups. The value of c is a positive integer greater than or equal to 2, that is, c may take a value of an integer of 2, 3, 4, or greater than 4.

If there are a lot of C atoms in R₇, c may take a large value, for example, a positive integer greater than 6. However, a large value of c may lead to difficulties in synthesis and purification during preparation of the first type of photosensitive material. However, in theory, the larger the value of c, the more reaction sites the first type of photosensitive material has. In addition, a large number of reaction sites of the first type of photosensitive material will increase molecular steric hindrance. Therefore, c may take a value of a positive integer greater than or equal to 2 and less than or equal to 6.

The first type of photosensitive material having a structure as shown in the general formula (IV-C) contains a diazirine group. The first type of photosensitive material containing a diazirine group may be cross-linked with the first ligand material coordinated on the quantum dot body. For example, the diazirine group is photolyzed to form an active intermediate free radical carbene —\ddot{C} under light radiation (hν), in which carbene will attack a C—H bond nearby to undergo a cross-linking reaction.

For example, the first type of photosensitive material containing a diazirine group and the C—H bond in the first ligand material undergo a cross-linking reaction under light irradiation, and the cross-linking reaction is shown in the following formula. Here, c takes a value of 2, the first type of photosensitive material contains 2 diazirine groups, each diazirine group will produce a carbene, and each carbene attacks a first ligand material molecule. The first type of photosensitive material and the quantum dot material are cross-linked through a C—H insertion reaction to form a cross-linked light-emitting material (including the first cross-linked light-emitting material, the second cross-linked light-emitting material and the third cross-linked light-emitting material). The solubilities of the first cross-linked light-emitting material, the second cross-linked light-emitting material and the third cross-linked light-emitting material in the first-type solvent decrease, that is, the first cross-linked light-emitting material, the second cross-linked light-emitting material and the third cross-linked light-emitting material are each insoluble in a respective developer (e.g., the first solvent, the fourth solvent or the seventh solvent) during development.

In some embodiments, any of the first cross-linked light-emitting material, the second cross-linked light-emitting material and the third cross-linked light-emitting material includes any of structures shown in the following general formula (I-C).

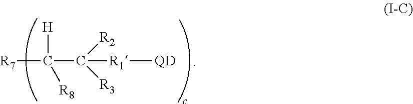

It will be noted that as for description of R₁, reference may be made to the above description of R₁. As for description of R₁′, reference may be made to the above description of R₁′. As for description of R₂ and R₃, reference may be made to the above description of R₂ and R₃, and R₂ and R₃ are the same or different. As for description of R₈, reference may be made to the above description of R₈. As for description of R₇, reference may be made to the above description of R₇. QD represents any of quantum dot bodies, and the quantum dot body includes any of the II-VI group quantum dot, the III-V group quantum dot, the IV-VI group quantum dot, the quantum dot with core-shell structure and the ABX₃ type perovskite quantum dot. As for description of the quantum dot body, reference may be made to the above description of the quantum dot. As for description of c, reference may be made to the above description of c. Details are not repeated here.

For example, c takes a value of 2, 3, 4, 5 or 6, which is not limited here. By setting the value of c to a positive integer greater than or equal to 2, each diazirine group in the first type of photosensitive material may be connected to a first ligand material molecule. Therefore, the first type of photosensitive material molecule containing diazirine groups with the number of c may achieve connection of quantum dot material (including the first quantum dot material, the second quantum dot material and the third quantum dot material) molecules with the number of c to form a cross-linked light-emitting material (including the first cross-linked light-emitting material, the second cross-linked light-emitting material and the third cross-linked light-emitting material).

In some examples, the first type of photosensitive material is selected from the following structural formula 3,3′-[4,4′(perfluorobutane-1,4-diyl)bis(4,1-phenylene)]bis[3-(trifluoromethyl)-3H-diazirine].

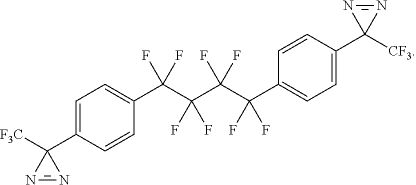 [SMILES: FC(F)(F)C1(c2ccc(C(F)(F)C(F)(F)C(F)(F)C(F)(F)c3ccc(C4(C(F)(F)F)N=N4)cc3)cc2)N=N1]

In some examples, a reaction equation between the first type of photosensitive material and the carrier transport material is shown in equation (X-5).

In some other examples, a reaction equation between the first type of photosensitive material and the carrier transport material is shown in equation (X-6).

In yet other examples, a reaction equation between the first type of photosensitive material and the carrier transport material is shown in equation (X-7).

Here, [symbol] represents the first ligand material oleic acid, which has a structure shown in the following formula.

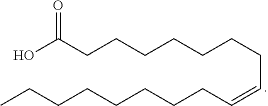 [SMILES: CCCCCCCC/C=C\CCCCCCCC(=O)O]

It can be understood that as described in the method for forming the first light-emitting device 201, the second light-emitting device 202 and the third light-emitting device 203, the quantum dot material and the first type of photosensitive material are applied by coating or printing after being dissolved in the first solution, the fourth solution or the seventh solution. The solvents of the first solution, the fourth solution and the seventh solution are the first solvent, the fourth solvent and the seventh solvent respectively, and all three solvents belong to the first-type solvents. The setting of the first type of photosensitive material being selected from the general formula (IV-A), the general formula (IV-B) or the general formula (IV-C) may increase the solubility of the first type of photosensitive material in the first-type solvent (e.g., octane or propylene glycol methyl ether acetate), which is beneficial to the formation of the light-emitting pattern 23 (including the first light-emitting pattern 23a, the second light-emitting pattern 23b and the third light-emitting pattern 23c).

The above is an exemplary introduction to the first type of photosensitive materials and the cross-linked light-emitting materials (the first cross-linked light-emitting material, the second cross-linked light-emitting material and the third cross-linked light-emitting material). The following is an exemplary introduction to the structures of the second type of photosensitive materials and the cross-linked carrier transport materials (the first cross-linked carrier transport material, the second cross-linked carrier transport material and the third cross-linked carrier transport material).

In some embodiments, the second photosensitive material, the fifth photosensitive material and the eighth photosensitive material are the same or different, and are each independently selected from any of second type of photosensitive materials. The second type of photosensitive material includes a second photosensitive group, the second photosensitive group undergoes a cross-linking reaction with a carrier transport material under light radiation; and the carrier transport material is one of the first carrier transport material, the second carrier transport material and the third carrier transport material. Moreover, the first photosensitive group and the second photosensitive group may be the same or different.

In some embodiments, any of the first carrier transport material, the second carrier transport material and the third carrier transport material includes a carbon-hydrogen insertion group ZH. The carbon-hydrogen insertion group ZH is configured to undergo a carbon-hydrogen insertion reaction with the second photosensitive group under light radiation, where as shown in the following formula, T is an active intermediate free radical generated by the second photosensitive group under light radiation. In the carbon-hydrogen insertion group ZH, Z is any of primary carbon, secondary carbon and tertiary carbon.

(T)+Z—H [symbol] Z-(T)-H

For example, the first carrier transport material, the second carrier transport material and the third carrier transport material are hole transport materials, and are each configured to enhance a transport rate of holes in the light-emitting device and effectively block electrons within the light-emitting pattern, so as to achieve maximum recombination of carriers. In addition, an energy barrier of holes during injection may be reduced, an injection efficiency of holes may be improved, and the brightness, efficiency and service life of the device may be improved.

For example, the hole transport material may be a material containing a structural unit of such triphenylamine, as poly (N,N′-bis-4-butylphenyl-N,N′-bisphenyl)benzidine (poly-TPD) and poly(9,9-dioctylfluorene-alt-N-(4-sec-butylphenyl)-diphenylamine) (TFB). Alternatively, the hole transport material may be a material containing a structural unit of 9,9′-spirobifluorene, such as 2,2′,7,7′-tetrakis(diphenylamino)-9,9′-spirobifluorene. Alternatively, the hole transport material may be polyvinyl carbazole (PVK).

For example, the carrier transport material contains a C—H bond, and the carrier transport material is cross-linked with the second type of photosensitive material through a carbon-hydrogen (C—H) insertion reaction. For convenience of representation, the carrier transport material may be represented by the following formula:

H—C—(X)

Here, X represents a remaining structure of any of the first carrier transport material, the second carrier transport material and the third carrier transport material after removing the C—H bond; and the C—H bond is used to undergo a cross-linking reaction with the second photosensitive group of the second type of photosensitive material under light radiation.

The C—H bond in the carrier transport material may be cross-linked with the second type of photosensitive material (the second photosensitive material, the fifth photosensitive material and the eighth photosensitive material) under light radiation. A specific introduction to the cross-linking reaction refers to subsequent contents and is not described in detail here.

In some embodiments, the second type of photosensitive material is selected from any of structures shown in the following general formula (V-A).

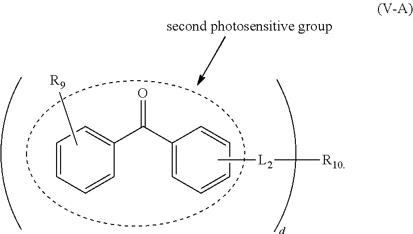

Where a benzophenone group is the second photosensitive group.

L₂ is selected from any of a single bond, an ester bond, an ether bond and a thioether bond.

R₉ and R₁₀ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C4.

d is selected from positive integers greater than or equal to 2.

It will be noted that d represents the number of the corresponding groups. The value of d is a positive integer greater than or equal to 2, that is, d may take a value of an integer of 2, 3, 4, or greater than 4.

If there are a lot of C atoms in R₁₀, d may take a large value, for example, a positive integer greater than 6. However, a large value of d may lead to difficulties in synthesis and purification during preparation of the second type of photosensitive material. However, in theory, the larger the value of d, the more reaction sites the second type of photosensitive material has. In addition, a large number of reaction sites of the second type of photosensitive material will increase molecular steric hindrance. Therefore, d may take a value of a positive integer greater than or equal to 2 and less than or equal to 6.

The second type of photosensitive material having a structure as shown in the general formula (V-A) contains a benzophenone group. The second type of photosensitive material containing a benzophenone group may be cross-linked with the carrier transport material. For example, benzophenone is photolyzed to form a triplet ketone intermediate (referring to the previous content for the structure) under light radiation (hν), and the C^{•}—O^{•} in the triplet ketone intermediate will attack a C—H bond nearby to undergo a cross-linking reaction.

In some embodiments, a reaction principle of the second type of photosensitive material and the carrier transport material (including the first carrier transport material, the second carrier transport material and the third carrier transport material) is as shown in the following formula. The active intermediate free radical C^{•}—O^{•} (carbon-oxygen free radical) contained in the triplet ketone intermediate in the second type of photosensitive material attacks the C—H bond nearby, that is, the C^{•}—O^{•} contained in the triplet ketone intermediate in the second type of photosensitive material attacks the C—H bond in the carrier transport material, so that the C—H bond in the carrier transport material is broken.

After the C—H bond in the carrier transport material is broken, a carbon free radical (C^{•}) and a hydrogen free radical (H^{•}) are formed. An oxygen free radical (O^{•}) in the second type of photosensitive material will attack the hydrogen free radical (H^{•}) to form a hydrogen-oxygen bond (—OH), and a carbon free radical (C^{•}) in the second type of photosensitive material will attack the carbon free radical (C^{•}) in the carrier transport material to form a carbon-carbon bond, so that the second type of photosensitive material and the carrier transport material (including the first carrier transport material, the second carrier transport material and the third carrier transport material) are cross-linked to form a cross-linked carrier transport material (including the first cross-linked carrier transport material, the second cross-linked carrier transport material and the third cross-linked carrier transport material).

Here, “Q” represents a linking group connecting two benzophenone groups. The linking group includes, for example, R₁₀ and at least two L₂.

In some examples, any of the first cross-linked carrier transport material, the second cross-linked carrier transport material and the third cross-linked carrier transport material includes any of structures shown in the following general formula (II-A).

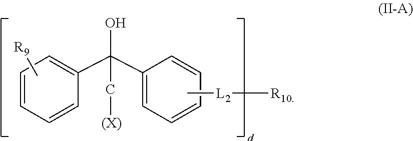

It will be noted that as for description of L₂, reference may be made to the above description of L₂. As for description of R₉, reference may be made to the above description of R₉. As for description of R₁₀, reference may be made to the above description of R₁₀. As for description of X, reference may be made to the above description of X. As for description of d, reference may be made to the above description of d. Details are not repeated here.

For example, d takes a value of 2, 3, 4, 5 or 6, which is not limited here. By setting the value of d to a positive integer greater than or equal to 2, each benzophenone group in the second type of photosensitive material may be connected to a carrier transport material molecule. Therefore, the second type of photosensitive material molecule containing benzophenone groups with the number of d may achieve connection of carrier transport material (including the first carrier transport material, the second carrier transport material and the third carrier transport material) molecules with the number of d to form a cross-linked carrier transport material (including the first cross-linked carrier transport material, the second cross-linked carrier transport material and the third cross-linked carrier transport material).

In some examples, the second type of photosensitive material is selected from the following structural formula (1,2-ethanediyl bis(3-benzoylbenzoate)).

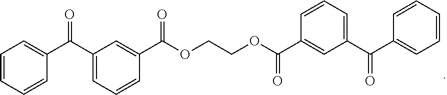 [SMILES: O=C(OCCOC(=O)c1cccc(C(=O)c2ccccc2)c1)c1cccc(C(=O)c2ccccc2)c1]

In some embodiments, the second type of photosensitive material is selected from any of structures shown in the following general formula (V-B).

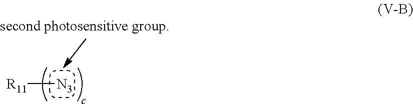

Where an azide group is the second photosensitive group.

R₁₁ is selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C4.

e is selected from positive integers greater than or equal to 2.

It will be noted that e represents the number of the corresponding groups. The value of e is a positive integer greater than or equal to 2, that is, e may take a value of an integer of 2, 3, 4, or greater than 4.

If there are a lot of C atoms in R₁₁, e may take a large value, for example, a positive integer greater than 6. However, a large value of e may lead to difficulties in synthesis and purification during preparation of the second type of photosensitive material. However, in theory, the larger the value of e, the more reaction sites the second type of photosensitive material has. In addition, a large number of reaction sites of the second type of photosensitive material will increase molecular steric hindrance. Therefore, e may take a value of a positive integer greater than or equal to 2 and less than or equal to 6.

The second type of photosensitive material having a structure as shown in the general formula (V-B) contains an azide group. The second type of photosensitive material containing an azide group may be cross-linked with the carrier transport material. For example, the azide group is photolyzed to form an active intermediate free radical nitrene —\ddot{N}: under light radiation (hν), in which nitrene will attack a C—H bond nearby to undergo a cross-linking reaction.

For example, the second type of photosensitive material containing an azide group (—N₃) and the C—H bond in the carrier transport material undergo a cross-linking reaction under light irradiation, and the cross-linking reaction is shown in the following formula. Here, e takes a value of 2, the second type of photosensitive material contains 2 azide groups (—N₃), each azide group (—N₃) will produce an active intermediate free radical nitrene, and each nitrene attacks a carrier transport material molecule. The second type of photosensitive material and the carrier transport material are cross-linked through a C—H insertion reaction to form a cross-linked carrier transport material (including the first cross-linked carrier transport material, the second cross-linked carrier transport material and the third cross-linked carrier transport material). The solubilities of the first cross-linked carrier transport material, the second cross-linked carrier transport material and the third cross-linked carrier transport material in the second-type solvent decrease, that is, the first cross-linked carrier transport material, the second cross-linked carrier transport material and the third cross-linked carrier transport material are each insoluble in a respective developer (e.g., the second solvent, the fifth solvent or the eighth solvent) during development.

In some examples, any of the first cross-linked carrier transport material, the second cross-linked carrier transport material and the third cross-linked carrier transport material includes any of structures shown in the following general formula (II-B).

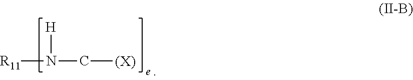

It will be noted that as for description of R₁₁, reference may be made to the above description of R₁₁. As for description of X, reference may be made to the above description of X. As for description of e, reference may be made to the above description of e. Details are not repeated here.

For example, e takes a value of 2, 3, 4, 5 or 6, which is not limited here. By setting the value of e to a positive integer greater than or equal to 2, each azide group in the second type of photosensitive material may be connected to a carrier transport material molecule. Therefore, the second type of photosensitive material molecule containing azide groups with the number of e may achieve connection of carrier transport material (including the first carrier transport material, the second carrier transport material and the third carrier transport material) molecules with the number of e to form a cross-linked carrier transport material (including the first carrier transport material, the second carrier transport material and the third carrier transport material).

In some examples, the second type of photosensitive material is selected from any of the following structural formulas.

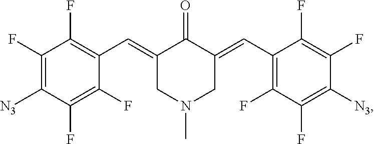 [SMILES: CN1C/C(=C\c2c(F)c(F)c(N=[N+]=[N-])c(F)c2F)C(=O)/C(=C/c2c(F)c(F)c(N=[N+]=[N-])c(F)c2F)C1]

### 3,5-bis[(4-azido-2,3,5,6-tetrafluorophenyl)methylene]-1-methyl-(3E,5E)-4-piperidinone

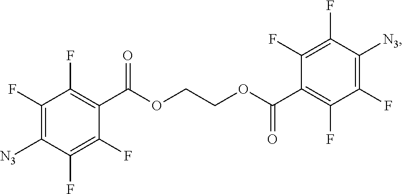 [SMILES: [N-]=[N+]=Nc1c(F)c(F)c(C(=O)OCCOC(=O)c2c(F)c(F)c(N=[N+]=[N-])c(F)c2F)c(F)c1F]

### ethane-1,2-diyl bis(4-azido-2,3,5,6-tetrafluorobenzoate)

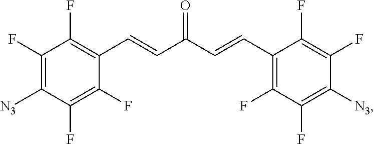 [SMILES: [N-]=[N+]=Nc1c(F)c(F)c(/C=C/C(=O)/C=C/c2c(F)c(F)c(N=[N+]=[N-])c(F)c2F)c(F)c1F]

### (1E,4E)-1,5-bis(4-azido-2,3,5,6-tetrafluorophenyl)penta-1,4-dien-3-one

In some embodiments, the second type of photosensitive material is selected from any of structures shown in the following general formula (V-C).

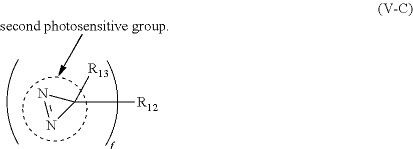

Where a diazirine group is the second photosensitive group.

R₁₂ and R₁₃ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

f is selected from positive integers greater than or equal to 2.

It will be noted that f represents the number of the corresponding groups. The value of f is a positive integer greater than or equal to 2, that is, f may take a value of an integer of 2, 3, 4, or greater than 4.

If there are a lot of C atoms in R₁₂, f may take a large value, for example, a positive integer greater than 6. However, a large value of f may lead to difficulties in synthesis and purification during preparation of the second type of photosensitive material. However, in theory, the larger the value of f, the more reaction sites the second type of photosensitive material has. In addition, a large number of reaction sites of the second type of photosensitive material will increase molecular steric hindrance. Therefore, f may take a value of a positive integer greater than or equal to 2 and less than or equal to 6.

The second type of photosensitive material having a structure as shown in the general formula (V-C) contains a diazirine group. The second type of photosensitive material containing a diazirine group may be cross-linked with the carrier transport material. For example, the diazirine group is photolyzed to form an active intermediate free radical carbene —\ddot{C} under light radiation (hν), in which carbene will attack a C—H bond nearby to undergo a cross-linking reaction.

For example, the second type of photosensitive material containing a diazirine group and the C—H bond in the carrier transport material undergo a cross-linking reaction under light irradiation, and the cross-linking reaction is shown in the following formula. Here, f takes a value of 2, the second type of photosensitive material contains 2 diazirine groups, each diazirine group will produce a carbene, and each carbene attacks a carrier transport material molecule. The second type of photosensitive material and the carrier transport material are cross-linked through a C—H insertion reaction to form a cross-linked carrier transport material (including the first cross-linked carrier transport material, the second cross-linked carrier transport material and the third cross-linked carrier transport material). The solubilities of the first cross-linked carrier transport material, the second cross-linked carrier transport material and the third cross-linked carrier transport material in the second-type solvent decrease, that is, the first cross-linked carrier transport material, the second cross-linked carrier transport material and the third cross-linked carrier transport material are each insoluble in a respective developer (e.g., the second solvent, the fifth solvent or the eighth solvent) during development.

In some examples, any of the first cross-linked carrier transport material, the second cross-linked carrier transport material and the third cross-linked carrier transport material includes any of structures shown in the following general formula (II-C).

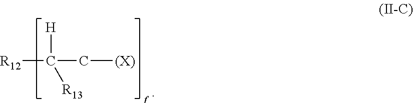

It will be noted that as for description of R₁₂, reference may be made to the above description of R₁₂. As for description of R₁₃, reference may be made to the above description of R₁₃. As for description of X, reference may be made to the above description of X. As for description of f, reference may be made to the above description of f. Details are not repeated here.

For example, f takes a value of 2, 3, 4, 5 or 6, which is not limited here. By setting the value of f to a positive integer greater than or equal to 2, each diazirine group in the second type of photosensitive material may be connected to a carrier transport material molecule. Therefore, the second type of photosensitive material molecule containing diazirine groups with the number of f may achieve connection of carrier transport material (including the first carrier transport material, the second carrier transport material and the third carrier transport material) molecules with the number of f to form a cross-linked carrier transport material (including the first carrier transport material, the second carrier transport material and the third carrier transport material).

In some examples, the second type of photosensitive material is selected from the following structural formula 3,3′-[4,4′(perfluorobutane-1,4-diyl)bis(4,1-phenylene)]bis[3-(trifluoromethyl)-3H-diazirine].

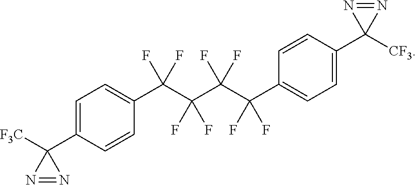 [SMILES: FC(F)(F)C1(c2ccc(C(F)(F)C(F)(F)C(F)(F)C(F)(F)c3ccc(C4(C(F)(F)F)N=N4)cc3)cc2)N=N1]

In some examples, a reaction equation between the second type of photosensitive material and the carrier transport material is shown in equation (X-2).

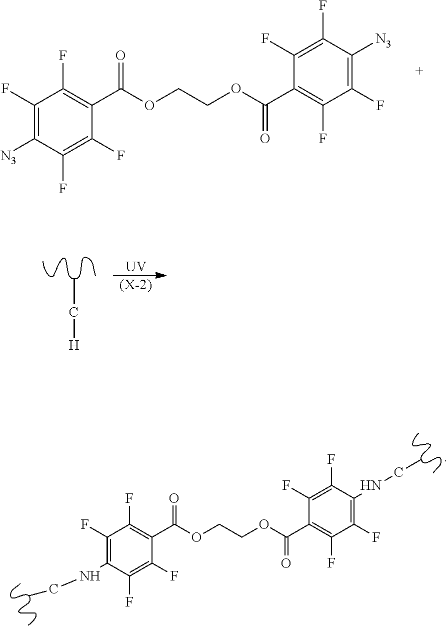

In some other examples, a reaction equation between the second type of photosensitive material and the carrier transport material is shown in equation (X-3).

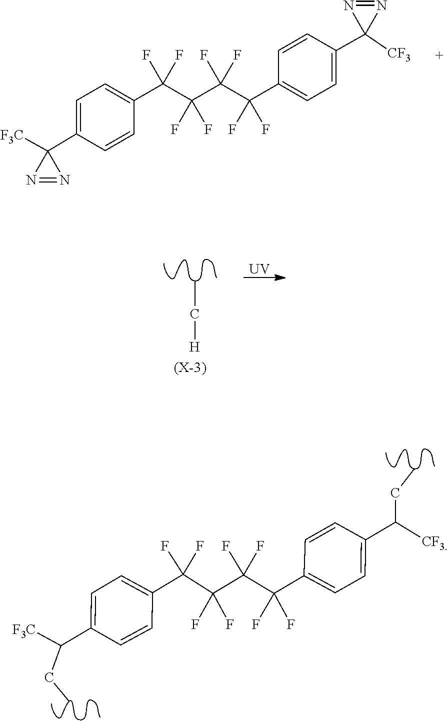

In yet other examples, a reaction equation between the second type of photosensitive material and the carrier transport material is shown in equation (X-4).

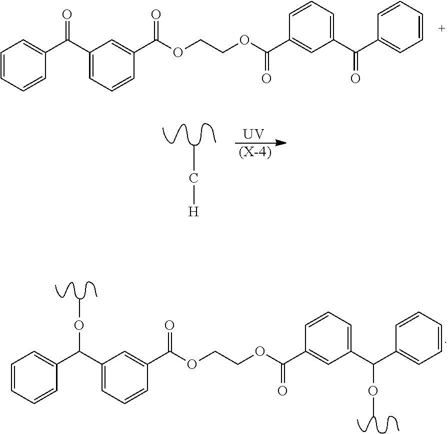

Here, [symbol] represents the hole transport material TFB, which has a structure shown in the following formula.

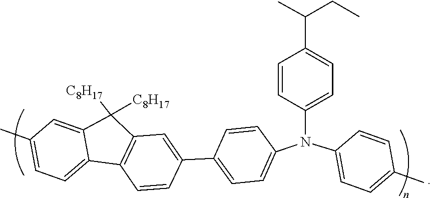

It can be understood that as described in the method for forming the first light-emitting device 201, the second light-emitting device 202 and the third light-emitting device 203, the carrier transport material and the second type of photosensitive material are applied by coating or printing after being dissolved in the second solution, the fifth solution or the eighth solution. The solvents of the second solution, the fifth solution and the eighth solution are the second solvent, the fifth solvent and the eighth solvent respectively, and all three solvents belong to the second-type solvents. The setting of the second type of photosensitive material being selected from the general formula (V-A), the general formula (V-B) or the general formula (V-C) may increase the solubility of the second type of photosensitive material in the second-type solvent (e.g., toluene, chlorobenzene or (dichloromethyl)benzene), which is beneficial to the formation of the carrier transport layer (including the first carrier transport layer 131, the second carrier transport layer 132 and the third carrier transport layer 133).

The above is an exemplary introduction to the second type of photosensitive materials and the cross-linked carrier transport materials (the first cross-linked carrier transport material, the second cross-linked carrier transport material and the third cross-linked carrier transport material). The following is an exemplary introduction to the structures of the third type of photosensitive materials and the cross-linked carrier injection materials (the first cross-linked carrier injection material, the second cross-linked carrier injection material and the third cross-linked carrier injection material).

In some embodiments, the third photosensitive material, the sixth photosensitive material and the ninth photosensitive material are the same or different, and are each independently selected from any of third type of photosensitive materials. The third type of photosensitive material includes a third photosensitive group, the third photosensitive group undergoes a cross-linking reaction with a carrier injection material under light radiation; and the carrier injection material is one of the first carrier injection material, the second carrier injection material and the third carrier injection material. Moreover, any two of the first photosensitive group, the second photosensitive group and the third photosensitive group may be the same or different.

In some embodiments, any of the first carrier injection material, the second carrier injection material and the third carrier injection material includes a carbon-hydrogen insertion group ZH. The carbon-hydrogen insertion group ZH is configured to undergo a carbon-hydrogen insertion reaction with the third photosensitive group under light radiation, where as shown in the following formula, T is an active intermediate free radical generated by the third photosensitive group under light radiation. In the carbon-hydrogen insertion group ZH, Z is any of primary carbon, secondary carbon and tertiary carbon.

(T)+Z—H [symbol] Z-(T)-H

For example, the first carrier injection material, the second carrier injection material and the third carrier injection material are hole injection materials, and are each configured to decrease a barrier for injecting holes from the anode, so that the holes may be effectively injected from the anode into the QLED light-emitting device. The hole injection material is, for example, poly(3,4-ethylenedioxythiophene)-poly(styrenesulfonate).

For example, the carrier injection material contains a C—H bond, and the carrier injection material is cross-linked with the third type of photosensitive material through a carbon-hydrogen (C—H) insertion reaction. For convenience of representation, the carrier injection material may be represented by the following formula:

H—C—(Y)

Here, Y represents a remaining structure of any of the first carrier injection material, the second carrier injection material and the third carrier injection material after removing the C—H bond; and the C—H bond is used to undergo a cross-linking reaction with the third photosensitive group of the third type of photosensitive material under light radiation.

The C—H bond in the carrier injection material may be cross-linked with the third type of photosensitive material (the third photosensitive material, the sixth photosensitive material and the ninth photosensitive material) under light radiation. A specific introduction to the cross-linking reaction refers to subsequent contents and is not described in detail here.

In some embodiments, the third photosensitive group is a benzophenone group, and the third type of photosensitive material containing a benzophenone group may be cross-linked with the carrier injection material. For example, benzophenone is photolyzed to form a triplet ketone intermediate (referring to the previous content for the structure) under light radiation (hν), and the C^{•}—O^{•} in the triplet ketone intermediate will attack a C—H bond nearby to undergo a cross-linking reaction.

In some embodiments, a reaction principle of the third type of photosensitive material and the carrier injection material (including the first carrier injection material, the second carrier injection material and the third carrier injection material) is as shown in the following formula. The active intermediate free radical C^{•}—O^{•} (carbon-oxygen free radical) contained in the triplet ketone intermediate in the third type of photosensitive material attacks the C—H bond nearby, that is, the C^{•}—O^{•} contained in the triplet ketone intermediate in the third type of photosensitive material attacks the C—H bond in the carrier injection material, so that the C—H bond in the carrier injection material is broken.

After the C—H bond in the carrier injection material is broken, a carbon free radical (C^{•}) and a hydrogen free radical (H^{•}) are formed. An oxygen free radical (O^{•}) in the third type of photosensitive material will attack the hydrogen free radical (H^{•}) to form a hydrogen-oxygen bond (—OH), and a carbon free radical (C^{•}) in the third type of photosensitive material will attack the carbon free radical (C^{•}) in the carrier injection material to form a carbon-carbon bond, so that the third type of photosensitive material and the carrier injection material (including the first carrier injection material, the second carrier injection material and the third carrier injection material) are cross-linked to form a cross-linked carrier injection material (including the first cross-linked carrier injection material, the second cross-linked carrier injection material and the third cross-linked carrier injection material).

Here, “Q” represents a linking group connecting two benzophenone groups. It will be noted that the third type of photosensitive material and carrier injection material in the formula may be non-ionic organic materials or ionic organic materials (with ionic groups and charges, not shown in the formula), and there is no limitation here.

In some embodiments, R_{B} is R₁₄, and Q is R₁₅ and at least two L₃. In this case, the third type of photosensitive material is selected from any of structures shown in the following general formula (VI-A).

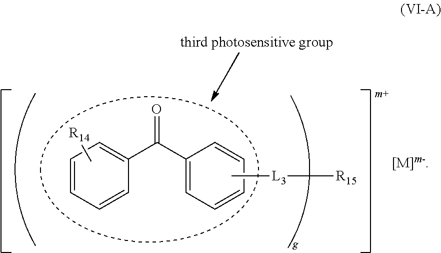

Where a benzophenone group is the third photosensitive group.

L₃ is selected from any of a single bond, an ester bond, an ether bond and a thioether bond.

R₁₄ and R₁₅ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C4.

[M]^{m-} is selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions.

g is selected from positive integers greater than or equal to 2.

m is selected from positive integers greater than or equal to 1.

It will be noted that g represents the number of the corresponding groups. The value of g is a positive integer greater than or equal to 2, that is, g may take a value of an integer of 2, 3, 4, or greater than 4.

If there are a lot of C atoms in R₁₅, g may take a large value, for example, a positive integer greater than 6. However, a large value of g may lead to difficulties in synthesis and purification during preparation of the third type of photosensitive material. However, in theory, the larger the value of g, the more reaction sites the third type of photosensitive material has. In addition, a large number of reaction sites of the third type of photosensitive material will increase molecular steric hindrance. Therefore, g may take a value of a positive integer greater than or equal to 2 and less than or equal to 6.

In some embodiments, any of the first cross-linked carrier injection material, the second cross-linked carrier injection material and the third cross-linked carrier injection material includes any of structures shown in the following general formula (III-A).

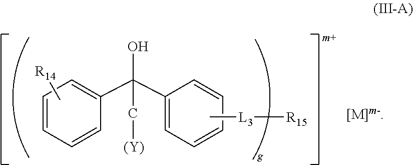

It will be noted that as for description of R₁₄, reference may be made to the above description of R₁₄. As for description of R₁₅, reference may be made to the above description of R₁₅. As for description of L₃, reference may be made to the above description of L₃. As for description of Y, reference may be made to the above description of Y. As for description of [M]^{m-}, reference may be made to the above description of [M]^{m-}. As for description of g, reference may be made to the above description of g. As for description of m, reference may be made to the above description of m. Details are not repeated here.

For example, g takes a value of 2, 3, 4, 5 or 6, which is not limited here. By setting the value of g to a positive integer greater than or equal to 2, each benzophenone group in the third type of photosensitive material may be connected to a carrier injection material molecule. Therefore, the third type of photosensitive material molecule containing benzophenone groups with the number of g may achieve connection of carrier injection material (including the first carrier injection material, the second carrier injection material and the third carrier injection material) molecules with the number of g to form a cross-linked carrier injection material (including the first cross-linked carrier injection material, the second cross-linked carrier injection material and the third cross-linked carrier injection material).

In some embodiments, R_{B} is R₁₆, and Q is R₁₇ and at least two L₄. In this case, the third type of photosensitive material is selected from any of structures shown in the following general formula (VI-B).

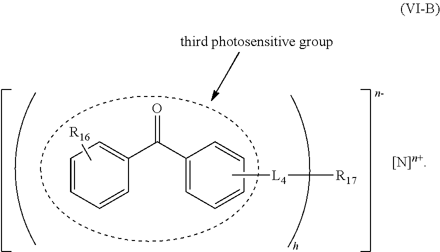

Where a benzophenone group is the third photosensitive group.

L₄ is selected from any of a single bond, an ester bond, an ether bond and a thioether bond.

R₁₆ and R₁₇ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C4.

[N]ⁿ⁺ is selected from any of organic cations and inorganic cations; the organic cations include methylammonium ions; and the inorganic cations include sodium ions and potassium ions.

h is selected from positive integers greater than or equal to 2.

n is selected from positive integers greater than or equal to 1.

It will be noted that h represents the number of the corresponding groups. The value of h is a positive integer greater than or equal to 2, that is, h may take a value of an integer of 2, 3, 4, or greater than 4.

If there are a lot of C atoms in R₁₇, h may take a large value, for example, a positive integer greater than 6. However, a large value of h may lead to difficulties in synthesis and purification during preparation of the third type of photosensitive material. However, in theory, the larger the value of h, the more reaction sites the third type of photosensitive material has. In addition, a large number of reaction sites of the third type of photosensitive material will increase molecular steric hindrance. Therefore, h may take a value of a positive integer greater than or equal to 2 and less than or equal to 6.

In some embodiments, any of the first cross-linked carrier injection material, the second cross-linked carrier injection material and the third cross-linked carrier injection material includes any of structures shown in the following general formula (III-B).

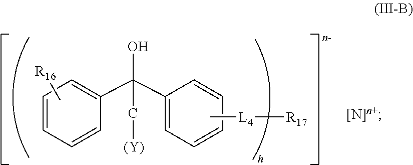

It will be noted that as for description of R₁₆, reference may be made to the above description of R₁₆. As for description of R₁₇, reference may be made to the above description of R₁₇. As for description of L₄, reference may be made to the above description of L₄. As for description of Y, reference may be made to the above description of Y. As for description of [N]ⁿ⁺, reference may be made to the above description of [N]ⁿ⁺. As for description of h, reference may be made to the above description of h. As for description of n, reference may be made to the above description of n. Details are not repeated here.

For example, h takes a value of 2, 3, 4, 5 or 6, which is not limited here. By setting the value of h to a positive integer greater than or equal to 2, each benzophenone group in the third type of photosensitive material may be connected to a carrier injection material molecule. Therefore, the third type of photosensitive material molecule containing benzophenone groups with the number of h may achieve connection of carrier injection material (including the first carrier injection material, the second carrier injection material and the third carrier injection material) molecules with the number of h to form a cross-linked carrier injection material (including the first cross-linked carrier injection material, the second cross-linked carrier injection material and the third cross-linked carrier injection material).

In some examples, the third type of photosensitive material is selected from the following structural formula.

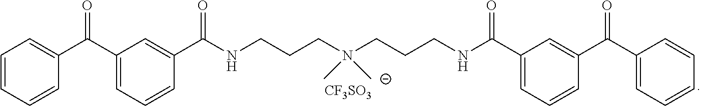

In some embodiments, the third photosensitive group is an azide group, and the third type of photosensitive material containing an azide group may be cross-linked with the carrier injection material. For example, the azide group is photolyzed to form an active intermediate free radical nitrene —\ddot{N}: under light radiation (hν), in which nitrene will attack a C—H bond nearby to undergo a cross-linking reaction.

For example, the third type of photosensitive material containing an azide group (—N₃) and the C—H bond in the carrier injection material undergo a cross-linking reaction under light irradiation, and the cross-linking reaction is shown in the following formula. Here, the third type of photosensitive material contains at least two azide groups (—N₃), each azide group (—N₃) will produce a nitrene, and each nitrene attacks a carrier injection material molecule. The third type of photosensitive material and the carrier injection material are cross-linked through a C—H insertion reaction to form a cross-linked carrier injection material (including the first cross-linked carrier injection material, the second cross-linked carrier injection material and the third cross-linked carrier injection material). The solubilities of the first cross-linked carrier injection material, the second cross-linked carrier injection material and the third cross-linked carrier injection material in the third-type solvent decrease, that is, the first cross-linked carrier injection material, the second cross-linked carrier injection material and the third cross-linked carrier injection material are each insoluble in a respective developer (e.g., the third solvent, the sixth solvent or the ninth solvent) during development.

It will be noted that the third type of photosensitive material and carrier injection material in the formula may be non-ionic organic materials or ionic organic materials (with ionic groups and charges, not shown in the formula), and there is no limitation here.

In some embodiments, R_{A} is R₁₈, and in this case, the third type of photosensitive material is selected from any of structures shown in the following general formula (VI-C).

[R₁₈ [symbol] N₃)ᵢ]^{q+}[Q]^{q-} (VI-C)

Where an azide group is the third photosensitive group.

R₁₈ is selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C4.

[Q]^{q-} is selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions.

i is selected from positive integers greater than or equal to 2.

q is selected from positive integers greater than or equal to 1.

It will be noted that i represents the number of the corresponding groups. The value of i is a positive integer greater than or equal to 2, that is, i may take a value of an integer of 2, 3, 4, or greater than 4.

If there are a lot of C atoms in R₁₈, i may take a large value, for example, a positive integer greater than 6. However, a large value of i may lead to difficulties in synthesis and purification during preparation of the third type of photosensitive material. However, in theory, the larger the value of i, the more reaction sites the third type of photosensitive material has. In addition, a large number of reaction sites of the third type of photosensitive material will increase molecular steric hindrance. Therefore, i may take a value of a positive integer greater than or equal to 2 and less than or equal to 6.

In some embodiments, any of the first cross-linked carrier injection material, the second cross-linked carrier injection material and the third cross-linked carrier injection material includes any of structures shown in the following general formula (III-C).

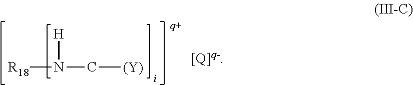

It will be noted that as for description of R₁₈, reference may be made to the above description of R₁₈. As for description of Y, reference may be made to the above description of Y. As for description of [Q]^{q-}, reference may be made to the above description of [Q]^{q-}. As for description of i, reference may be made to the above description of i. As for description of q, reference may be made to the above description of q. Details are not repeated here.

For example, i takes a value of 2, 3, 4, 5 or 6, which is not limited here. By setting the value of i to a positive integer greater than or equal to 2, each azide group in the third type of photosensitive material may be connected to a carrier injection material molecule. Therefore, the third type of photosensitive material molecule containing azide groups with the number of i may achieve connection of carrier injection material (including the first carrier injection material, the second carrier injection material and the third carrier injection material) molecules with the number of i to form a cross-linked carrier injection material (including the first cross-linked carrier injection material, the second cross-linked carrier injection material and the third cross-linked carrier injection material).

In some embodiments, R_{B} is R₁₉, and in this case, the third type of photosensitive material is selected from any of structures shown in the following general formula (VI-D).

[R₁₉ [symbol] N₃)ⱼ]^{t-}[T]^{t+} (VI-D)

Where an azide group is the third photosensitive group.

R₁₉ is selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C4.

[T]^{t+} is selected from any of organic cations and inorganic cations; the organic cations include methylammonium ions; and the inorganic cations include sodium ions and potassium ions.

j is selected from positive integers greater than or equal to 2.

t is selected from positive integers greater than or equal to 1.

It will be noted that j represents the number of the corresponding groups. The value of j is a positive integer greater than or equal to 2, that is, j may take a value of an integer of 2, 3, 4, or greater than 4.

If there are a lot of C atoms in R₁₉, j may take a large value, for example, a positive integer greater than 6. However, a large value of j may lead to difficulties in synthesis and purification during preparation of the third type of photosensitive material. However, in theory, the larger the value of j, the more reaction sites the third type of photosensitive material has. In addition, a large number of reaction sites of the third type of photosensitive material will increase molecular steric hindrance. Therefore, j may take a value of a positive integer greater than or equal to 2 and less than or equal to 6.

In some embodiments, any of the first cross-linked carrier injection material, the second cross-linked carrier injection material and the third cross-linked carrier injection material includes any of structures shown in the following general formula (III-D).

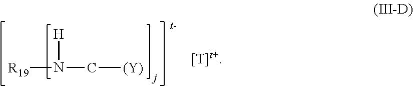

It will be noted that as for description of R₁₉, reference may be made to the above description of R₁₉. As for description of Y, reference may be made to the above description of Y. As for description of [T]^{t+}, reference may be made to the above description of [T]^{t+}. As for description of j, reference may be made to the above description of j. As for description of t, reference may be made to the above description of t. Details are not repeated here.

For example, j takes a value of 2, 3, 4, 5 or 6, which is not limited here. By setting the value of j to a positive integer greater than or equal to 2, each azide group in the third type of photosensitive material may be connected to a carrier injection material molecule. Therefore, the third type of photosensitive material molecule containing azide groups with the number of j may achieve connection of carrier injection material (including the first carrier injection material, the second carrier injection material and the third carrier injection material) molecules with the number of j to form a cross-linked carrier injection material (including the first cross-linked carrier injection material, the second cross-linked carrier injection material and the third cross-linked carrier injection material).

In some examples, the third type of photosensitive material is selected from any of the following structural formulas.

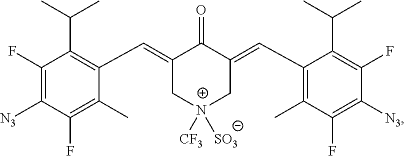

### 3′-bis(4-azido-3,5-difluoro-2,6-diisopropylbenzamido)dipropyldimethylammonium trifluoromethanesulfonate

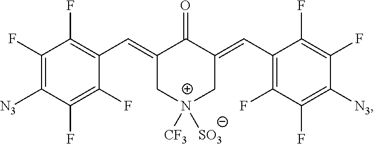

### 3′-bis(4-azido-2,3,5,6-tetrafluorobenzamido)dipropyldimethylammoniumtrifluoromethane sulfonate

In some embodiments, the third photosensitive group is a diazirine group, and the third type of photosensitive material containing a diazirine group may be cross-linked with the carrier injection material. For example, the diazirine group is photolyzed to form an active intermediate free radical carbene —\ddot{C} under light radiation (hν), in which carbene will attack a C—H bond nearby to undergo a cross-linking reaction.

For example, the third type of photosensitive material containing a diazirine group and the C—H bond in the carrier injection material undergo a cross-linking reaction under light irradiation, and the cross-linking reaction is shown in the following formula. Here, the third type of photosensitive material contains at least two diazirine groups, each diazirine group will produce a carbene, and each carbene attacks a carrier injection material molecule. The third type of photosensitive material and the carrier injection material are cross-linked through a C—H insertion reaction to form a cross-linked carrier injection material (including the first cross-linked carrier injection material, the second cross-linked carrier injection material and the third cross-linked carrier injection material). The solubilities of the first cross-linked carrier injection material, the second cross-linked carrier injection material and the third cross-linked carrier injection material in the third-type solvent decrease, that is, the first cross-linked carrier injection material, the second cross-linked carrier injection material and the third cross-linked carrier injection material are each insoluble in a respective developer (e.g., the third solvent, the sixth solvent or the ninth solvent) during development.

It will be noted that the third type of photosensitive material and carrier injection material in the formula may be non-ionic organic materials or ionic organic materials (with ionic groups and charges, not shown in the formula), and there is no limitation here.

In some embodiments, R_{C} is R₂₁, and R_{D} is R₂₀. In this case, the third type of photosensitive material is selected from any of structures shown in the following general formula (VI-E).

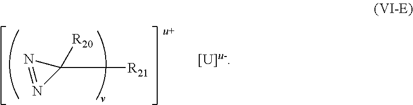

Where a diazirine group is the third photosensitive group.

R₂₀ and R₂₁ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

[U]^{u-} is selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions.

k is selected from positive integers greater than or equal to 2.

u is selected from positive integers greater than or equal to 1.

It will be noted that k represents the number of the corresponding groups. The value of k is a positive integer greater than or equal to 2, that is, k may take a value of an integer of 2, 3, 4, or greater than 4.

If there are a lot of C atoms in R₂₁, k may take a large value, for example, a positive integer greater than 6. However, a large value of k may lead to difficulties in synthesis and purification during preparation of the third type of photosensitive material. However, in theory, the larger the value of k, the more reaction sites the third type of photosensitive material has. In addition, a large number of reaction sites of the third type of photosensitive material will increase molecular steric hindrance. Therefore, k may take a value of a positive integer greater than or equal to 2 and less than or equal to 6.

In some embodiments, any of the first cross-linked carrier injection material, the second cross-linked carrier injection material and the third cross-linked carrier injection material includes any of structures shown in the following general formula (III-E).

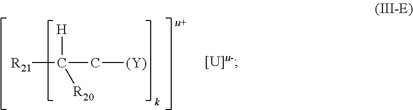

It will be noted that as for description of R₂₀, reference may be made to the above description of R₂₀. As for description of R₂₁, reference may be made to the above description of R₂₁. As for description of Y, reference may be made to the above description of Y. As for description of [U]^{u-}, reference may be made to the above description of [U]^{u-}. As for description of k, reference may be made to the above description of k. As for description of u, reference may be made to the above description of u. Details are not repeated here.

For example, k takes a value of 2, 3, 4, 5 or 6, which is not limited here. By setting the value of k to a positive integer greater than or equal to 2, each diazirine group in the third type of photosensitive material may be connected to a carrier injection material molecule. Therefore, the third type of photosensitive material molecule containing diazirine groups with the number of k may achieve connection of carrier injection material (including the first carrier injection material, the second carrier injection material and the third carrier injection material) molecules with the number of k to form a cross-linked carrier injection material (including the first cross-linked carrier injection material, the second cross-linked carrier injection material and the third cross-linked carrier injection material).

In some embodiments, R_{C} is R₂₃, and R_{D} is R₂₂. In this case, the third type of photosensitive material is selected from any of structures shown in the following general formula (VI-F).

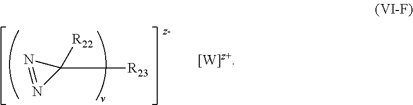

Where a diazirine group is the third photosensitive group.

R₂₂ and R₂₃ are the same or different, and are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40.

[W]^{z+} is selected from any of organic cations and inorganic cations; the organic cations include methylammonium ions; and the inorganic cations include sodium ions and potassium ions.

v is selected from positive integers greater than or equal to 2.

z is selected from positive integers greater than or equal to 1.

It will be noted that v represents the number of the corresponding groups. The value of v is a positive integer greater than or equal to 2, that is, v may take a value of an integer of 2, 3, 4, or greater than 4.

If there are a lot of C atoms in R₂₃, v may take a large value, for example, a positive integer greater than 6. However, a large value of v may lead to difficulties in synthesis and purification during preparation of the third type of photosensitive material. However, in theory, the larger the value of v, the more reaction sites the third type of photosensitive material has. In addition, a large number of reaction sites of the third type of photosensitive material will increase molecular steric hindrance. Therefore, v may take a value of a positive integer greater than or equal to 2 and less than or equal to 6.

In some embodiments, any of the first cross-linked carrier injection material, the second cross-linked carrier injection material and the third cross-linked carrier injection material includes any of structures shown in the following general formula (III-F).

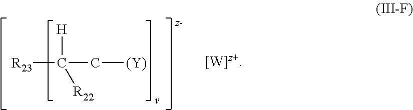

It will be noted that as for description of R₂₂, reference may be made to the above description of R₂₂. As for description of R₂₃, reference may be made to the above description of R₂₃. As for description of Y, reference may be made to the above description of Y. As for description of [W]^{z+}, reference may be made to the above description of [W]^{z+}. As for description of v, reference may be made to the above description of v. As for description of z, reference may be made to the above description of z. Details are not repeated here.

For example, v takes a value of 2, 3, 4, 5 or 6, which is not limited here. By setting the value of v to a positive integer greater than or equal to 2, each diazirine group in the third type of photosensitive material may be connected to a carrier injection material molecule. Therefore, the third type of photosensitive material molecule containing diazirine groups with the number of v may achieve connection of carrier injection material (including the first carrier injection material, the second carrier injection material and the third carrier injection material) molecules with the number of v to form a cross-linked carrier injection material (including the first cross-linked carrier injection material, the second cross-linked carrier injection material and the third cross-linked carrier injection material).

In some examples, the third type of photosensitive material is selected from the following structural formula (Fast Blue B Salt (FBBS)).

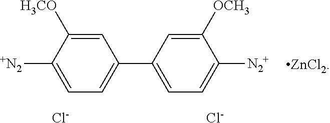

In some examples, a reaction equation between the third type of photosensitive material and the carrier injection material is shown in equation (X-1).

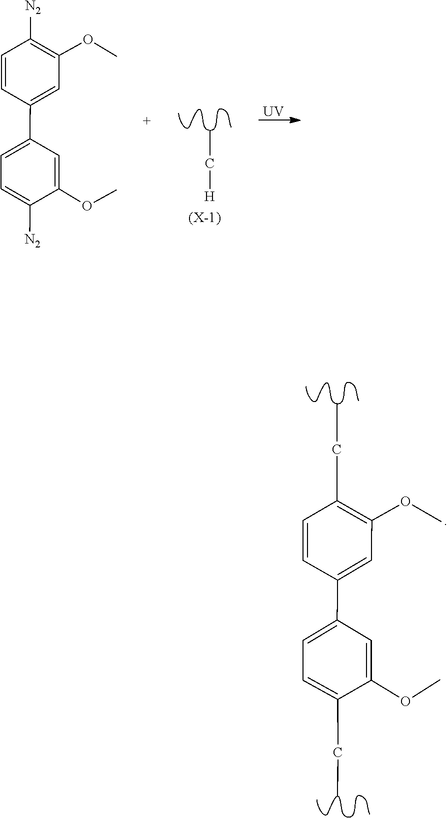

In the formula, [symbol] represents the hole injection material PEDOT, which has a structure shown in the following formula.

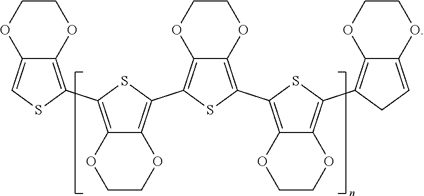

It can be understood that as described in the method for forming the first light-emitting device 201, the second light-emitting device 202 and the third light-emitting device 203, the carrier injection material and the third type of photosensitive material are applied by coating or printing after being dissolved in the third solution, the sixth solution or the ninth solution. The solvents of the third solution, the sixth solution and the ninth solution are the third solvent, the sixth solvent and the ninth solvent respectively, and all three solvents belong to the third-type solvents. The setting of the third type of photosensitive material being selected from the general formula (VI-A), the general formula (VI-B), the general formula (VI-C), the general formula (VI-D), the general formula (VI-E) or the general formula (VI-F) makes the third type of photosensitive material an ionic material (such as a water-soluble organic salt). In this way, the solubility of the third type of photosensitive material in the third-type solvent (e.g., water, ethanol, methanol, N,N-dimethylformamide, N-methylformamide and thionyl chloride) may increase, which is beneficial to the formation of the carrier injection layer (including the first carrier injection layer 141, the second carrier injection layer 142 and the third carrier injection layer 143). In addition, since the carrier transport layer (including the first carrier transport layer 131, the second carrier transport layer 132 and the third carrier transport layer 133) adjacent to the carrier injection layer is prepared using the second-type solvent, the above setting makes the solubility of the third type of photosensitive material in the third-type solvent greater than the solubility thereof in the second-type solvent (including the second solvent, the fifth solvent and the eighth solvent). Thus, when the first light-emitting device 201, the second light-emitting device 202 and the third light-emitting device 203 are formed, the third type of photosensitive material is not easily transferred from the initial carrier injection layer (including the first initial carrier injection layer 141i, the second initial carrier injection layer 142i and the third initial carrier injection layer 143i) to the initial carrier transport layer (including the first initial carrier transport layer 131i, the second initial carrier transport layer 132i and the third initial carrier transport layer 133i).

In some embodiments, R₅, R₆ and R₇ are the same or different, and are each independently selected from any of a C1 to C30 saturated or unsaturated straight or branched alkyl group, a C1 to C30 saturated or unsaturated straight or branched alkyl group in which at least one hydrogen atom is replaced by a fluorine atom, and a C10 to C30 saturated or unsaturated straight or branched alkyl group containing at least one ether bond.

It can be understood that as described in the method for forming the first light-emitting device 201, the second light-emitting device 202 and the third light-emitting device 203, the quantum dot material and the first type of photosensitive material are applied by coating or printing after being dissolved in the first solution, the fourth solution or the seventh solution. The solvents of the first solution, the fourth solution and the seventh solution are the first solvent, the fourth solvent and the seventh solvent respectively, and all three solvents belong to the first-type solvents. The setting of R₅, R₆ and R₇ being each selected from any of a C1 to C30 saturated or unsaturated straight or branched alkyl group, a C1 to C30 saturated or unsaturated straight or branched alkyl group in which at least one hydrogen atom is replaced by a fluorine atom, and a C10 to C30 saturated or unsaturated straight or branched alkyl group containing at least one ether bond may increase polarities of R₅, R₆ and R₇ and increase a polarity of the first type of photosensitive material. In this way, the solubility of the first type of photosensitive material in the first-type solvent (e.g., octane or propylene glycol methyl ether acetate) may increase, which is beneficial to the formation of the light-emitting pattern 23 (including the first light-emitting pattern 23a, the second light-emitting pattern 23b and the third light-emitting pattern 23c). In addition, since the carrier transport layer (including the first carrier transport layer 131, the second carrier transport layer 132 and the third carrier transport layer 133) adjacent to the light-emitting pattern 23 is prepared using the second-type solvent, the above setting makes the solubility of the first type of photosensitive material in the first-type solvent greater than the solubility thereof in the second-type solvent (including the second solvent, the fifth solvent and the eighth solvent). Thus, when the first light-emitting device 201, the second light-emitting device 202 and the third light-emitting device 203 are formed, the first type of photosensitive material is not easily transferred from the initial light-emitting pattern (including the first initial light-emitting pattern 23ai, the second initial light-emitting pattern 23bi and the third initial light-emitting pattern 23ci) to the initial carrier transport layer (including the first initial carrier transport layer 131i, the second initial carrier transport layer 132i and the third initial carrier transport layer 133i).

In some embodiments, R₁₀, R₁₁ and R₁₂ are the same or different, and are each independently selected from C1 to C8 saturated or unsaturated straight or branched alkyl groups.

It can be understood that as described in the method for forming the first light-emitting device 201, the second light-emitting device 202 and the third light-emitting device 203, the carrier transport material and the second type of photosensitive material are applied by coating and printing after being dissolved in the second solution, the fifth solution or the eighth solution. The solvents of the second solution, the fifth solution and the eighth solution are the second solvent, the fifth solvent and the eighth solvent respectively, and all three solvents belong to the second-type solvents. The setting of R₁₀, R₁₁ and R₁₂ being each selected from C1 to C8 saturated or unsaturated straight or branched alkyl groups may make polarities of R₁₀, R₁₁ and R₁₂ moderate and make a polarity of the second type of photosensitive material moderate. In this way, the solubility of the second type of photosensitive material in the second-type solvent (e.g., toluene, chlorobenzene or (dichloromethyl)benzene) may increase, which is beneficial to the formation of the carrier transport layer (including the first carrier transport layer 131, the second carrier transport layer 132 and the third carrier transport layer 133). In addition, since the carrier injection layer (including the first carrier injection layer 141, the second carrier injection layer 142 and the third carrier injection layer 143) adjacent to the carrier transport layer is prepared using the third-type solvent, and the light-emitting pattern 23 (including the first light-emitting pattern 23a, the second light-emitting pattern 23b and the third light-emitting pattern 23c) adjacent to the carrier transport layer is prepared using the first-type solvent, the above setting makes the solubility of the second type of photosensitive material in the second-type solvent greater than both the solubility thereof in the first-type solvent (including the first solvent, the fourth solvent and the seventh solvent) and the solubility thereof in the third-type solvent (including the third solvent, the sixth solvent and the ninth solvent). Thus, when the first light-emitting device 201, the second light-emitting device 202 and the third light-emitting device 203 are formed, the second type of photosensitive material is not easily transferred from the initial carrier transport layer (including the first initial carrier transport layer 131i, the second initial carrier transport layer 132i and the third initial carrier transport layer 133i) to the initial carrier injection layer (including the first initial carrier injection layer 141i, the second initial carrier injection layer 142i and the third initial carrier injection layer 143i) or the initial light-emitting pattern (including the first initial light-emitting pattern 23ai, the second initial light-emitting pattern 23bi and the third initial light-emitting pattern 23ci).

In some embodiments, R₁₅, R₁₇, R₁₈, R₁₉, R₂₁ and R₂₃ are the same or different, and are each independently selected from any of a C1 to C40 carbon chain containing an ester bond, a C1 to C40 carbon chain containing an ether bond, a C1 to C40 carbon chain containing a carbonyl group, a C1 to C40 carbon chain containing an acylamino group, a C1 to C40 carbon chain containing a carboxyl group, a C1 to C40 carbon chain containing an amino group and a C1 to C40 carbon chain containing an aldehyde group.

It can be understood that as described in the method for forming the first light-emitting device 201, the second light-emitting device 202 and the third light-emitting device 203, the carrier injection material and the third type of photosensitive material are applied by coating and printing after being dissolved in the third solution, the sixth solution or the ninth solution. The solvents of the third solution, the sixth solution and the ninth solution are the third solvent, the sixth solvent and the ninth solvent respectively, and all three solvents belong to the third-type solvents. The setting of R₁₅, R₁₇, R₁₈, R₁₉, R₂₁ and R₂₃ being selected from any of a C1 to C40 carbon chain containing an ester bond, a C1 to C40 carbon chain containing an ether bond, a C1 to C40 carbon chain containing a carbonyl group, a C1 to C40 carbon chain containing an acylamino group, a C1 to C40 carbon chain containing a carboxyl group, a C1 to C40 carbon chain containing an amino group and a C1 to C40 carbon chain containing an aldehyde group may make polarities of R₁₅, R₁₇, R₁₈, R₁₉, R₂₁ and R₂₃ large and make a polarity of the third type of photosensitive material large. In this way, the solubility of the third type of photosensitive material in the third-type solvent (e.g., water, ethanol, methanol, N,N-dimethylformamide, N-methylformamide and thionyl chloride) may increase, which is beneficial to the formation of the carrier injection layer (including the first carrier injection layer 141, the second carrier injection layer 142 and the third carrier injection layer 143). In addition, since the carrier transport layer (including the first carrier transport layer 131, the second carrier transport layer 132 and the third carrier transport layer 133) adjacent to the carrier injection layer is prepared using the second-type solvent, the above setting makes the solubility of the third type of photosensitive material in the third-type solvent greater than the solubility thereof in the second-type solvent (including the second solvent, the fifth solvent and the eighth solvent). Thus, when the first light-emitting device 201, the second light-emitting device 202 and the third light-emitting device 203 are formed, the third type of photosensitive material is not easily transferred from the initial carrier injection layer (including the first initial carrier injection layer 141i, the second initial carrier injection layer 142i and the third initial carrier injection layer 143i) to the initial carrier transport layer (including the first initial carrier transport layer 131i, the second initial carrier transport layer 132i and the third initial carrier transport layer 133i).

In some embodiments, under ultraviolet light with a wavelength ranging from 200 nm to 400 nm, a molar extinction coefficient of the third type of photosensitive material is greater than 1 cm⁻¹ (mol/L)⁻¹.

It can be understood that in a case of a high molar extinction coefficient of the third type of photosensitive material, when the third type of photosensitive material and the carrier injection material undergo a cross-linking reaction under light radiation, a utilization rate of light is high and an efficiency of the cross-linking reaction is also high. Therefore, the setting of the molar extinction coefficient of the third type of photosensitive material being greater than 1 cm⁻¹ (mol/L)⁻¹ may increase the utilization rate of light when the third type of photosensitive material and the carrier injection material undergo a cross-linking reaction under light radiation. In this way, a photo-cross-linking efficiency of the third type of photosensitive material and the carrier injection material may be improved.

In some embodiments, under ultraviolet light with a wavelength ranging from 200 nm to 400 nm, a molar extinction coefficient of the third type of photosensitive material is greater than 1000 cm⁻¹ (mol/L)⁻¹. For example, a molar extinction coefficient of the third type of photosensitive material is 2000 cm⁻¹ (mol/L)⁻¹, 3000 cm⁻¹ (mol/L)⁻¹, 4000 cm⁻¹ (mol/L)⁻¹ or 5000 cm⁻¹ (mol/L)⁻¹.

In some embodiments, a polarity of the third solvent is greater than a polarity of the second solvent; and the polarity of the second solvent is greater than a polarity of the first solvent.

In the related art, a solvent used during deposition of a specific layer will not damage a previously-deposited layer in a dissolve or other ways, and the solvent is often referred to as being orthogonal to the previous (i.e., previously-deposited) layer.

In a case where the polarity of the third solvent is greater than the polarity of the second solvent, the solubility of the first carrier injection material in the third solvent is much greater than the solubility thereof in the second solvent, and the solubility of the third photosensitive material in the third solvent is much greater than the solubility thereof in the second solvent. In this way, the solvent (i.e., the second solvent) of the first initial carrier transport layer 131i may be orthogonal to the first initial carrier injection layer 141i. In other words, during formation of the first light-emitting device 201, when the first initial carrier transport layer 131i is applied by coating or printing, the first carrier injection material and the third photosensitive material will remain at a position of the first initial carrier injection layer 141i and will not be dissolved or transferred into the first initial carrier transport layer 131i (i.e., the second solution). Thus, after light radiation, the first cross-linked carrier injection material will be located in the first carrier injection layer 141 to improve a carrier injection effect.

In a case where the polarity of the second solvent is greater than the polarity of the first solvent, the solubility of the first carrier transport material in the second solvent is much greater than the solubility thereof in the first solvent, and the solubility of the second photosensitive material in the second solvent is much greater than the solubility thereof in the first solvent. In this way, the solvent (i.e., the first solvent) of the first initial light-emitting pattern 23ai may be orthogonal to the first initial carrier transport layer 131i. In other words, during formation of the first light-emitting device 201, when the first initial light-emitting pattern 23ai is applied by coating or printing, the first carrier transport material and the second photosensitive material will remain at a position of the first initial carrier transport layer 131i and will not be dissolved or transferred into the first initial light-emitting pattern 23ai (i.e., the first solution). Thus, after light radiation, the first cross-linked carrier transport material will be located in the first carrier transport layer 131 to improve a carrier transport effect.

In some embodiments, a polarity of the sixth solvent is greater than a polarity of the fifth solvent; and the polarity of the fifth solvent is greater than a polarity of the fourth solvent.

In a case where the polarity of the sixth solvent is greater than the polarity of the fifth solvent, the solubility of the second carrier injection material in the sixth solvent is much greater than the solubility thereof in the fifth solvent, and the solubility of the sixth photosensitive material in the sixth solvent is much greater than the solubility thereof in the fifth solvent. In this way, the solvent (i.e., the fifth solvent) of the second initial carrier transport layer 132i may be orthogonal to the second initial carrier injection layer 142i. In other words, during formation of the second light-emitting device 202, when the second initial carrier transport layer 132i is applied by coating or printing, the second carrier injection material and the sixth photosensitive material will remain at a position of the second initial carrier injection layer 142i and will not be dissolved or transferred into the second initial carrier transport layer 132i (i.e., the fifth solution). Thus, after light radiation, the second cross-linked carrier injection material will be located in the second carrier injection layer 142 to improve a carrier injection effect.

In a case where the polarity of the fifth solvent is greater than the polarity of the fourth solvent, the solubility of the second carrier transport material in the fifth solvent is much greater than the solubility thereof in the fourth solvent, and the solubility of the fifth photosensitive material in the fifth solvent is much greater than the solubility thereof in the fourth solvent. In this way, the solvent (i.e., the fourth solvent) of the second initial light-emitting pattern 23bi may be orthogonal to the second initial carrier transport layer 132i. In other words, during formation of the second light-emitting device 202, when the second initial light-emitting pattern 23bi is applied by coating or printing, the second carrier transport material and the fifth photosensitive material will remain at a position of the second initial carrier transport layer 132i and will not be dissolved or transferred into the second initial light-emitting pattern 23bi (i.e., the fourth solution). Thus, after light radiation, the second cross-linked carrier transport material will be located in the second carrier transport layer 132 to improve a carrier transport effect.

In some embodiments, a polarity of the ninth solvent is greater than a polarity of the eighth solvent; and the polarity of the eighth solvent is greater than a polarity of the seventh solvent.

In a case where the polarity of the ninth solvent is greater than the polarity of the eighth solvent, the solubility of the third carrier injection material in the ninth solvent is much greater than the solubility thereof in the eighth solvent, and the solubility of the ninth photosensitive material in the ninth solvent is much greater than the solubility thereof in the eighth solvent. In this way, the solvent (i.e., the eighth solvent) of the third initial carrier transport layer 133i may be orthogonal to the third initial carrier injection layer 143i. In other words, during formation of the third light-emitting device 203, when the third initial carrier transport layer 133i is applied by coating or printing, the third carrier injection material and the ninth photosensitive material will remain at a position of the third initial carrier injection layer 143i and will not be dissolved or transferred into the third initial carrier transport layer 133i (i.e., the eighth solution). Thus, after light radiation, the third cross-linked carrier injection material will be located in the third carrier injection layer 143 to improve a carrier injection effect.

In a case where the polarity of the eighth solvent is greater than the polarity of the seventh solvent, the solubility of the third carrier transport material in the eighth solvent is much greater than the solubility thereof in the seventh solvent, and the solubility of the eighth photosensitive material in the eighth solvent is much greater than the solubility thereof in the seventh solvent. In this way, the solvent (i.e., the seventh solvent) of the third initial light-emitting pattern 23ci may be orthogonal to the third initial carrier transport layer 133i. In other words, during formation of the third light-emitting device 203, when the third initial light-emitting pattern 23ci is applied by coating or printing, the third carrier transport material and the eighth photosensitive material will remain at a position of the third initial carrier transport layer 133i and will not be dissolved or transferred into the third initial light-emitting pattern 23ci (i.e., the seventh solution). Thus, after light radiation, the third cross-linked carrier transport material will be located in the third carrier transport layer 133 to improve a carrier transport effect.

In some embodiments, the first-type solvent is orthogonal to the initial carrier injection layer (including the first initial carrier injection layer 141i, the second initial carrier injection layer 142i and the third initial carrier injection layer 143i).

In some embodiments, the first-type solvent is at least one of octane and propylene glycol methyl ether acetate; and the first-type solvent is any of the first solvent, the fourth solvent and the seventh solvent. The second-type solvent is at least one of toluene, chlorobenzene and (dichloromethyl)benzene; and the second-type solvent is any of the second solvent, the fifth solvent and the eighth solvent. The third-type solvent is at least one of water, ethanol, methanol, N,N-dimethylformamide, N-methylformamide and thionyl chloride; and the third-type solvent is any of the third solvent, the sixth solvent and the ninth solvent.

Such a setting may make the polarity of the third-type solvent greater than the polarity of the second-type solvent, and make the polarity of the second-type solvent greater than the polarity of the first-type solvent. In this way, the second-type solvent is orthogonal to the first initial carrier injection layer 141i, the second initial carrier injection layer 142i and the third initial carrier injection layer 143i; and the first-type solvent is orthogonal to the first initial carrier transport layer 131i, the second initial carrier transport layer 132i and the third initial carrier transport layer 133i.

The light-emitting substrate 1 is exemplarily introduced above, and a method for manufacturing the light-emitting substrate 1 is exemplarily introduced below.

Some embodiments of the present disclosure further provide a method for manufacturing a light-emitting substrate 1. As shown in FIGS. 3A to 3B, a plurality of light-emitting devices 20 are formed on a substrate 11. The plurality of light-emitting devices 20 are arranged in a first direction X, where the first direction is parallel to a plane X1 where the substrate 11 is located. Each light-emitting device 20 in the plurality of light-emitting devices 20 includes a first electrode 21, a second electrode 22, and a light-emitting pattern 23 disposed between the first electrode 21 and the second electrode 22. The plurality of light-emitting devices 20 include at least one first light-emitting device 201. Each first light-emitting device 201 in the at least one first light-emitting device 201 includes a first light-emitting pattern 23a, and a first carrier transport layer 131 and a first carrier injection layer 141 that are provided between the substrate 11 and the first light-emitting pattern 23a. The first carrier transport layer 131 is closer to the first light-emitting pattern 23a than the first carrier injection layer 141. A material of the first light-emitting pattern 23a includes a first cross-linked light-emitting material; a material of the first carrier transport layer 131 includes a first cross-linked carrier transport material; and a material of the first carrier injection layer 141 includes a first cross-linked carrier injection material.

For example, the first cross-linked light-emitting material is generated by cross-linking of a first quantum dot material under light radiation; alternatively, the first cross-linked light-emitting material is generated by cross-linking of a first quantum dot material and a first photosensitive material under light radiation.

For example, the first cross-linked carrier transport material is generated by cross-linking of a first carrier transport material under light radiation; alternatively, the first cross-linked carrier transport material is generated by cross-linking of a first carrier transport material and a second photosensitive material under light radiation.

For example, the first cross-linked carrier injection material is generated by cross-linking of a first carrier injection material under light radiation; alternatively, the first cross-linked carrier injection material is generated by cross-linking of a first carrier injection material and a third photosensitive material under light radiation.

As for the introduction to the first cross-linked light-emitting material, the first quantum dot material, the first photosensitive material, the first cross-linked carrier transport material, the first carrier transport material, the second photosensitive material, the first cross-linked carrier injection material, the first carrier injection material and the third photosensitive material, reference may be made to the above contents and details are not repeated here.

Beneficial effects that can be achieved by the method for manufacturing the light-emitting substrate 1 provided in some embodiments of the present disclosure are the same as beneficial effects that can be achieved by the light-emitting substrate 1 provided in the above technical solution, and details are not repeated here.

In some embodiments, a method for manufacturing the light-emitting substrate 1 includes S1′ to S4′.

In S1′, at least one first light-emitting device 201 is formed; and the first light-emitting device 201 includes a first light-emitting pattern 23a.

In S2′, at least one second light-emitting device 202 is formed; and the second light-emitting device 202 includes a second light-emitting pattern 23b.

In S3′, at least one third light-emitting device 203 is formed; and the third light-emitting device 203 includes a third light-emitting pattern 23c.

In S4′, a second electrode 22 is formed on a side of the first light-emitting pattern 23a, the second light-emitting pattern 23b and the third light-emitting pattern 23c away from the substrate 11.

For example, a method for forming the second electrode 22 is electrophoretic deposition.

In some embodiments, forming at least one first light-emitting device 201 includes, as shown in FIGS. 4, M1 to M4.

In M1, a first electrode layer 21a is formed on the substrate 11; and the first electrode layer 21a includes a first electrode 21 of at least one first light-emitting device 201.

For example, a process of forming the first electrode layer 21a is magnetron sputtering.

For example, the first electrodes 21 and openings Q in the pixel defining layer 12 are in one-to-one correspondence.

In M2, a first initial carrier injection layer 141i, a first initial carrier transport layer 131i and a first initial light-emitting pattern 23ai are sequentially formed on a side of the first electrode layer 21a away from the substrate 11. A material of the first initial carrier injection layer 141i includes a first carrier injection material, or includes a first carrier injection material and a third photosensitive material. A material of the first initial carrier transport layer 131i includes a first carrier transport material, or includes a first carrier transport material and a second photosensitive material. A material of the first initial light-emitting pattern 23ai includes a first quantum dot material, or includes a first quantum dot material and a first photosensitive material.

It can be understood that as shown in FIG. 4, the first initial carrier injection layer 141i, the first initial carrier transport layer 131i and the first initial light-emitting pattern 23ai are also formed on a surface of the pixel defining layer.

For example, a process for forming the first initial carrier injection layer 141i is any of spin coating, screen printing, scraping coating and drip coating, and a process solution is a third solution. As for an introduction to the third solution, reference may be made to the above contents, and details are not repeated here.

For example, a process for forming the first initial carrier transport layer 131i is any of spin coating, screen printing, scraping coating and drip coating, and a process solution is a second solution. As for an introduction to the second solution, reference may be made to the above contents, and details are not repeated here.

For example, a process for forming the first initial light-emitting pattern 23ai is any of spin coating, screen printing, scraping coating and drip coating, and a process solution is a first solution. As for an introduction to the first solution, reference may be made to the above contents, and details are not repeated here.

As for the introduction to the first carrier injection material, the third photosensitive material, the first carrier transport material, the second photosensitive material, the first quantum dot material and the first photosensitive material, reference may be made to the above contents and details are not repeated here.

In M3, the first initial carrier injection layer 141i, the first initial carrier transport layer 131i and the first initial light-emitting pattern 23ai that are stacked are exposed to convert a material of an exposed portion of the first initial carrier injection layer 141i into a first cross-linked carrier injection material, convert a material of an exposed portion of the first initial carrier transport layer 131i into a first cross-linked carrier transport material, and convert a material of an exposed portion of the first initial light-emitting pattern 23ai into a first cross-linked light-emitting material.

The first initial carrier injection layer 141i, the first initial carrier transport layer 131i and the first initial light-emitting pattern 23ai that are stacked being exposed as described above means that a first region W1 where at least one first light-emitting device 201 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the first cross-linked carrier injection material, the first cross-linked carrier transport material and the first cross-linked light-emitting material, reference may be made to the above contents and details are not repeated here.

In M4, the first initial carrier injection layer 141i, the first initial carrier transport layer 131i and the first initial light-emitting pattern 23ai that are stacked are developed to form the first carrier injection layer 141, the first carrier transport layer 131 and the first light-emitting pattern 23a that are stacked.

For example, M4 may include three steps of development, where developers in the three steps of development are a first solvent, a second solvent and a third solvent, and an order of the three steps of development is, for example, the first solvent, the second solvent and the third solvent. As for the introduction to the first solvent, the second solvent and the third solvent, reference may be made to the above contents and details are not repeated here.

Through the above development process, portions of the first initial carrier injection layer 141i, the first initial carrier transport layer 131i and the first initial light-emitting pattern 23ai located in a second region W2 may be removed. The second region W2 is a remaining region, except a region where at least one first light-emitting device 201 is located, in a region where the plurality of light-emitting devices 20 are located.

For example, when developing is performed using the first solvent, a portion of the first quantum dot material proximate to the substrate 11, or portions of the first quantum dot material and the first photosensitive material proximate to the substrate 11 may have a residue, and a first temporary residual layer may be residual in the second region W2. When developing is performed using the second solvent, a portion of the first carrier transport material proximate to the substrate 11, or portions of the first carrier transport material and the second photosensitive material proximate to the substrate 11 may have a residue, and a second temporary residual layer may be residual in the second region W2; moreover, the first temporary residual layer residual in the second region W2 may be removed, thereby effectively preventing the first quantum dot material from remaining in the second region W2. When developing is performed using the third solvent, a portion of the first carrier injection material proximate to the substrate 11, or portions of the first carrier injection material and the third photosensitive material proximate to the substrate 11 may have a residue, and a first initial residual pattern 330 may be residual in the second region W2; moreover, the second temporary residual layer residual in the second region W2 may be removed, thereby effectively improving a removal rate of the first quantum dot material and reducing a residual probability of the first quantum dot material. As for the introduction to the first temporary residual layer, the second temporary residual layer and the first initial residual pattern 330, reference may be made to the above contents and details are not repeated here.

In the above method for forming the at least one first light-emitting device 201, the first initial carrier injection layer 141i, the first initial carrier transport layer 131i and the first initial light-emitting pattern 23ai are exposed at one time, and thus the process of the at least one first light-emitting device 201 may be simplified.

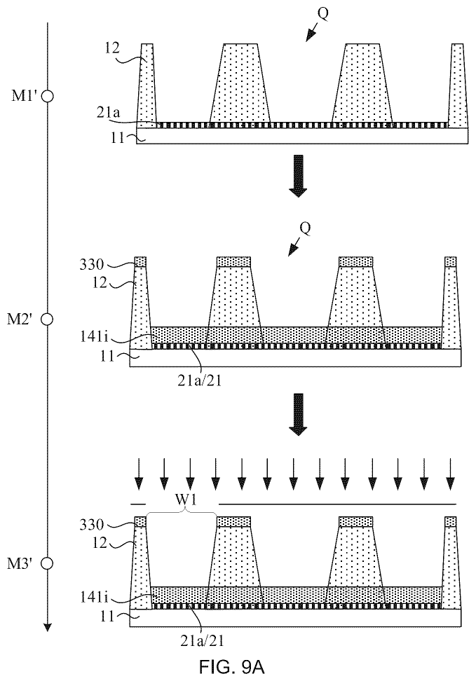

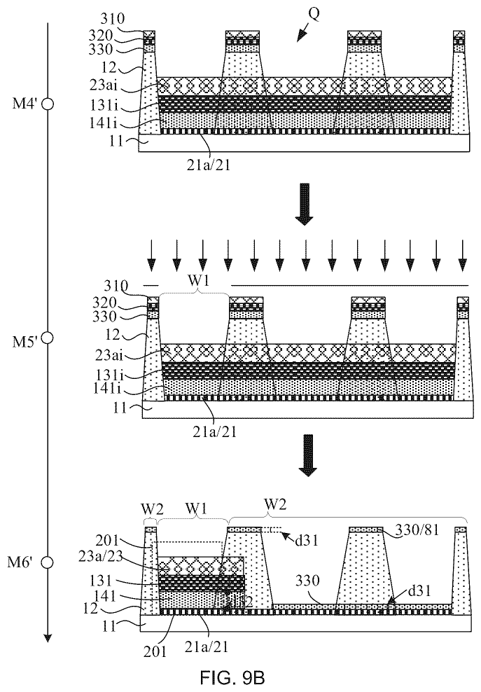

In some other embodiments, forming at least one first light-emitting device 201 includes, as shown in FIGS. 9A to 9B, M1′ to M6′.

In M1′, a first electrode layer 21a is formed on the substrate 11; and the first electrode layer 21a includes a first electrode 21 of at least one first light-emitting device 201.

For example, a process of forming the first electrode layer 21a is magnetron sputtering.

For example, the first electrodes 21 and openings Q in the pixel defining layer 12 are in one-to-one correspondence.

In M2′, a first initial carrier injection layer 141i is formed on a side of the first electrode layer 21a away from the substrate 11; and a material of the first initial carrier injection layer 141i includes a first carrier injection material, or includes a first carrier injection material and a third photosensitive material.

It can be understood that as shown in FIG. 9A, the first initial carrier injection layer 141i is also formed on the surface of the pixel defining layer.

For example, a process for forming the first initial carrier injection layer 141i is any of spin coating, screen printing, scraping coating and drip coating, and a process solution is a third solution. As for an introduction to the third solution, reference may be made to the above contents, and details are not repeated here.

As for the introduction to the first carrier injection material and the third photosensitive material, reference may be made to the above contents and details are not repeated here.

In M3′, the first initial carrier injection layer 141i is exposed to convert a material of an exposed portion of the first initial carrier injection layer 141i into a first cross-linked carrier injection material.

For example, an exposure time of the first initial carrier injection layer 141i is 60 seconds or 5 minutes.

The first initial carrier injection layer 141i being exposed as described above means that a first region W1 where at least one first light-emitting device 201 is located is exposed, which includes: performing exposure using light of a first waveband or light of full spectrum.

As for the introduction to the first cross-linked carrier injection material, reference may be made to the above contents and details are not repeated here.

In M4′, a first initial carrier transport layer 131i and a first initial light-emitting pattern 23ai are sequentially formed on a side of the first initial carrier injection layer 141i away from the substrate. A material of the first initial carrier transport layer 131i includes a first carrier transport material, or includes a first carrier transport material and a second photosensitive material. A material of the first initial light-emitting pattern 23ai includes a first quantum dot material, or includes a first quantum dot material and a first photosensitive material.

It can be understood that as shown in FIG. 9B, the first initial carrier transport layer 131i and the first initial light-emitting pattern 23ai are also formed on a side of the pixel defining layer.

For example, a process for forming the first initial carrier transport layer 131i is any of spin coating, screen printing, scraping coating and drip coating, and a process solution is a second solution. As for an introduction to the second solution, reference may be made to the above contents, and details are not repeated here.

For example, a process for forming the first initial light-emitting pattern 23ai is any of spin coating, screen printing, scraping coating and drip coating, and a process solution is a first solution. As for an introduction to the first solution, reference may be made to the above contents, and details are not repeated here.

As for the introduction to the first carrier transport material, the second photosensitive material, the first quantum dot material and the first photosensitive material, reference may be made to the above contents and details are not repeated here.

In M5′, the first initial carrier transport layer 131i and the first initial light-emitting pattern 23ai that are stacked are exposed to convert a material of an exposed portion of the first initial carrier transport layer 131i into a first cross-linked carrier transport material, and convert a material of an exposed portion of the first initial light-emitting pattern 23ai into a first cross-linked light-emitting material.

For example, an exposure time of the first initial carrier transport layer 131i and the first initial light-emitting pattern 23ai is 5 seconds or 3 seconds.

The first initial carrier transport layer 131i and the first initial light-emitting pattern 23ai that are stacked being exposed as described above means that a first region W1 where at least one first light-emitting device 201 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the first cross-linked carrier transport material and the first cross-linked light-emitting material, reference may be made to the above contents and details are not repeated here.

In M6′, the first initial carrier injection layer 141i, the first initial carrier transport layer 131i and the first initial light-emitting pattern 23ai that are stacked are developed to form the first carrier injection layer 141, the first carrier transport layer 131 and the first light-emitting pattern 23a that are stacked.

For example, M6′ may include three steps of development, where developers in the three steps of development are a first solvent, a second solvent and a third solvent, and an order of the three steps of development is, for example, the first solvent, the second solvent and the third solvent. As for the introduction to the first solvent, the second solvent and the third solvent, reference may be made to the above contents and details are not repeated here.

Through the above development process, portions of the first initial carrier injection layer 141i, the first initial carrier transport layer 131i and the first initial light-emitting pattern 23ai located in a second region W2 may be removed. The second region W2 is a remaining region, except a region where at least one first light-emitting device 201 is located, in a region where the plurality of light-emitting devices 20 are located.

For example, when developing is performed using the first solvent, a portion of the first quantum dot material proximate to the substrate 11, or portions of the first quantum dot material and the first photosensitive material proximate to the substrate 11 may have a residue, and a first temporary residual layer may be residual in the second region W2. When developing is performed using the second solvent, a portion of the first carrier transport material proximate to the substrate 11, or portions of the first carrier transport material and the second photosensitive material proximate to the substrate 11 may have a residue, and a second temporary residual layer may be residual in the second region W2; moreover, the first temporary residual layer residual in the second region W2 may be removed, thereby effectively preventing the first quantum dot material from remaining in the second region W2. When developing is performed using the third solvent, a portion of the first carrier injection material proximate to the substrate 11, or portions of the first carrier injection material and the third photosensitive material proximate to the substrate 11 may have a residue, and a first initial residual pattern 330 may be residual in the second region W2; moreover, the second temporary residual layer residual in the second region W2 may be removed, thereby effectively improving a removal rate of the first quantum dot material and reducing a residual probability of the first quantum dot material. As for the introduction to the first temporary residual layer, the second temporary residual layer and the first initial residual pattern 330, reference may be made to the above contents and details are not repeated here.

For example, development using the first solvent may be performed between M4′ and M5′, that is, development may be performed before the first initial carrier transport layer 131i and the first initial light-emitting pattern 23ai that are stacked are exposed.

In the above method for forming the at least one first light-emitting device 201, the first initial carrier injection layer 141i and a whole of the first initial carrier transport layer 131i and the first initial light-emitting pattern 23ai are exposed separately. In this way, the exposure time of the first initial carrier injection layer 141i may be increased to improve an exposure sufficiency of the first initial carrier injection layer 141i, so that the material for forming the first initial carrier injection layer 141i may be fully cross-linked under light radiation to form the first cross-linked carrier injection material, thereby improving the carrier injection effect of the first light-emitting device 201.

The above is an exemplary introduction to methods for forming at least one first light-emitting device 201. It will be noted that the method for forming at least one first light-emitting device 201 may be selected from any of the above exemplary methods for forming at least one first light-emitting device 201. The following is an exemplary introduction to forming at least one second light-emitting device 202.

In some embodiments, forming at least one second light-emitting device 202 includes, as shown in FIGS. 5, N1 to N3.

In N1, a second initial carrier transport layer 132i and a second initial light-emitting pattern 23bi are sequentially formed on a side of the first electrode layer 21a and the at least one first light-emitting device 201 away from the substrate 11. A material of the second initial carrier transport layer 132i includes a second carrier transport material, or includes a second carrier transport material and a fifth photosensitive material. A material of the second initial light-emitting pattern 23bi includes a second quantum dot material, or includes a second quantum dot material and a fourth photosensitive material.

For example, a process for forming the second initial carrier transport layer 132i is any of spin coating, screen printing, scraping coating and drip coating, and a process solution is a fifth solution. As for the introduction to the fifth solution, reference may be made to the above contents and details are not repeated here.

For example, a process for forming the second initial light-emitting pattern 23bi is any of spin coating, screen printing, scraping coating and drip coating, and a process solution is a fourth solution. As for the introduction to the fourth solution, reference may be made to the above contents and details are not repeated here.

As for the introduction to the second carrier transport material, the fifth photosensitive material, the second quantum dot material and the fourth photosensitive material, reference may be made to the above contents and details are not repeated here.

For example, as shown in FIG. 5, in a case where the first initial residual pattern 330 is residual on a side of the first electrode layer 21a away from the substrate 11, the second initial carrier transport layer 132i located on a side of the first electrode layer 21a is formed on a surface of the first initial residual pattern 330.

For example, as shown in FIG. 5, in a case where the first initial residual pattern 330 is residual on a side of the pixel defining layer 12 away from the substrate 11, the second initial carrier transport layer 132i located on a side of the pixel defining layer 12 is formed on a surface of the first initial residual pattern 330.

In N2, the second initial carrier transport layer 132i and the second initial light-emitting pattern 23bi that are stacked are exposed to convert a material of an exposed portion of the second initial carrier transport layer 132i into the second cross-linked carrier transport material, and convert a material of an exposed portion of the second initial light-emitting pattern 23bi into the second cross-linked light-emitting material.

The second initial carrier transport layer 132i and the second initial light-emitting pattern 23bi that are stacked being exposed as described above means that a third region W3 where at least one second light-emitting device 202 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the second cross-linked carrier transport material and the second cross-linked light-emitting material, reference may be made to the above contents and details are not repeated here.

In N3, the second initial carrier transport layer 132i and the second initial light-emitting pattern 23bi that are stacked are developed to form the second carrier transport layer 132 and the second light-emitting pattern 23b that are stacked.

For example, N3 may include two steps of development, where developers in the two steps of development are a fourth solvent and a fifth solvent, and an order of the two steps of development is, for example, the fourth solvent and the fifth solvent. As for the introduction to the fourth solvent and the fifth solvent, reference may be made to the above contents and details are not repeated here.

Through the above development process, portions of the second initial carrier transport layer 132i and the second initial light-emitting pattern 23bi located in a fourth region W4 may be removed. The fourth region W4 is a remaining region, except a region where at least one second light-emitting device 202 is located, in a region where the plurality of light-emitting devices 20 are located.

For example, when developing is performed using the fourth solvent, a portion of the second quantum dot material proximate to the substrate 11, or portions of the second quantum dot material and the fourth photosensitive material proximate to the substrate 11 may have a residue, and a fourth temporary residual layer may be residual in the fourth region W4. When developing is performed using the fifth solvent, a portion of the second carrier transport material proximate to the substrate 11, or portions of the second carrier transport material and the fifth photosensitive material proximate to the substrate 11 may have a residue, and a second initial residual pattern 350a may be residual in the fourth region W4; moreover, the fourth temporary residual layer residual in the fourth region W4 may be removed, thereby effectively preventing the second quantum dot material from remaining in the fourth region W4. As for the introduction to the fourth temporary residual layer and the second initial residual pattern 350a, reference may be made to the above contents and details are not repeated here.

In the above method for forming the at least one second light-emitting device 202, the second initial carrier transport layer 132i and the second initial light-emitting pattern 23bi are exposed at one time, and thus the process of the at least one second light-emitting device 202 may be simplified.

In some other embodiments, forming at least one second light-emitting device 202 includes, as shown in FIG. 6, N1′ to N3′.

In N1′, a second initial carrier injection layer 142i, a second initial carrier transport layer 132i and a second initial light-emitting pattern 23bi are sequentially formed on a side of the first electrode layer 21a and the at least one first light-emitting device 201 away from the substrate 11. A material of the second initial carrier injection layer 142i includes a second carrier injection material, or includes a second carrier injection material and a sixth photosensitive material. A material of the second initial carrier transport layer 132i includes a second carrier transport material, or includes a second carrier transport material and a fifth photosensitive material. A material of the second initial light-emitting pattern 23bi includes a second quantum dot material, or includes a second quantum dot material and a fourth photosensitive material.

As for an exemplary introduction to the formation of the second initial carrier transport layer 132i and the second initial light-emitting pattern 23bi, reference may be made to the relevant contents of the aforementioned part N1, and details are not repeated here.

For example, a process for forming the second initial carrier injection layer 142i is any of spin coating, screen printing, scraping coating and drip coating, and a process solution is a sixth solution. As for an introduction to the sixth solution, reference may be made to the above contents, and details are not repeated here.

As for the introduction to the second carrier injection material, the sixth photosensitive material, the second carrier transport material, the fifth photosensitive material, the second quantum dot material and the fourth photosensitive material, reference may be made to the above contents, and details are not repeated here.

For example, as shown in FIG. 6, in a case where the first initial residual pattern 330 is residual on a side of the first electrode layer 21a away from the substrate 11, the second initial carrier injection layer 142i located on a side of the first electrode layer 21a is formed on a surface of the first initial residual pattern 330.

For example, as shown in FIG. 6, in a case where the first initial residual pattern 330 is residual on a side of the pixel defining layer 12 away from the substrate 11, the second initial carrier injection layer 142i located on a side of the pixel defining layer 12 is formed on a surface of the first initial residual pattern 330.

In N2′, the second initial carrier injection layer 142i, the second initial carrier transport layer 132i and the second initial light-emitting pattern 23bi that are stacked are exposed to convert a material of an exposed portion of the second initial carrier injection layer 142i into the second cross-linked carrier injection material, convert a material of an exposed portion of the second initial carrier transport layer 132i into the second cross-linked carrier transport material, and convert a material of an exposed portion of the second initial light-emitting pattern 23bi into the second cross-linked light-emitting material.

The second initial carrier injection layer 142i, the second initial carrier transport layer 132i and the second initial light-emitting pattern 23bi that are stacked being exposed as described above means that a third region W3 where at least one second light-emitting device 202 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the second cross-linked carrier injection layer, the second cross-linked carrier transport material and the second cross-linked light-emitting material, reference may be made to the above contents and details are not repeated here.

In N3′, the second initial carrier injection layer 142i, the second initial carrier transport layer 132i and the second initial light-emitting pattern 23bi that are stacked are developed to form the second carrier injection layer 142, the second carrier transport layer 132 and the second light-emitting pattern 23b that are stacked.

For example, N3′ may include three steps of development, where developers in the three steps of development are a fourth solvent, a fifth solvent and a sixth solvent, and an order of the three steps of development is, for example, the fourth solvent, the fifth solvent and the sixth solvent. As for the introduction to the fourth solvent, the fifth solvent and the sixth solvent, reference may be made to the above contents and details are not repeated here.

Through the above development process, portions of the second initial carrier transport layer 142i, the second initial carrier transport layer 132i and the second initial light-emitting pattern 23bi located in a fourth region W4 may be removed. The fourth region W4 is a remaining region, except a region where at least one second light-emitting device 202 is located, in a region where the plurality of light-emitting devices 20 are located.

For example, when developing is performed using the fourth solvent, a portion of the second quantum dot material proximate to the substrate 11, or portions of the second quantum dot material and the fourth photosensitive material proximate to the substrate 11 may have a residue, and a fourth temporary residual layer may be residual in the fourth region W4. When developing is performed using the fifth solvent, a portion of the second carrier transport material proximate to the substrate 11, or portions of the second carrier transport material and the fifth photosensitive material proximate to the substrate 11 may have a residue, and a fifth temporary residual layer may be residual in the fourth region W4; moreover, the fourth temporary residual layer residual in the fourth region W4 may be removed, thereby effectively preventing the second quantum dot material from remaining in the fourth region W4. When developing is performed using the sixth solvent, a portion of the second carrier injection material proximate to the substrate 11, or portions of the second carrier injection material and the sixth photosensitive material proximate to the substrate 11 may have a residue, and a second initial residual pattern 360b may be residual in the fourth region W4; moreover, the fifth temporary residual layer residual in the fourth region W4 may be removed, thereby effectively improving a removal rate of the second quantum dot material and reducing a residual probability of the second quantum dot material. As for the introduction to the fourth temporary residual layer, the fifth temporary residual layer and the second initial residual pattern 360b, reference may be made to the above contents and details are not repeated here.

In the above method for forming the at least one second light-emitting device 202, the second initial carrier injection layer 142i, the second initial carrier transport layer 132i and the second initial light-emitting pattern 23bi are exposed at one time, and thus the process of the at least one second light-emitting device 202 may be simplified.

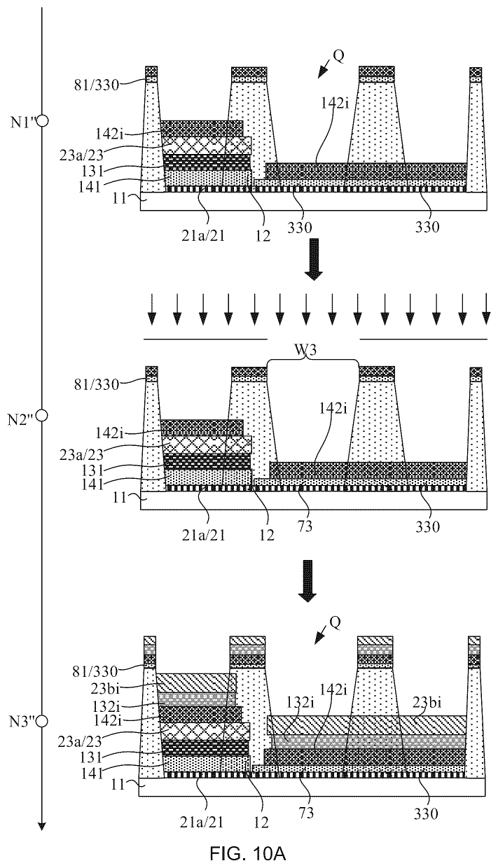

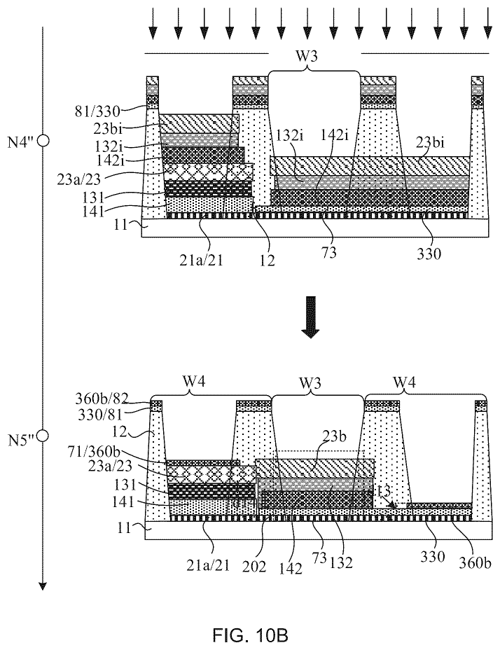

In some other embodiments, as shown in FIGS. 10A to 10B, forming at least one second light-emitting device 202 includes N1″ to N5″.

In N1″, a second initial carrier injection layer 142i is formed on a side of the first electrode layer 21a and the at least one first light-emitting device 201 away from the substrate 11. A material of the second initial carrier injection layer 142i includes a second carrier injection material, or includes a second carrier injection material and a sixth photosensitive material.

For example, a process for forming the second initial carrier injection layer 142i is any of spin coating, screen printing, scraping coating and drip coating, and a process solution is a sixth solution. As for an introduction to the sixth solution, reference may be made to the above contents, and details are not repeated here.

As for the introduction to the second carrier injection material and the sixth photosensitive material, reference may be made to the above contents, and details are not repeated here.

For example, as shown in FIG. 10A, in a case where the first initial residual pattern 330 is residual on a side of the first electrode layer 21a away from the substrate 11, the second initial carrier injection layer 142i located on a side of the first electrode layer 21a is formed on a surface of the first initial residual pattern 330.

For example, as shown in FIG. 10A, in a case where the first initial residual pattern 330 is residual on a side of the pixel defining layer 12 away from the substrate 11, the second initial carrier injection layer 142i located on a side of the pixel defining layer 12 is formed on a surface of the first initial residual pattern 330.

In N2″, the second initial carrier injection layer 142i is exposed to convert a material of an exposed portion of the second initial carrier injection layer 142i into a second cross-linked carrier injection material.

For example, an exposure time of the second initial carrier injection layer 142i is 60 seconds or 5 minutes.

The second initial carrier injection layer 142i being exposed as described above means that a third region W3 where at least one second light-emitting device 202 is located is exposed, which includes: performing exposure using light of a first waveband or light of full spectrum.

As for the introduction to the second cross-linked carrier injection material, reference may be made to the above contents and details are not repeated here.

In N3″, a second initial carrier transport layer 132i and a second initial light-emitting pattern 23bi are sequentially formed on a side of the second initial carrier injection layer 142i away from the substrate. A material of the second initial carrier transport layer 132i includes a second carrier transport material, or includes a second carrier transport material and a fifth photosensitive material. A material of the second initial light-emitting pattern 23bi includes a second quantum dot material, or includes a second quantum dot material and a fourth photosensitive material.

For example, a process for forming the second initial carrier transport layer 132i is any of spin coating, screen printing, scraping coating and drip coating, and a process solution is a fifth solution. As for the introduction to the fifth solution, reference may be made to the above contents and details are not repeated here.

For example, a process for forming the second initial light-emitting pattern 23bi is any of spin coating, screen printing, scraping coating and drip coating, and a process solution is a fourth solution. As for the introduction to the fourth solution, reference may be made to the above contents and details are not repeated here.

As for the introduction to the second carrier transport material, the fifth photosensitive material, the second quantum dot material and the fourth photosensitive material, reference may be made to the above contents and details are not repeated here.

In N4″, the second initial carrier transport layer 132i and the second initial light-emitting pattern 23bi that are stacked are exposed to convert a material of an exposed portion of the second initial carrier transport layer 132i into the second cross-linked carrier transport material, and convert a material of an exposed portion of the second initial light-emitting pattern 23bi into the second cross-linked light-emitting material.

For example, an exposure time of the second initial carrier transport layer 132i and the second initial light-emitting pattern 23bi is 5 seconds or 3 seconds.

The second initial carrier transport layer 132i and the second initial light-emitting pattern 23bi that are stacked being exposed as described above means that a third region W3 where at least one second light-emitting device 202 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the second cross-linked carrier transport material and the second cross-linked light-emitting material, reference may be made to the above contents and details are not repeated here.

In N5″, the second initial carrier injection layer 142i, the second initial carrier transport layer 132i and the second initial light-emitting pattern 23bi that are stacked are developed to form the second carrier injection layer 142, the second carrier transport layer 132 and the second light-emitting pattern 23b that are stacked.

For example, N5″ may include three steps of development, where developers in the three steps of development are a fourth solvent, a fifth solvent and a sixth solvent, and an order of the three steps of development is, for example, the fourth solvent, the fifth solvent and the sixth solvent. As for the introduction to the fourth solvent, the fifth solvent and the sixth solvent, reference may be made to the above contents and details are not repeated here.

Through the above development process, portions of the second initial carrier transport layer 142i, the second initial carrier transport layer 132i and the second initial light-emitting pattern 23bi located in a fourth region W4 may be removed. The fourth region W4 is a remaining region, except a region where at least one second light-emitting device 202 is located, in a region where the plurality of light-emitting devices 20 are located.

For example, when developing is performed using the fourth solvent, a portion of the second quantum dot material proximate to the substrate 11, or portions of the second quantum dot material and the fourth photosensitive material proximate to the substrate 11 may have a residue, and a fourth temporary residual layer may be residual in the fourth region W4. When developing is performed using the fifth solvent, a portion of the second carrier transport material proximate to the substrate 11, or portions of the second carrier transport material and the fifth photosensitive material proximate to the substrate 11 may have a residue, and a fifth temporary residual layer may be residual in the fourth region W4; moreover, the fourth temporary residual layer residual in the fourth region W4 may be removed, thereby effectively preventing the second quantum dot material from remaining in the fourth region W4. When developing is performed using the sixth solvent, a portion of the second carrier injection material proximate to the substrate 11, or portions of the second carrier injection material and the sixth photosensitive material proximate to the substrate 11 may have a residue, and a second initial residual pattern 360b may be residual in the fourth region W4; moreover, the fifth temporary residual layer residual in the fourth region W4 may be removed, thereby effectively improving a removal rate of the second quantum dot material and reducing a residual probability of the second quantum dot material. As for the introduction to the fourth temporary residual layer, the fifth temporary residual layer and the second initial residual pattern 360b, reference may be made to the above contents and details are not repeated here.

For example, development using the fourth solvent may be performed between N3″ and N4″, that is, development may be performed before the second initial carrier transport layer 132i and the second initial light-emitting pattern 23bi that are stacked are exposed.

In the above method for forming the at least one second light-emitting device 202, the second initial carrier injection layer 142i and a whole of the second initial carrier transport layer 132i and the second initial light-emitting pattern 23bi are exposed separately. In this way, the exposure time of the second initial carrier injection layer 142i to improve an exposure sufficiency of the second initial carrier injection layer 142i, so that the material for forming the second initial carrier injection layer 142i may be fully cross-linked under light radiation to form the second cross-linked carrier injection material, thereby improving the carrier injection effect of the second light-emitting device 202.

The above is an exemplary introduction to methods for forming at least one second light-emitting device 202. It will be noted that the method for forming at least one second light-emitting device 202 may be selected from any of the above exemplary methods for forming at least one second light-emitting device 202. In addition, the method for forming at least one second light-emitting device 202 and the method for forming at least one first light-emitting device 201 are the same (or similar) or different, and are independently selected.

The following is an exemplary introduction to forming at least one third light-emitting device 203.

In some embodiments, forming at least one third light-emitting device 203 includes, as shown in FIGS. 7, H1 to H3.

In H1, a third initial carrier transport layer 133i and a third initial light-emitting pattern 23ci are sequentially formed on a side of the first electrode layer 21a, the at least one first light-emitting device 201 and the at least one second light-emitting device 202 away from the substrate 11. A material of the third initial carrier transport layer 133i includes a third carrier transport material, or includes a third carrier transport material and an eighth photosensitive material. A material of the third initial light-emitting pattern 23ci includes a third quantum dot material, or includes a third quantum dot material and a seventh photosensitive material.

For example, a process for forming the third initial carrier transport layer 133i is any of spin coating, screen printing, scraping coating and drip coating, and a process solution is an eighth solution. As for the introduction to the eighth solution, reference may be made to the above contents and details are not repeated here.

For example, a process for forming the third initial light-emitting pattern 23ci is any of spin coating, screen printing, scraping coating and drip coating, and a process solution is a seventh solution. As for the introduction to the seventh solution, reference may be made to the above contents and details are not repeated here.

As for the introduction to the third carrier transport material, the eighth photosensitive material, the third quantum dot material and the seventh photosensitive material, reference may be made to the above contents and details are not repeated here.

For example, as shown in FIG. 7, in a case where the second initial residual pattern 350a is residual on a side of the first electrode layer 21a and the at least one first light-emitting device 201 away from the substrate 11, the third initial carrier transport layer 133i located on a side of the first electrode layer 21a and the at least one first light-emitting device 201 is formed on a surface of the second initial residual pattern 350a.

For example, as shown in FIG. 7, in a case where the second initial residual pattern 350a is residual on a side of the pixel defining layer 12 away from the substrate 11, the third initial carrier transport layer 133i located on a side of the pixel defining layer 12 is formed on a surface of the second initial residual pattern 350a.

In H2, the third initial carrier transport layer 133i and the third initial light-emitting pattern 23ci that are stacked are exposed to convert a material of an exposed portion of the third initial carrier transport layer 133i into the third cross-linked carrier transport material, and convert a material of an exposed portion of the third initial light-emitting pattern 23ci into the third cross-linked light-emitting material.

The third initial carrier transport layer 133i and the third initial light-emitting pattern 23ci that are stacked being exposed as described above means that a fifth region W5 where at least one third light-emitting device 203 is located is exposed, which includes: performing exposure using light of a first waveband or light of full spectrum;

alternatively, performing exposure using light of a second waveband, and then performing exposure using light of the first waveband; alternatively, performing exposure using light of the first waveband, and then performing exposure using light of the second waveband.

As for the introduction to the third cross-linked carrier transport material and the third cross-linked light-emitting material, reference may be made to the above contents and details are not repeated here.

In H3, the third initial carrier transport layer 133i and the third initial light-emitting pattern 23ci that are stacked are developed to form the third carrier transport layer 133 and the third light-emitting pattern 23b that are stacked.

For example, H3 may include two steps of development, where developers in the two steps of development are a seventh solvent and an eighth solvent, and an order of the two steps of development is, for example, the seventh solvent and the eighth solvent. As for the introduction to the seventh solvent and the eighth solvent, reference may be made to the above contents and details are not repeated here.

Through the above development process, portions of the third initial carrier transport layer 133i and the third initial light-emitting pattern 23ci located in a sixth region W6 may be removed. The sixth region W6 is a remaining region, except a region where at least one third light-emitting device 203 is located, in a region where the plurality of light-emitting devices 20 are located.

For example, when developing is performed using the seventh solvent, a portion of the third quantum dot material proximate to the substrate 11, or portions of the third quantum dot material and the seventh photosensitive material proximate to the substrate 11 may have a residue, and a seventh temporary residual layer may be residual in the sixth region W6. When developing is performed using the eighth solvent, a portion of the third carrier transport material proximate to the substrate 11, or portions of the third carrier transport material and the eighth photosensitive material proximate to the substrate 11 may have a residue, and a third initial residual pattern 380a may be residual in the sixth region W6; moreover, the seventh temporary residual layer residual in the sixth region W6 may be removed, thereby effectively preventing the third quantum dot material from remaining in the sixth region W6. As for the introduction to the seventh temporary residual layer and the third initial residual pattern 380a, reference may be made to the above contents and details are not repeated here.

In the above method for forming the at least one third light-emitting device 203, the third initial carrier transport layer 133i and the third initial light-emitting pattern 23ci are exposed at one time, and thus the process of the at least one third light-emitting device 203 may be simplified.

In some other embodiments, forming at least one third light-emitting device 203 includes, as shown in FIG. 8, H1′ to H3′.

In H1′, a third initial carrier injection layer 143i, a third initial carrier transport layer 133i and a third initial light-emitting pattern 23ci are sequentially formed on a side of the first electrode layer 21a, the at least one first light-emitting device 201 and the at least one second light-emitting device 202 away from the substrate 11. A material of the third initial carrier injection layer 143i includes a third carrier injection material, or includes a third carrier injection material and a ninth photosensitive material. A material of the third initial carrier transport layer 133i includes a third carrier transport material, or includes a third carrier transport material and an eighth photosensitive material. A material of the third initial light-emitting pattern 23ci includes a third quantum dot material, or includes a third quantum dot material and a seventh photosensitive material.

As for an exemplary introduction to the formation of the third initial carrier transport layer 133i and the third initial light-emitting pattern 23ci, reference may be made to the relevant contents of the aforementioned part H1, and details are not repeated here.

For example, a process for forming the third initial carrier injection layer 143i is any of spin coating, screen printing, scraping coating and drip coating, and a process solution is a ninth solution. As for the introduction to the ninth solvent, reference may be made to the above contents and details are not repeated here.

As for the introduction to the third carrier injection material, the ninth photosensitive material, the third carrier transport material, the eighth photosensitive material, the third quantum dot material and the seventh photosensitive material, reference may be made to the above contents and details are not repeated here.

For example, as shown in FIG. 8, in a case where the second initial residual pattern 360b is residual on a side of the first electrode layer 21a and the at least one first light-emitting device 201 away from the substrate 11, the third initial carrier injection layer 143i located on a side of the first electrode layer 21a and the at least one first light-emitting device 201 is formed on a surface of the second initial residual pattern 360b.

For example, as shown in FIG. 8, in a case where the second initial residual pattern 360b is residual on a side of the pixel defining layer 12 away from the substrate 11, the third initial carrier injection layer 143i located on a side of the pixel defining layer 12 is formed on a surface of the second initial residual pattern 360b.

In H2′, the third initial carrier injection layer 143i, the third initial carrier transport layer 133i and the third initial light-emitting pattern 23ci that are stacked are exposed to convert a material of an exposed portion of the third initial carrier injection layer 143i into the third cross-linked carrier injection material, convert a material of an exposed portion of the third initial carrier transport layer 133i into the third cross-linked carrier transport material, and convert a material of an exposed portion of the third initial light-emitting pattern 23ci into the third cross-linked light-emitting material.

The third initial carrier injection layer 143i, the third initial carrier transport layer 133i and the third initial light-emitting pattern 23ci that are stacked being exposed as described above means that a fifth region W5 where at least one third light-emitting device 203 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the third cross-linked carrier injection material, the third cross-linked carrier transport material and the third cross-linked light-emitting material, reference may be made to the above contents and details are not repeated here.

In H3′, the third initial carrier injection layer 143i, the third initial carrier transport layer 133i and the third initial light-emitting pattern 23ci that are stacked are developed to form the third carrier injection layer 143, the third carrier transport layer 133 and the third light-emitting pattern 23c that are stacked.

For example, H3′ may include three steps of development, where developers in the three steps of development are a seventh solvent, an eighth solvent and a ninth solvent, and an order of the three steps of development is, for example, the seventh solvent, the eighth solvent and the ninth solvent. As for the introduction to the seventh solvent, the eighth solvent and the ninth solvent, reference may be made to the above contents and details are not repeated here.

Through the above development process, portions of the third initial carrier injection layer 143i, the third initial carrier transport layer 133i and the third initial light-emitting pattern 23ci located in a sixth region W6 may be removed. The sixth region W6 is a remaining region, except a region where at least one third light-emitting device 203 is located, in a region where the plurality of light-emitting devices 20 are located.

For example, when developing is performed using the seventh solvent, a portion of the third quantum dot material proximate to the substrate 11, or portions of the third quantum dot material and the seventh photosensitive material proximate to the substrate 11 may have a residue, and a seventh temporary residual layer may be residual in the sixth region W6. When developing is performed using the eighth solvent, a portion of the third carrier transport material proximate to the substrate 11, or portions of the third carrier transport material and the eighth photosensitive material proximate to the substrate 11 may have a residue, and an eighth temporary residual layer may be residual in the sixth region W6; moreover, the seventh temporary residual layer residual in the sixth region W6 may be removed, thereby effectively preventing the third quantum dot material from remaining in the sixth region W6. When developing is performed using the ninth solvent, a portion of the third carrier injection material proximate to the substrate 11, or portions of the third carrier injection material and the ninth photosensitive material proximate to the substrate 11 may have a residue, and a third initial residual pattern 390b may be residual in the sixth region W6; moreover, the eighth temporary residual layer residual in the sixth region W6 may be removed, thereby effectively improving a removal rate of the third quantum dot material and reducing a residual probability of the third quantum dot material. As for the introduction to the seventh temporary residual layer, the eighth temporary residual layer and the third initial residual pattern 390a, reference may be made to the above contents and details are not repeated here.

In the above method for forming the at least one third light-emitting device 203, the third initial carrier injection layer 143i, the third initial carrier transport layer 133i and the third initial light-emitting pattern 23ci are exposed at one time, and thus the process of the at least one third light-emitting device 203 may be simplified.

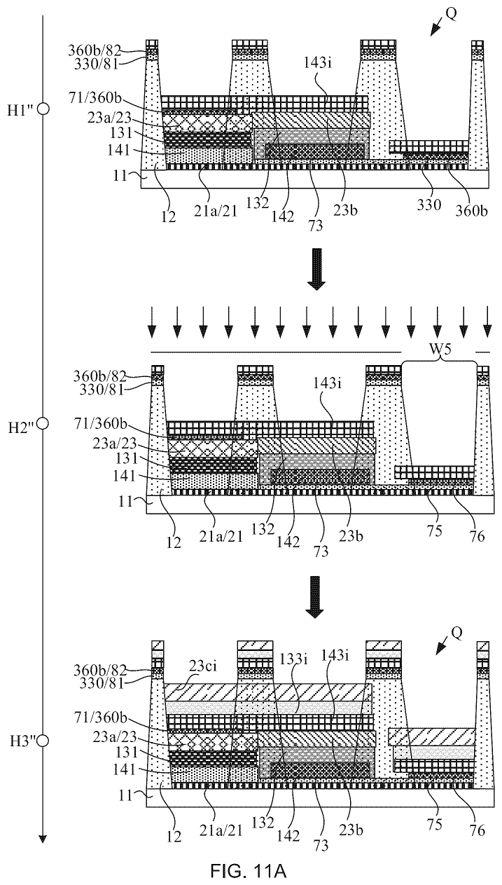

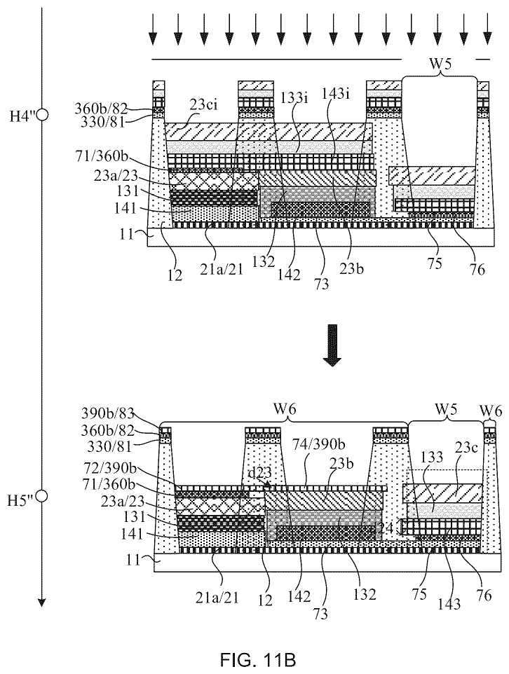

In some other embodiments, as shown in FIGS. 11A to 11B, forming at least one third light-emitting device 203 includes H1″ to H5″.

In H1″, a third initial carrier injection layer 143i is formed on a side of the first electrode layer 21a, the at least one first light-emitting device 201 and the at least one second light-emitting device 202 away from the substrate 11. A material of the third initial carrier injection layer 143i includes a third carrier injection material, or includes a third carrier injection material and a ninth photosensitive material.

For example, a process for forming the third initial carrier injection layer 143i is any of spin coating, screen printing, scraping coating and drip coating, and a process solution is a ninth solution. As for the introduction to the ninth solvent, reference may be made to the above contents and details are not repeated here.

As for the introduction to the third carrier injection material and the ninth photosensitive material, reference may be made to the above contents and details are not repeated here.

For example, as shown in FIG. 11A, in a case where the second initial residual pattern 360b is residual on a side of the first electrode layer 21a and the at least one first light-emitting device 201 away from the substrate 11, the third initial carrier injection layer 143i located on a side of the first electrode layer 21a and the at least one first light-emitting device 201 is formed on a surface of the second initial residual pattern 360b.

For example, as shown in FIG. 11A, in a case where the second initial residual pattern 360b is residual on a side of the pixel defining layer 12 away from the substrate 11, the third initial carrier injection layer 143i located on a side of the pixel defining layer 12 is formed on a surface of the second initial residual pattern 360b.

In H2″, the third initial carrier injection layer 143i is exposed to convert a material of an exposed portion of the third initial carrier injection layer 143i into a third cross-linked carrier injection material.

For example, an exposure time of the third initial carrier injection layer 143i is 60 seconds or 5 minutes.

The third initial carrier injection layer 143i being exposed as described above means that a fifth region W5 where at least one third light-emitting device 203 is located is exposed, which includes: performing exposure using light of a first waveband or light of full spectrum.

As for the introduction to the third cross-linked carrier injection material, reference may be made to the above contents and details are not repeated here.

In H3″, a third initial carrier transport layer 133i and a third initial light-emitting pattern 23ci are sequentially formed on a side of the third initial carrier injection layer 143i away from the substrate 11. A material of the third initial carrier transport layer 133i includes a third carrier transport material, or includes a third carrier transport material and an eighth photosensitive material. A material of the third initial light-emitting pattern 23ci includes a third quantum dot material, or includes a third quantum dot material and a seventh photosensitive material.

For example, a process for forming the third initial carrier transport layer 133i is any of spin coating, screen printing, scraping coating and drip coating, and a process solution is an eighth solution. As for the introduction to the eighth solution, reference may be made to the above contents and details are not repeated here.

For example, a process for forming the third initial light-emitting pattern 23ci is any of spin coating, screen printing, scraping coating and drip coating, and a process solution is a seventh solution. As for the introduction to the seventh solution, reference may be made to the above contents and details are not repeated here.

As for the introduction to the third carrier transport material, the eighth photosensitive material, the third quantum dot material and the seventh photosensitive material, reference may be made to the above contents and details are not repeated here.

In H4″, the third initial carrier transport layer 133i and the third initial light-emitting pattern 23ci that are stacked are exposed to convert a material of an exposed portion of the third initial carrier transport layer 133i into the third cross-linked carrier transport material, and convert a material of an exposed portion of the third initial light-emitting pattern 23ci into the third cross-linked light-emitting material.

For example, an exposure time of the third initial carrier transport layer 133i and the third initial light-emitting pattern 23ci is 5 seconds or 3 seconds.

The third initial carrier transport layer 133i and the third initial light-emitting pattern 23ci that are stacked being exposed as described above means that a fifth region W5 where at least one third light-emitting device 203 is located is exposed, which includes: performing exposure using light of a first waveband or light of full spectrum; alternatively, performing exposure using light of a second waveband, and then performing exposure using light of the first waveband; alternatively, performing exposure using light of the first waveband, and then performing exposure using light of the second waveband.

As for the introduction to the third cross-linked carrier transport material and the third cross-linked light-emitting material, reference may be made to the above contents and details are not repeated here.

In H5″, the third initial carrier injection layer 143i, the third initial carrier transport layer 133i and the third initial light-emitting pattern 23ci that are stacked are developed to form the third carrier injection layer 143, the third carrier transport layer 133 and the third light-emitting pattern 23c that are stacked.

For example, H5″ may include three steps of development, where developers in the three steps of development are a seventh solvent, an eighth solvent and a ninth solvent, and an order of the three steps of development is, for example, the seventh solvent, the eighth solvent and the ninth solvent. As for the introduction to the seventh solvent, the eighth solvent and the ninth solvent, reference may be made to the above contents and details are not repeated here.

Through the above development process, portions of the third initial carrier injection layer 143i, the third initial carrier transport layer 133i and the third initial light-emitting pattern 23ci located in a sixth region W6 may be removed. The sixth region W6 is a remaining region, except a region where at least one third light-emitting device 203 is located, in a region where the plurality of light-emitting devices 20 are located.

For example, when developing is performed using the seventh solvent, a portion of the third quantum dot material proximate to the substrate 11, or portions of the third quantum dot material and the seventh photosensitive material proximate to the substrate 11 may have a residue, and a seventh temporary residual layer may be residual in the sixth region W6. When developing is performed using the eighth solvent, a portion of the third carrier transport material proximate to the substrate 11, or portions of the third carrier transport material and the eighth photosensitive material proximate to the substrate 11 may have a residue, and an eighth temporary residual layer may be residual in the sixth region W6; moreover, the seventh temporary residual layer residual in the sixth region W6 may be removed, thereby effectively preventing the third quantum dot material from remaining in the sixth region W6. When developing is performed using the ninth solvent, a portion of the third carrier injection material proximate to the substrate 11, or portions of the third carrier injection material and the ninth photosensitive material proximate to the substrate 11 may have a residue, and a third initial residual pattern 390b may be residual in the sixth region W6; moreover, the eighth temporary residual layer residual in the sixth region W6 may be removed, thereby effectively improving a removal rate of the third quantum dot material and reducing a residual probability of the third quantum dot material. As for the introduction to the seventh temporary residual layer, the eighth temporary residual layer and the third initial residual pattern 390a, reference may be made to the above contents and details are not repeated here.

For example, development using the seventh solvent may be performed between H3″ and H4″, that is, development may be performed before the third initial carrier transport layer 133i and the third initial light-emitting pattern 23ci that are stacked are exposed.

In the above method for forming the at least one third light-emitting device 203, the third initial carrier injection layer 143i and a whole of the third initial carrier transport layer 133i and the third initial light-emitting pattern 23ci are exposed separately. In this way, the exposure time of the third initial carrier injection layer 143i to improve an exposure sufficiency of the third initial carrier injection layer 143i, so that the material for forming the third initial carrier injection layer 143i may be fully cross-linked under light radiation to form the third cross-linked carrier injection material, thereby improving the carrier injection effect of the third light-emitting device 203.

The above is an exemplary introduction to methods for forming at least one third light-emitting device 203. It will be noted that the method for forming at least one third light-emitting device 203 may be selected from any of the above exemplary methods for forming at least one third light-emitting device 203. In addition, the method for forming at least one third light-emitting device 203 and the method for forming at least one first light-emitting device 201 are the same (or similar) or different, and are independently selected.

In some embodiments, in the first initial light-emitting pattern 23ai, a ratio of a mass of the first photosensitive material to a mass of the first quantum dot material is in a range of 0% to 30%, inclusive.

For example, a ratio of the mass of the first photosensitive material to the mass of the first quantum dot material is any of 0%, 1%, 4%, 6%, 10%, 18% or 30%.

In some embodiments, in the second initial light-emitting pattern 23bi, a ratio of a mass of the fourth photosensitive material to a mass of the second quantum dot material is in a range of 0% to 30%, inclusive.

For example, a ratio of the mass of the fourth photosensitive material to the mass of the second quantum dot material is any of 0%, 2%, 5%, 11%, 20%, 25% or 30%.

In some embodiments, in the third initial light-emitting pattern 23ci, a ratio of a mass of the seventh photosensitive material to a mass of the third quantum dot material is in a range of 0% to 30%, inclusive.

For example, a ratio of the mass of the seventh photosensitive material to the mass of the third quantum dot material is any of 0%, 1%, 2%, 5%, 10%, 17% or 30%.

That is to say, a ratio of a mass of the first type of photosensitive material to a mass of the quantum dot material (including the first quantum dot material, the second quantum dot material and the third quantum dot material) is in a range of 0% to 30%, inclusive. It will be noted that in a case where a ratio of the mass of the first type of photosensitive material to the mass of the quantum dot material is 0%, the cross-linked light-emitting material (including the first cross-linked light-emitting material, the second cross-linked light-emitting material and the third cross-linked light-emitting material) is generated by self-crosslinking of the quantum dot material under light radiation.

By setting a ratio of the mass of the first type of photosensitive material to the mass of the quantum dot material to be in the range of 0% to 30%, inclusive, a usage mount of the first type of photosensitive material may meet requirements of cross-linking, so that the light-emitting pattern 23 maintains a high film retention rate.

In some embodiments, in the first initial carrier transport layer 131i, a ratio of a mass of the second photosensitive material to a mass of the first carrier transport material is in a range of 0% to 30%, inclusive.

For example, a ratio of the mass of the second photosensitive material to the mass of the first carrier transport material is any of 0%, 1%, 2%, 6%, 9%, 24% or 30%.

In some embodiments, in the second initial carrier transport layer 132i, a ratio of a mass of the fifth photosensitive material to a mass of the second carrier transport material is in a range of 0% to 30%, inclusive.

For example, a ratio of the mass of the fifth photosensitive material to the mass of the second carrier transport material is any of 0%, 2%, 3%, 10%, 11%, 22% or 30%.

In some embodiments, in the third initial carrier transport layer 131i, a ratio of a mass of the eighth photosensitive material to a mass of the third carrier transport material is in a range of 0% to 30%, inclusive.

For example, a ratio of the mass of the eighth photosensitive material to the mass of the third carrier transport material is any of 0%, 1%, 2%, 5%, 12%, 18% or 30%.

That is to say, a ratio of a mass of the second type of photosensitive material to a mass of the carrier transport material (any of the first carrier transport material, the second carrier transport material and the third carrier transport material) is in a range of 0% to 30%, inclusive. It will be noted that in a case where a ratio of the mass of the second type of photosensitive material to the mass of the carrier transport material is 0%, the cross-linked carrier transport material (including the first cross-linked carrier transport material, the second cross-linked carrier transport material and the third cross-linked carrier transport material) is generated by self-crosslinking of the carrier transport material under light radiation.

By setting a ratio of the mass of the second type of photosensitive material to the mass of the carrier transport material to be in the range of 0% to 30%, inclusive, a usage mount of the second type of photosensitive material may meet requirements of cross-linking, so that the carrier transport layer (any of the first carrier transport material layer 131, the second carrier transport material layer 132 and the third carrier transport material layer 133) maintains a high film retention rate.

In some embodiments, in the first initial carrier injection layer 141i, a ratio of a mass of the third photosensitive material to a mass of the first carrier injection material is in a range of 0% to 30%, inclusive.

For example, a ratio of the mass of the third photosensitive material to the mass of the first carrier injection material is any of 0%, 1%, 3%, 4%, 9%, 18% or 30%.

In some embodiments, in the second initial carrier injection layer 142i, a ratio of a mass of the sixth photosensitive material to a mass of the second carrier injection material in a range of 0% to 30%, inclusive.

For example, a ratio of the mass of the sixth photosensitive material to the mass of the second carrier injection material is any of 0%, 1%, 2.5%, 8%, 10%, 16% or 30%.

In some embodiments, in the third initial carrier injection layer 143i, a ratio of a mass of the ninth photosensitive material to a mass of the third carrier injection material in a range of 0% to 30%, inclusive.

For example, a ratio of the mass of the ninth photosensitive material to the mass of the third carrier injection material is any of 0%, 1.8%, 3%, 5%, 10%, 17% or 30%.

That is to say, a ratio of a mass of the third type of photosensitive material to a mass of the carrier injection material (any of the first carrier injection material, the second carrier injection material and the third carrier injection material) is in a range of 0% to 30%, inclusive. It will be noted that in a case where a ratio of the mass of the third type of photosensitive material to the mass of the carrier injection material is 0%, the cross-linked carrier injection material (including the first cross-linked carrier injection material, the second cross-linked carrier injection material and the third cross-linked carrier injection material) is generated by self-crosslinking of the carrier injection material under light radiation.

By setting a ratio of the mass of the third type of photosensitive material to the mass of the carrier injection material to be in the range of 0% to 30%, inclusive, a usage mount of the third type of photosensitive material may meet requirements of cross-linking, so that the carrier injection layer (any of the first carrier injection material layer 141, the second carrier injection material layer 142 and the third carrier injection material layer 143) maintains a high film retention rate.

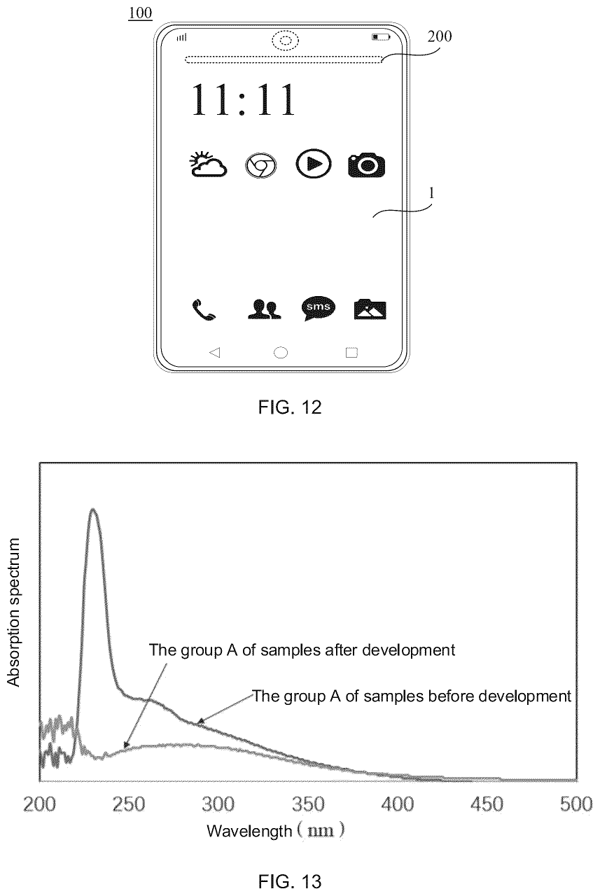

Some embodiments of the present disclosure further provide a light-emitting apparatus 100. As shown in FIG. 12, the light-emitting apparatus 100 includes the light-emitting substrate 1 as described in any of the above embodiments.

Of course, the light-emitting apparatus 100 may further include other components, for example, a driver chip 200 for providing an electrical signal to the light-emitting substrate 1 to drive the light-emitting substrate 1 to emit light. The light-emitting apparatus 100 may further include a circuit board electrically connected to the light-emitting substrate 1. The circuit board is, for example, a flexible printed circuit (FPC) for electrically connecting the driver chip and the light-emitting substrate, so as to realize electrical signal transmission.

In some embodiments, the light-emitting apparatus 100 may be an illumination apparatus. In this case, the light-emitting apparatus 100 is used as a light source to achieve an illumination function. For example, the light-emitting apparatus 100 is a backlight module in a liquid crystal display apparatus, a lamp for internal or external illumination, or any of various signal lamps.

In some other embodiments, the light-emitting apparatus 100 may be a display apparatus. In this case, the light-emitting substrate 1 is a display substrate for realizing a function of displaying an image (i.e., a picture). The light-emitting apparatus 100 may include a display or a product including the display. The display may be a flat panel display (FPD), a micro display, or the like. According to whether a user can see a scene behind the display, the display may be a transparent display or an opaque display. According to whether the display can be bent or curled, the display may be a flexible display or a common display (which may be referred to as a rigid display). For example, the product including the display may include a computer display, a television, a billboard, a laser printer with a display function, a telephone, a mobile phone, a personal digital assistant (PDA), a laptop computer, a digital camera, a portable camcorder, a viewfinder, a vehicle, a large-area wall, a screen in a theater or a sign in a stadium. FIG. 12 illustrates an example where the light-emitting apparatus 100 is a mobile phone.

Based on the above specific implementations, in order to objectively evaluate technical effects of technical solutions provided in the present disclosure, the technical effects and feasibility of the technical solutions provided in the present disclosure will be verified through validation experiments below.

### Experiment Example 1

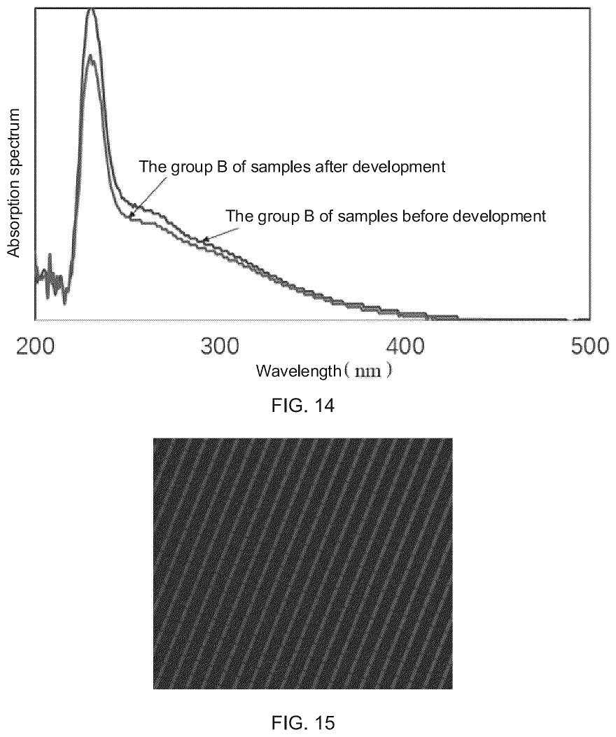

Two groups of 4 cm×4 cm glass sheets are spin-coated with an aqueous solution of a mixture of poly(3,4-ethylenedioxythiophene):poly(styrene sulfonate) (PEDOT:PSS, 20 mg/mL) and Fast Blue B Salt (FBBS, 1 mg/mL) at a speed of 2000 rpm, and each glass sheet is spin-coated with the solution with an amount of 100 μL to obtain a group A of samples and a group B of samples. Next, the group A of samples are placed in a dark (i.e., unexposed) condition for 60 seconds, and the group B of samples are exposed to light of full spectrum for 60 seconds using an ultraviolet lithography machine. Some of the group A of samples are taken to measure the UV absorption spectrum, and the results are shown in FIG. 13; and some of the group B of samples are taken to measure the UV absorption spectrum, and the results are shown in FIG. 14. Then, the group A of samples and the group B of samples are developed with water as a developer. After development, the UV absorption spectrum of the group A of samples is measured, and the results are shown in FIG. 13; and the UV absorption spectrum of the group B of samples is measured, and the results are shown in FIG. 14.

It can be seen according to FIG. 13 that after development, PEDOT:PSS in the group A of samples is almost completely washed away by water. It can be seen according to FIG. 14 that after development, a retention rate of PEDOT:PSS in the group B of samples is very high, up to 86%. This is because the group A of samples are not exposed, while the group B of samples are exposed to light of full spectrum for 60 seconds and are fully exposed.

It can be seen that by exposure, FBBS and PEDOT:PSS may be fully photo-cross-linked under light radiation to generate a cross-linked carrier injection material, and the cross-linked carrier injection material may be well retained after development.

### Experiment Example 2

Forming a plurality of first light-emitting devices includes R1 to R8.

In R1, a patterned first electrode layer is formed on a glass substrate base; and a material of the first electrode layer is indium tin oxide (ITO).

In R2, a third solution is applied by spin-coating on a side of the first electrode layer away from the glass substrate base to form a first initial carrier injection layer. A spin-coating speed is 2000 rpm and a spin-coating time is 30 seconds. A solvent of the third solution is water, and solutes of the third solution are the first carrier injection material PEDOT:PSS and the third photosensitive material FBBS, where a concentration of PEDOT:PSS in the third solution is 20 mg/mL, and a concentration of FBBS in the third solution is 1 mg/mL.

In R3, UV alignment exposure is performed on the first initial carrier injection layer for 60 seconds using a photomask, so that a material of an exposed portion of the first initial carrier injection layer is converted into a first cross-linked carrier injection material.

In R4, a second solution is applied by spin-coating on a side of the first initial carrier injection layer away from the glass substrate base to form a first initial carrier transport layer. A spin-coating speed is 2000 rpm and a spin-coating time is 30 seconds. A solvent of the second solution is chlorobenzene, and solutes of the second solution are the first carrier transport material TFB and the second photosensitive material ethyl-1,2-bis(4-azido-2,3,5,6-tetrafluorobenzoate), where a concentration of the first carrier transport material in the second solution is 8 mg/mL, and a concentration of the second photosensitive material in the second solution is 0.2 mg/mL.

In R5, a first solution is applied by spin-coating on a side of the first initial carrier transport layer away from the glass substrate base to form a first initial light-emitting pattern. A spin-coating speed is 2000 rpm and a spin-coating time is 30 seconds. A first solvent is octane, and solutes of the first solution are the first quantum dot material and the first photosensitive material 3,3′-[4,4′(perfluorobutane-1,4-diyl)bis(4,1-phenylene)]bis[3-(trifluoromethyl)-3H-diazirine], where a concentration of the first quantum dot material in the first solution is 20 mg/mL, and a concentration of the first photosensitive material in the first solution is 1 mg/mL. The quantum dot body of the first quantum dot material is a red quantum dot body CdSe@ZnS, and the first ligand material of the first quantum dot material is oleic acid.

In R6, UV alignment exposure is performed on the first initial carrier transport layer and the first initial light-emitting pattern that are stacked for 5 seconds using a photomask, so that a material of an exposed portion of the first initial carrier transport layer is converted into a first cross-linked carrier transport material, and a material of an exposed portion of the first initial light-emitting pattern is converted into a first cross-linked light-emitting material.

In R7, the first initial carrier injection layer, the first initial carrier transport layer and the first initial light-emitting pattern that are stacked are developed to form a first carrier injection layer, a first carrier transport layer and a first light-emitting pattern that are stacked. Development is performed in two steps, where a developer in the first step of development is toluene, and a developer in the second step of development is water.

In R8, a second electrode is formed by evaporation on a side of the first light-emitting pattern away from the glass substrate base; and the second electrode is an aluminium electrode.

The plurality of first light-emitting devices 201 formed in this Experimental Example are observed using a fluorescence microscope, and the results are shown in FIG. 15. It can be seen from FIG. 15 that, the red quantum dot material has no residue in a region other than a region where the plurality of first light-emitting devices 201 are located, that is, the red quantum dot material has no residue in the unexposed region.

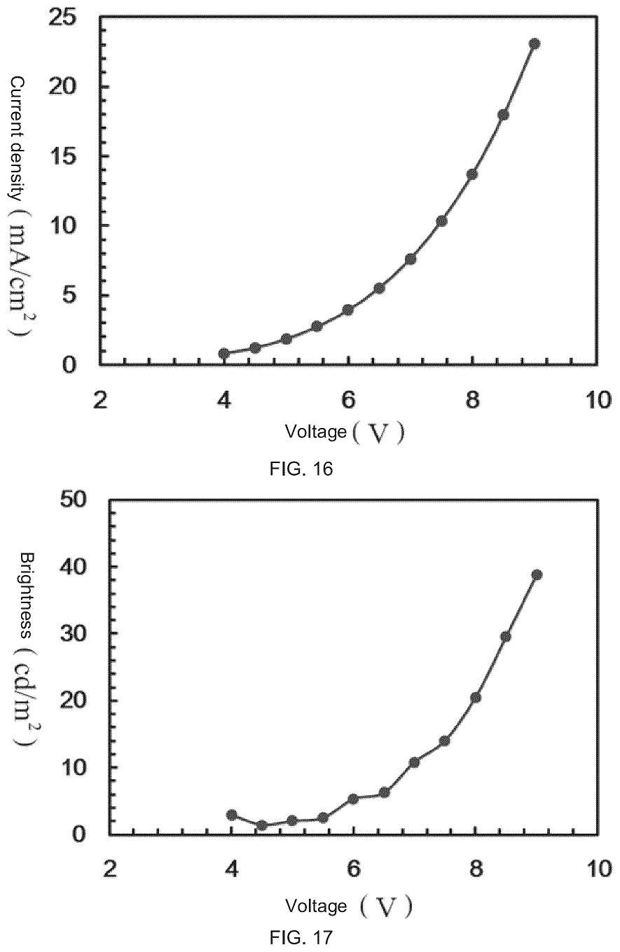

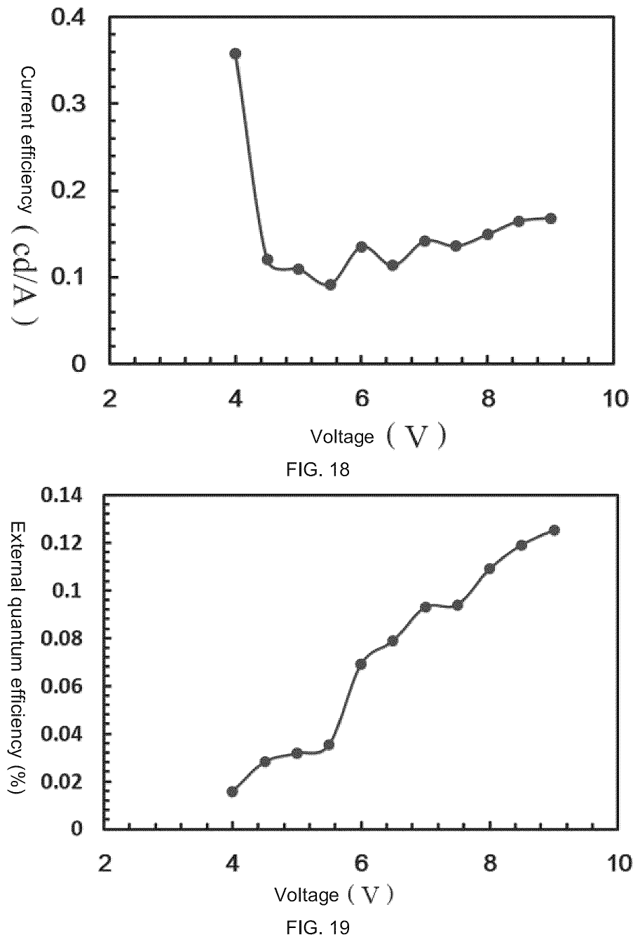

This Experimental Example also tests the device performance of the plurality of first light-emitting devices 201, and the results are shown in FIGS. 16 to 19.

### Experiment Example 3

Forming a plurality of first light-emitting devices includes R1′ to R8′.

In R1′, a patterned first electrode layer is formed on a glass substrate base; and a material of the first electrode layer is indium tin oxide (ITO).

In R2′, a third solution is applied by spin-coating on a side of the first electrode layer away from the glass substrate base to form a first initial carrier injection layer. A spin-coating speed is 2000 rpm and a spin-coating time is 30 seconds. A solvent of the third solution is water, and solutes of the third solution are the first carrier injection material PEDOT:PSS and the third photosensitive material FBBS, where a concentration of PEDOT:PSS in the third solution is 20 mg/mL, and a concentration of FBBS in the third solution is 1 mg/mL.

In R3′, UV alignment exposure is performed on the first initial carrier injection layer for 10 seconds using a photomask, so that a material of an exposed portion of the first initial carrier injection layer is converted into a first cross-linked carrier injection material.

In R4′, a second solution is applied by spin-coating on a side of the first initial carrier injection layer away from the glass substrate base to form a first initial carrier transport layer. A spin-coating speed is 2000 rpm and a spin-coating time is 30 seconds. A solvent of the second solution is chlorobenzene, and solutes of the second solution are the first carrier transport material TFB and the second photosensitive material ethyl-1,2-bis(4-azido-2,3,5,6-tetrafluorobenzoate), where a concentration of the first carrier transport material in the second solution is 8 mg/mL, and a concentration of the second photosensitive material in the second solution is 0.2 mg/mL.

In R5′, a first solution is applied by spin-coating on a side of the first initial carrier transport layer away from the glass substrate base to form a first initial light-emitting pattern. A spin-coating speed is 2000 rpm and a spin-coating time is 30 seconds. A first solvent is octane, and solutes of the first solution are the first quantum dot material and the first photosensitive material 3,3′-[4,4′(perfluorobutane-1,4-diyl)bis(4,1-phenylene)]bis[3-(trifluoromethyl)-3H-diazirine], where a concentration of the first quantum dot material in the first solution is 20 mg/mL, and a concentration of the first photosensitive material in the first solution is 1 mg/mL. The quantum dot body of the first quantum dot material is a red quantum dot body CdSe@ZnS, and the first ligand material of the first quantum dot material is oleic acid.

In R6′, UV alignment exposure is performed on the first initial carrier transport layer and the first initial light-emitting pattern that are stacked for 5 seconds using a photomask, so that a material of an exposed portion of the first initial carrier transport layer is converted into a first cross-linked carrier transport material, and a material of an exposed portion of the first initial light-emitting pattern is converted into a first cross-linked light-emitting material.

In R7′, the first initial carrier injection layer, the first initial carrier transport layer and the first initial light-emitting pattern that are stacked are developed to form a first carrier injection layer, a first carrier transport layer and a first light-emitting pattern that are stacked. Development is performed in two steps, where a developer in the first step of development is toluene, and a developer in the second step of development is water.

In R8′, a second electrode is formed by evaporation on a side of the first light-emitting pattern away from the glass substrate base; and the second electrode is a silver electrode.

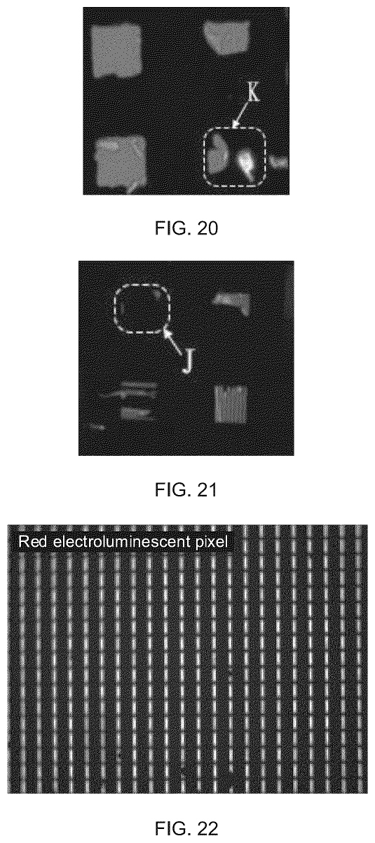

The plurality of first light-emitting devices formed in this Experimental Example are observed using a fluorescence microscope, and the results are shown in FIG. 20. It can be seen from FIG. 20 that first light-emitting patterns of some first light-emitting devices are incomplete, such as the first light-emitting pattern shown in the lower right corner of FIG. 20 (i.e., a region K in FIG. 20). This is because after the exposure time of the first initial carrier injection layer is shortened to 10 seconds, the exposure sufficiency of some first initial carrier injection layer is poor, that is, a cross-linking reaction between the first carrier injection material and the third photosensitive material has a poor sufficiency, resulting in incompleteness of the first light-emitting pattern.

### Experiment Example 4

Forming a plurality of first light-emitting devices includes R1″ to R8″.

In R1″, a patterned first electrode layer is formed on a glass substrate base; and a material of the first electrode layer is indium tin oxide (ITO).

In R2″, a third solution is applied by spin-coating on a side of the first electrode layer away from the glass substrate base to form a first initial carrier injection layer. A spin-coating speed is 2000 rpm and a spin-coating time is 30 seconds. A solvent of the third solution is water, and solutes of the third solution are the first carrier injection material PEDOT:PSS and the third photosensitive material FBBS, where a concentration of PEDOT:PSS in the third solution is 20 mg/mL, and a concentration of FBBS in the third solution is 1 mg/mL.

In R3″, UV alignment exposure is performed on the first initial carrier injection layer for 60 seconds using a photomask, so that a material of an exposed portion of the first initial carrier injection layer is converted into a first cross-linked carrier injection material.

In R4″, a second solution is applied by spin-coating on a side of the first initial carrier injection layer away from the glass substrate base to form a first initial carrier transport layer. A spin-coating speed is 2000 rpm and a spin-coating time is 30 seconds. A solvent of the second solution is chlorobenzene, and solutes of the second solution are the first carrier transport material TFB and the second photosensitive material ethyl-1,2-bis(4-azido-2,3,5,6-tetrafluorobenzoate), where a concentration of the first carrier transport material in the second solution is 8 mg/mL, and a concentration of the second photosensitive material in the second solution is 0.1 mg/mL.

In R5″, a first solution is applied by spin-coating on a side of the first initial carrier transport layer away from the glass substrate base to form a first initial light-emitting pattern. A spin-coating speed is 2000 rpm and a spin-coating time is 30 seconds. A first solvent is octane, and solutes of the first solution are the first quantum dot material and the first photosensitive material 3,3′-[4,4′(perfluorobutane-1,4-diyl)bis(4,1-phenylene)]bis[3-(trifluoromethyl)-3H-diazirine], where a concentration of the first quantum dot material in the first solution is 20 mg/mL, and a concentration of the first photosensitive material in the first solution is 1 mg/mL. The quantum dot body of the first quantum dot material is a red quantum dot body CdSe@ZnS, and the first ligand material of the first quantum dot material is oleic acid.

In R6″, UV alignment exposure is performed on the first initial carrier transport layer and the first initial light-emitting pattern that are stacked for 5 seconds using a photomask, so that a material of an exposed portion of the first initial carrier transport layer is converted into a first cross-linked carrier transport material, and a material of an exposed portion of the first initial light-emitting pattern is converted into a first cross-linked light-emitting material.

In R7″, the first initial carrier injection layer, the first initial carrier transport layer and the first initial light-emitting pattern that are stacked are developed to form a first carrier injection layer, a first carrier transport layer and a first light-emitting pattern that are stacked. Development is performed in two steps, where a developer in the first step of development is toluene, and a developer in the second step of development is water.

In R8″, a second electrode is formed by evaporation on a side of the first light-emitting pattern away from the glass substrate base; and the second electrode is an aluminium electrode.

A lighting test is performed on the plurality of first light-emitting devices formed in this Experimental Example, and the results are shown in FIG. 21. It can be seen from FIG. 21 that, some first light-emitting devices are incomplete after being lit up, such as the first light-emitting device shown in the upper left corner of the figure (i.e., a region J in FIG. 21). This is because after the concentration of the second photosensitive material in the second solution is reduced to 0.1 mg/mL, the exposure sufficiency of some first initial carrier transport layer is poor, that is, a cross-linking reaction between the first carrier transport material and the second photosensitive material has a poor sufficiency, so that a retention rate of the first carrier transport layer is affected, and a lighting effect of some first light-emitting device is further affected.

### Experiment Example 5

Forming a plurality of second light-emitting devices includes Q1 to Q8.

In Q1, a patterned first electrode layer is formed on a glass substrate base; and a material of the first electrode layer is indium tin oxide (ITO).

In Q2, a sixth solution is applied by spin-coating on a side of the first electrode layer away from the glass substrate base to form a second initial carrier injection layer. A spin-coating speed is 2000 rpm and a spin-coating time is 30 seconds. A solvent of the sixth solution is water, and solutes of the sixth solution are the second carrier injection material PEDOT:PSS and the sixth photosensitive material FBBS, where a concentration of PEDOT:PSS in the sixth solution is 20 mg/mL, and a concentration of FBBS in the sixth solution is 1 mg/mL.

In Q3, UV alignment exposure is performed on the second initial carrier injection layer for 60 seconds using a photomask, so that a material of an exposed portion of the second initial carrier injection layer is converted into a second cross-linked carrier injection material.

In Q4, a fifth solution is applied by spin-coating on a side of the second initial carrier injection layer away from the glass substrate base to form a second initial carrier transport layer. A spin-coating speed is 2000 rpm and a spin-coating time is 30 seconds. A solvent of the fifth solution is chlorobenzene, and solutes of the fifth solution are the second carrier transport material TFB and the fifth photosensitive material ethyl-1,2-bis(4-azido-2,3,5,6-tetrafluorobenzoate), where a concentration of the second carrier transport material in the fifth solution is 8 mg/mL, and a concentration of the fifth photosensitive material in the fifth solution is 0.2 mg/mL.

In Q5, a fourth solution is applied by spin-coating on a side of the second initial carrier transport layer away from the glass substrate base to form a second initial light-emitting pattern. A spin-coating speed is 2000 rpm and a spin-coating time is 30 seconds. A fourth solvent is octane, and solutes of the fourth solution are the second quantum dot material and the fourth photosensitive material 3,3′-[4,4′(perfluorobutane-1,4-diyl)bis(4,1-phenylene)]bis[3-(trifluoromethyl)-3H-diazirine], where a concentration of the second quantum dot material in the fourth solution is 20 mg/mL, and a concentration of the fourth photosensitive material in the fourth solution is 1 mg/mL. The quantum dot body of the second quantum dot material is a green quantum dot body CdSe@ZnSe, and the first ligand material of the second quantum dot material is oleic acid.

In Q6, UV alignment exposure is performed on the second initial carrier transport layer and the second initial light-emitting pattern that are stacked for 5 seconds using a photomask, so that a material of an exposed portion of the second initial carrier transport layer is converted into a second cross-linked carrier transport material, and a material of an exposed portion of the second initial light-emitting pattern is converted into a second cross-linked light-emitting material.

In Q7, the second initial carrier injection layer, the second initial carrier transport layer and the second initial light-emitting pattern that are stacked are developed to form a second carrier injection layer, a second carrier transport layer and a second light-emitting pattern that are stacked. Development is performed in two steps, where a developer in the first step of development is toluene, and a developer in the second step of development is water.

In Q8, a second electrode is formed by evaporation on a side of the second light-emitting pattern away from the glass substrate base; and the second electrode is an aluminium electrode.

The plurality of second light-emitting devices 202 formed in this Experimental Example are observed using a fluorescence microscope, the green quantum dot material has no residue in a region other than a region where the plurality of second light-emitting devices 202 are located, that is, the green quantum dot material has no residue in the unexposed region.

### Experiment Example 6

Forming a plurality of third light-emitting devices includes K1 to K8.

In K1, a patterned first electrode layer is formed on a glass substrate base; and a material of the first electrode layer is indium tin oxide (ITO).

In K2, a ninth solution is applied by spin-coating on a side of the first electrode layer away from the glass substrate base to form a third carrier injection layer. A spin-coating speed is 2000 rpm and a spin-coating time is 30 seconds. A solvent of the ninth solution is water, and solutes of the ninth solution are the third carrier injection material PEDOT:PSS and the ninth photosensitive material FBBS, where a concentration of PEDOT:PSS in the ninth solution is 20 mg/mL, and a concentration of FBBS in the ninth solution is 1 mg/mL.

In K3, UV alignment exposure is performed on the third initial carrier injection layer for 60 seconds using a photomask, so that a material of an exposed portion of the third initial carrier injection layer is converted into a third cross-linked carrier injection material.

In K4, an eighth solution is applied by spin-coating on a side of the third initial carrier injection layer away from the glass substrate base to form a third initial carrier transport layer. A spin-coating speed is 2000 rpm and a spin-coating time is 30 seconds. A solvent of the eighth solution is chlorobenzene, and solutes of the eighth solution are the third carrier transport material TFB and the eighth photosensitive material ethyl-1,2-bis(4-azido-2,3,5,6-tetrafluorobenzoate), where a concentration of the third carrier transport material in the eighth solution is 8 mg/mL, and a concentration of the eighth photosensitive material in the eighth solution is 0.2 mg/mL.

In K5, a seventh solution is applied by spin-coating on a side of the third initial carrier transport layer away from the glass substrate base to form a third initial light-emitting pattern. A spin-coating speed is 2000 rpm and a spin-coating time is 30 seconds. A seventh solvent is octane, and solutes of the seventh solution are the third quantum dot material and the seventh photosensitive material 3,3′-[4,4′(perfluorobutane-1,4-diyl)bis(4,1-phenylene)]bis[3-(trifluoromethyl)-3H-diazirine], where a concentration of the third quantum dot material in the seventh solution is 20 mg/mL, and a concentration of the seventh photosensitive material in the seventh solution is 1 mg/mL. The quantum dot body of the third quantum dot material is a blue quantum dot body ZnCdSe@ZnS, and the first ligand material of the third quantum dot material is oleic acid.

In K6, UV alignment exposure is performed on the third initial carrier transport layer and the third initial light-emitting pattern that are stacked for 5 seconds using a photomask, so that a material of an exposed portion of the third initial carrier transport layer is converted into a third cross-linked carrier transport material, and a material of an exposed portion of the third initial light-emitting pattern is converted into a third cross-linked light-emitting material.

In K7, the third initial carrier injection layer, the third initial carrier transport layer and the third initial light-emitting pattern that are stacked are developed to form a third carrier injection layer, a third carrier transport layer and a third light-emitting pattern that are stacked. Development is performed in two steps, where a developer in the first step of development is toluene, and a developer in the second step of development is water.

In K8, a second electrode is formed by evaporation on a side of the third light-emitting pattern away from the glass substrate base; and the second electrode is an aluminium electrode.

The plurality of third light-emitting devices 203 formed in this Experimental Example are observed using a fluorescence microscope, the blue quantum dot material has no residue in a region other than a region where the plurality of third light-emitting devices 203 are located, that is, the blue quantum dot material has no residue in the unexposed region.

### Experiment Example 7

Forming electroluminescent full-color patterned QLED light-emitting devices includes U1 to U21.

In U1, a patterned first electrode layer is formed on a glass substrate base; and a material of the first electrode layer is indium tin oxide (ITO). The glass substrate base with the first electrode layer is cleaned with deionized water and isopropanol, and then treated with a plasma cleaner under ultraviolet and ozone conditions for 15 minutes.

In U2, a third solution is applied by spin-coating on a side of the first electrode layer away from the glass substrate base to form a first initial carrier injection layer. A spin-coating speed is 2000 rpm and a spin-coating time is 30 seconds. A solvent of the third solution is water, and solutes of the third solution are the first carrier injection material PEDOT:PSS and the third photosensitive material FBBS, where a concentration of PEDOT:PSS in the third solution is 20 mg/mL, and a concentration of FBBS in the third solution is 1 mg/mL.

In U3, UV alignment exposure is performed on the first initial carrier injection layer for 5 minutes using a photomask, so that a material of an exposed portion of the first initial carrier injection layer is converted into a first cross-linked carrier injection material.

In U4, a second solution is applied by spin-coating on a side of the first initial carrier injection layer away from the glass substrate base to form a first initial carrier transport layer. A spin-coating speed is 2000 rpm and a spin-coating time is 30 seconds. A solvent of the second solution is chlorobenzene, and solutes of the second solution are the first carrier transport material TFB and the second photosensitive material ethyl-1,2-bis(4-azido-2,3,5,6-tetrafluorobenzoate), where a concentration of the first carrier transport material in the second solution is 8 mg/mL, and a concentration of the second photosensitive material in the second solution is 0.2 mg/mL.

In U5, a first solution is applied by spin-coating on a side of the first initial carrier transport layer away from the glass substrate base to form a first initial light-emitting pattern. A spin-coating speed is 2000 rpm and a spin-coating time is 30 seconds. A first solvent is octane, and solutes of the first solution are the first quantum dot material and the first photosensitive material 3,3′-[4,4′(perfluorobutane-1,4-diyl)bis(4,1-phenylene)]bis[3-(trifluoromethyl)-3H-diazirine], where a concentration of the first quantum dot material in the first solution is 20 mg/ml, and a concentration of the first photosensitive material in the first solution is 1 mg/mL. The quantum dot body of the first quantum dot material is a red quantum dot body CdSe@ZnS, and the first ligand material of the first quantum dot material is oleic acid.

In U6, UV alignment exposure is performed on the first initial carrier transport layer and the first initial light-emitting pattern that are stacked for 3 seconds using a photomask, so that a material of an exposed portion of the first initial carrier transport layer is converted into a first cross-linked carrier transport material, and a material of an exposed portion of the first initial light-emitting pattern is converted into a first cross-linked light-emitting material.

In U7, the first initial carrier injection layer, the first initial carrier transport layer and the first initial light-emitting pattern that are stacked are developed to form a first carrier injection layer, a first carrier transport layer and a first light-emitting pattern that are stacked. Development is performed in two steps, where a developer in the first step of development is toluene, and a developer in the second step of development is water.

In U8, a sixth solution is applied by spin-coating on a side of the first electrode layer and the plurality of first light-emitting devices away from the glass substrate base to form a second initial carrier injection layer. A spin-coating speed is 2000 rpm and a spin-coating time is 30 seconds. A solvent of the sixth solution is water, and solutes of the sixth solution are the second carrier injection material PEDOT:PSS and the sixth photosensitive material FBBS, where a concentration of PEDOT:PSS in the sixth solution is 20 mg/mL, and a concentration of FBBS in the sixth solution is 1 mg/mL.

In U9, UV alignment exposure is performed on the second initial carrier injection layer for 5 minutes using a photomask, so that a material of an exposed portion of the second initial carrier injection layer is converted into a second cross-linked carrier injection material.

In U10, a fifth solution is applied by spin-coating on a side of the second initial carrier injection layer away from the glass substrate base to form a second initial carrier transport layer. A spin-coating speed is 2000 rpm and a spin-coating time is 30 seconds. A solvent of the fifth solution is chlorobenzene, and solutes of the fifth solution are the second carrier transport material TFB and the fifth photosensitive material ethyl-1,2-bis(4-azido-2,3,5,6-tetrafluorobenzoate), where a concentration of the second carrier transport material in the fifth solution is 8 mg/mL, and a concentration of the fifth photosensitive material in the fifth solution is 0.2 mg/mL.

In U11, a fourth solution is applied by spin-coating on a side of the second initial carrier transport layer away from the glass substrate base to form a second initial light-emitting pattern. A spin-coating speed is 2000 rpm and a spin-coating time is 30 seconds. A fourth solvent is octane, and solutes of the fourth solution are the second quantum dot material and the fourth photosensitive material 3,3′-[4,4′(perfluorobutane-1,4-diyl)bis(4,1-phenylene)]bis[3-(trifluoromethyl)-3H-diazirine], where a concentration of the second quantum dot material in the fourth solution is 20 mg/mL, and a concentration of the fourth photosensitive material in the fourth solution is 1 mg/mL. The quantum dot body of the second quantum dot material is a green quantum dot body CdSe@ZnSe, and the first ligand material of the second quantum dot material is oleic acid.

In U12, UV alignment exposure is performed on the second initial carrier transport layer and the second initial light-emitting pattern that are stacked for 3 seconds using a photomask, so that a material of an exposed portion of the second initial carrier transport layer is converted into a second cross-linked carrier transport material, and a material of an exposed portion of the second initial light-emitting pattern is converted into a second cross-linked light-emitting material.

In U13, the second initial carrier injection layer, the second initial carrier transport layer and the second initial light-emitting pattern that are stacked are developed to form a second carrier injection layer, a second carrier transport layer and a second light-emitting pattern that are stacked. Development is performed in two steps, where a developer in the first step of development is toluene, and a developer in the second step of development is water.

In U14, a ninth solution is applied by spin-coating on a side of the first electrode layer, the plurality of first light-emitting devices and the plurality of second light-emitting devices away from the glass substrate base to form a third initial carrier injection layer. A spin-coating speed is 2000 rpm and a spin-coating time is 30 seconds. A solvent of the ninth solution is water, and solutes of the ninth solution are the third carrier injection material PEDOT:PSS and the ninth photosensitive material FBBS, where a concentration of PEDOT:PSS in the ninth solution is 20 mg/mL, and a concentration of FBBS in the ninth solution is 1 mg/mL.

In U15, UV alignment exposure is performed on the third initial carrier injection layer for 5 minutes using a photomask, so that a material of an exposed portion of the third initial carrier injection layer is converted into a third cross-linked carrier injection material.

In U16, an eighth solution is applied by spin-coating on a side of the third initial carrier injection layer away from the glass substrate base to form a third initial carrier transport layer. A spin-coating speed is 2000 rpm and a spin-coating time is 30 seconds. A solvent of the eighth solution is chlorobenzene, and solutes of the eighth solution are the third carrier transport material TFB and the eighth photosensitive material ethyl-1,2-bis(4-azido-2,3,5,6-tetrafluorobenzoate), where a concentration of the third carrier transport material in the eighth solution is 8 mg/mL, and a concentration of the eighth photosensitive material in the eighth solution is 0.2 mg/mL.

In U17, a seventh solution is applied by spin-coating on a side of the third initial carrier transport layer away from the glass substrate base to form a third initial light-emitting pattern. A spin-coating speed is 2000 rpm and a spin-coating time is 30 seconds. A seventh solvent is octane, and solutes of the seventh solution are the third quantum dot material and the seventh photosensitive material 3,3′-[4,4′(perfluorobutane-1,4-diyl)bis(4,1-phenylene)]bis[3-(trifluoromethyl)-3H-diazirine], where a concentration of the third quantum dot material in the seventh solution is 20 mg/mL, and a concentration of the seventh photosensitive material in the seventh solution is 1 mg/mL. The quantum dot body of the third quantum dot material is a blue quantum dot body ZnCdSe@ZnS, and the first ligand material of the third quantum dot material is oleic acid.

In U18, UV alignment exposure is performed on the third initial carrier transport layer and the third initial light-emitting pattern that are stacked for 3 seconds using a photomask, so that a material of an exposed portion of the third initial carrier transport layer is converted into a third cross-linked carrier transport material, and a material of an exposed portion of the third initial light-emitting pattern is converted into a third cross-linked light-emitting material.

In U19, the third initial carrier injection layer, the third initial carrier transport layer and the third initial light-emitting pattern that are stacked are developed to form a third carrier injection layer, a third carrier transport layer and a third light-emitting pattern that are stacked. Development is performed in two steps, where a developer in the first step of development is toluene, and a developer in the second step of development is water.

In U20, a second electrode is formed, which includes: applying ethanol solution of zinc oxide nanoparticles with a concentration of 30 mg/mL by spin-coating in a glove box at a spin-coating speed of 3000 rpm for a spin-coating time of 30 seconds, performing baking at 120 °C for 10 minutes to remove the solvent; and forming an aluminium electrode with a thickness of 120 nm by evaporation.

In U21, adhesive dispensing packaging is performed.

After U7, the first light-emitting device and film layer(s) in the unexposed region (i.e., the film layer(s) in an opening region corresponding to the second light-emitting device and the third light-emitting device) are conductive using a test substrate to perform an electroluminescence test. The specific method is as follows.

A temporary second electrode is provided on a side of each first light-emitting device (i.e., the red light-emitting device) away from the substrate, and voltages are applied through the first electrode and the second electrode to enable the plurality of first light-emitting devices to emit light. The applied voltage is 5V, the light-emitting conditions of the plurality of first light-emitting devices are tested to obtain an electroluminescence fluorescence microscope photo, and the fluorescence microscope photo is processed to obtain the result shown in FIG. 22. It can be seen from FIG. 22 that light exit from regions corresponding to the first light-emitting devices 201 has a consistent color, which indicates that the light emitted by the first light-emitting devices 201 has a high purity.

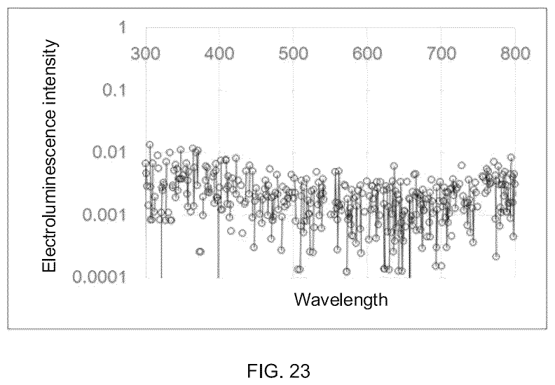

A temporary second electrode is provided on a side of a film layer (the first electrode and the first initial residual pattern that may be formed during formation of the first light-emitting device) in an unexposed region away from the substrate, and a voltage is applied to the film layer in the unexposed region to make the film layer conductive. The applied voltage is 5V, and an electroluminescence intensity of the film layer in the unexposed region is tested at different wavelengths to obtain a change curve of electroluminescence intensities of the film layer in the unexposed region at different wavelengths shown in FIG. 23. It will be noted that a horizontal axis of each circle in FIG. 23 represents a test wavelength, and a vertical axis thereof represents an electroluminescence intensity corresponding to the test wavelength. It can be seen from FIG. 23 that an average of the electroluminescence intensities of the film layer in the unexposed region at different wavelengths is less than 0.01, which indicates that there is basically no red quantum dot emission peak in the unexposed region, that is, the first quantum dot material has no residue in the unexposed region.

### Experiment Example 8

The electroluminescent full-color patterned QLED light-emitting devices are formed by referring to the above method U1 to U21. In addition to the exposure time of the initial carrier injection layer and the exposure time of the initial carrier transport layer and the initial light-emitting pattern, the manufacturing conditions are the same as those in Experimental Example 7.

It will be noted that the manufacturing conditions described here include but are not limited to process methods, materials, concentrations, solvents, exposure time, and developing solvents.

In this Experimental Example, the initial carrier injection layer includes a first initial carrier injection layer, a second initial carrier injection layer and a third initial carrier injection layer, and the exposure time of the initial carrier injection layer is 60 seconds. The initial carrier transport layer includes a first initial carrier transport layer, a second initial carrier transport layer and a third initial carrier transport layer, the initial light-emitting pattern includes a first initial light-emitting pattern, a second initial light-emitting pattern and a third initial light-emitting pattern, and the exposure time of the initial carrier transport layer and the initial light-emitting pattern is 5 seconds.

### Experiment Example 9

Forming electroluminescent full-color patterned QLED light-emitting devices includes T1 to T17.

In T1, a patterned first electrode layer is formed on a glass substrate base; and a material of the first electrode layer is indium tin oxide (ITO). The glass substrate base with the first electrode layer is cleaned with deionized water and isopropanol, and then treated with a plasma cleaner under ultraviolet and ozone conditions for 15 minutes.

In T2, a third solution is applied by spin-coating on a side of the first electrode layer away from the glass substrate base to form a first initial carrier injection layer. A spin-coating speed is 2000 rpm and a spin-coating time is 30 seconds. A solvent of the third solution is water, and solutes of the third solution are the first carrier injection material PEDOT:PSS and the third photosensitive material FBBS, where a concentration of PEDOT:PSS in the third solution is 20 mg/mL, and a concentration of FBBS in the third solution is 1 mg/mL.

In In T3, UV alignment exposure is performed on the first initial carrier injection layer for 60 seconds using a photomask, so that a material of an exposed portion of the first initial carrier injection layer is converted into a first cross-linked carrier injection material.

In T4, a second solution is applied by spin-coating on a side of the first initial carrier injection layer away from the glass substrate base to form a first initial carrier transport layer. A spin-coating speed is 2000 rpm and a spin-coating time is 30 seconds. A solvent of the second solution is chlorobenzene, and solutes of the second solution are the first carrier transport material TFB and the second photosensitive material ethyl-1,2-bis(4-azido-2,3,5,6-tetrafluorobenzoate), where a concentration of the first carrier transport material in the second solution is 8 mg/mL, and a concentration of the second photosensitive material in the second solution is 0.2 mg/mL.

In T5, a first solution is applied by spin-coating on a side of the first initial carrier transport layer away from the glass substrate base to form a first initial light-emitting pattern. A spin-coating speed is 2000 rpm and a spin-coating time is 30 seconds. A first solvent is octane, and solutes of the first solution are the first quantum dot material and the first photosensitive material ethylene glycol di(3-benzoylbenzoate), where a concentration of the first quantum dot material in the first solution is 20 mg/ml, and a concentration of the first photosensitive material in the first solution is 1 mg/mL. The quantum dot body of the first quantum dot material is a red quantum dot body CdSe@ZnS, and the first ligand material of the first quantum dot material is oleic acid.

In T6, UV alignment exposure is performed on the first initial carrier transport layer and the first initial light-emitting pattern that are stacked for 5 seconds using a photomask, so that a material of an exposed portion of the first initial carrier transport layer is converted into a first cross-linked carrier transport material, and a material of an exposed portion of the first initial light-emitting pattern is converted into a first cross-linked light-emitting material.

In T7, the first initial carrier injection layer, the first initial carrier transport layer and the first initial light-emitting pattern that are stacked are developed to form a first carrier injection layer, a first carrier transport layer and a first light-emitting pattern that are stacked. Development is performed in two steps, where a developer in the first step of development is toluene, and a developer in the second step of development is water.

In T8, a fifth solution is applied by spin-coating on a side of the first electrode layer and the plurality of first light-emitting devices away from the glass substrate base to form a second initial carrier transport layer. A spin-coating speed is 2000 rpm and a spin-coating time is 30 seconds. A solvent of the fifth solution is chlorobenzene, and solutes of the fifth solution are the second carrier transport material TFB and the fifth photosensitive material ethyl-1,2-bis(4-azido-2,3,5,6-tetrafluorobenzoate), where a concentration of the second carrier transport material in the fifth solution is 8 mg/mL, and a concentration of the fifth photosensitive material in the fifth solution is 0.2 mg/mL.

In T9, a fourth solution is applied by spin-coating on a side of the second initial carrier transport layer away from the glass substrate base to form a second initial light-emitting pattern. A spin-coating speed is 2000 rpm and a spin-coating time is 30 seconds. A fourth solvent is octane, and solutes of the fourth solution are the second quantum dot material and the fourth photosensitive material ethylene glycol di(3-benzoylbenzoate), where a concentration of the second quantum dot material in the fourth solution is 20 mg/mL, and a concentration of the fourth photosensitive material in the fourth solution is 1 mg/ml. The quantum dot body of the second quantum dot material is a green quantum dot body CdSe@ZnSe, and the first ligand material of the second quantum dot material is oleic acid.

In T10, UV alignment exposure is performed on the second initial carrier transport layer and the second initial light-emitting pattern that are stacked for 5 seconds using a photomask, so that a material of an exposed portion of the second initial carrier transport layer is converted into a second cross-linked carrier transport material, and a material of an exposed portion of the second initial light-emitting pattern is converted into a second cross-linked light-emitting material.

In T11, the second initial carrier transport layer and the second initial light-emitting pattern that are stacked are developed to form a second carrier transport layer and a second light-emitting pattern that are stacked. Development is performed in two steps, where a developer in the first step of development is toluene, and a developer in the second step of development is water.

In T12, an eighth solution is applied by spin-coating on a side of the first electrode layer, the plurality of first light-emitting devices and the plurality of second light-emitting devices away from the glass substrate base to form a third initial carrier transport layer. A spin-coating speed is 2000 rpm and a spin-coating time is 30 seconds. A solvent of the eighth solution is water, and solutes of the eighth solution are the third carrier transport material TFB and the eighth photosensitive material ethyl-1,2-bis(4-azido-2,3,5,6-tetrafluorobenzoate), where a concentration of the third carrier transport material in the eighth solution is 8 mg/mL, and a concentration of the eighth photosensitive material in the eighth solution is 0.2 mg/mL.

In T13, a seventh solution is applied by spin-coating on a side of the third initial carrier transport layer away from the glass substrate base to form a third initial light-emitting pattern. A spin-coating speed is 2000 rpm and a spin-coating time is 30 seconds. A seventh solvent is octane, and solutes of the seventh solution are the third quantum dot material and the seventh photosensitive material ethylene glycol di(3-benzoylbenzoate), where a concentration of the third quantum dot material in the seventh solution is 20 mg/mL, and a concentration of the seventh photosensitive material in the seventh solution is 1 mg/mL. The quantum dot body of the third quantum dot material is a blue quantum dot body ZnCdSe@ZnS, and the first ligand material of the third quantum dot material is oleic acid.

In T14, UV alignment exposure is performed on the third initial carrier transport layer and the third initial light-emitting pattern that are stacked for 5 seconds using a photomask, so that a material of an exposed portion of the third initial carrier transport layer is converted into a third cross-linked carrier transport material, and a material of an exposed portion of the third initial light-emitting pattern is converted into a third cross-linked light-emitting material.

In T15, the third initial carrier transport layer and the third initial light-emitting pattern that are stacked are developed to form a third carrier transport layer and a third light-emitting pattern that are stacked. Development is performed in two steps, where a developer in the first step of development is toluene, and a developer in the second step of development is water.

In T16, a second electrode is formed, which includes: applying ethanol solution of zinc oxide nanoparticles with a concentration of 30 mg/mL by spin-coating in a glove box at a spin-coating speed of 3000 rpm for a spin-coating time of 30 seconds, performing baking at 120 °C for 10 minutes to remove the solvent; and forming an aluminium electrode with a thickness of 120 nm by evaporation.

In T17, adhesive dispensing packaging is performed.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting substrate comprising:
a substrate; and
a plurality of light-emitting devices disposed on the substrate and arranged in a first direction, the first direction being parallel to a plane where the substrate is located, and each light-emitting device in the plurality of light-emitting devices including a first electrode, a second electrode, and a light-emitting pattern disposed between the first electrode and the second electrode, wherein
the plurality of light-emitting devices include at least one first light-emitting device, each first light-emitting device in the at least one first light-emitting device includes a first light-emitting pattern, and a first carrier transport layer and a first carrier injection layer that are disposed between the substrate and the first light-emitting pattern; and the first carrier transport layer is closer to the first light-emitting pattern than the first carrier injection layer; and
a material of the first light-emitting pattern includes a first cross-linked light-emitting material; a material of the first carrier transport layer includes a first cross-linked carrier transport material; and a material of the first carrier injection layer includes a first cross-linked carrier injection material.

2. The light-emitting substrate according to claim 1, wherein the plurality of light-emitting devices further include:
at least one second light-emitting device; each second light-emitting device in the at least one second light-emitting device including a second light-emitting pattern, and a second sacrificial layer group disposed between the substrate and the second light-emitting pattern; wherein
the second sacrificial layer group includes a second carrier transport layer; a material of the second light-emitting pattern includes a second cross-linked light-emitting material; and a material of the second carrier transport layer includes a second cross-linked carrier transport material; or
the second sacrificial layer group includes a second carrier transport layer and a second carrier injection layer, and the second carrier injection layer is located on a side of the second carrier transport layer proximate to the substrate; a material of the second light-emitting pattern includes a second cross-linked light-emitting material; a material of the second carrier transport layer includes a second crossed-linked carrier transport material; and a material of the second carrier injection layer includes a second cross-linked carrier injection material.

3. (canceled)

4. The light-emitting substrate according to claim 2, wherein the plurality of light-emitting devices further include:
at least one third light-emitting device; each third light-emitting device in the at least one third light-emitting device including a third light-emitting pattern, and a third sacrificial layer group disposed between the substrate and the third light-emitting pattern; wherein
the third sacrificial layer group includes a third carrier transport layer; a material of the third light-emitting pattern includes a third cross-linked light-emitting material; and a material of the third carrier transport layer includes a third cross-linked carrier transport material; or
the third sacrificial layer group includes a third carrier transport layer and a third carrier injection layer, and the third carrier injection layer is located on a side of the third carrier transport layer proximate to the substrate; a material of the third light-emitting pattern includes a third cross-linked light-emitting material; a material of the third carrier transport layer includes a third crossed-linked carrier transport material; and a material of the third carrier injection layer includes a third cross-linked carrier injection material.

5. (canceled)

6. The light-emitting substrate according to claim 1, wherein the first cross-linked light-emitting material is generated by cross-linking of a first quantum dot material under light radiation, and a solubility of the first quantum dot material in a first solvent is greater than a solubility of the first cross-linked light-emitting material in the first solvent; or the first cross-linked light-emitting material is generated by cross-linking of a first quantum dot material and a first photosensitive material under light radiation, and solubilities of the first quantum dot material and the first photosensitive material in a first solvent are greater than a solubility of the first cross-linked light-emitting material in the first solvent;
the first cross-linked carrier transport material is generated by cross-linking of a first carrier transport material under light radiation, and a solubility of the first carrier transport material in a second solvent is greater than a solubility of the first cross-linked carrier transport material in the second solvent; or the first cross-linked carrier transport material is generated by cross-linking of a first carrier transport material and a second photosensitive material under light radiation, and solubilities of the first carrier transport material and the second photosensitive material in a second solvent are greater than a solubility of the first cross-linked carrier transport material in the second solvent; and
the first cross-linked carrier injection material is generated by cross-linking of a first carrier injection material under light radiation, and a solubility of the first carrier injection material in a third solvent is greater than a solubility of the first cross-linked carrier injection material in the third solvent; or the first cross-linked carrier injection material is generated by cross-linking of a first carrier injection material and a third photosensitive material under light radiation, and solubilities of the first carrier injection material and the third photosensitive material in a third solvent are greater than a solubility of the first cross-linked carrier injection material in the third solvent.

7. The light-emitting substrate according to claim 2, wherein the second cross-linked light-emitting material is generated by cross-linking of a second quantum dot material under light radiation, and a solubility of the second quantum dot material in a fourth solvent is greater than a solubility of the second cross-linked light-emitting material in the fourth solvent; or the second cross-linked light-emitting material is generated by cross-linking of a second quantum dot material and a fourth photosensitive material under light radiation, and solubilities of the second quantum dot material and the fourth photosensitive material in a fourth solvent are greater than a solubility of the second cross-linked light-emitting material in the fourth solvent;
the second cross-linked carrier transport material is generated by cross-linking of a second carrier transport material under light radiation, and a solubility of the second carrier transport material in a fifth solvent is greater than a solubility of the second cross-linked carrier transport material in the fifth solvent; or the second cross-linked carrier transport material is generated by cross-linking of a second carrier transport material and a fifth photosensitive material under light radiation, and solubilities of the second carrier transport material and the fifth photosensitive material in a fifth solvent are greater than a solubility of the second cross-linked carrier transport material in the fifth solvent; and
in a case where the second sacrificial layer group includes the second carrier injection layer, the second cross-linked carrier injection material is generated by cross-linking of a second carrier injection material under light radiation, and a solubility of the second carrier injection material in a sixth solvent is greater than a solubility of the second cross-linked carrier injection material in the sixth solvent, or the second cross-linked carrier injection material is generated by cross-linking of a second carrier injection material and a sixth photosensitive material under light radiation, and solubilities of the second carrier injection material and the sixth photosensitive material in a sixth solvent are greater than a solubility of the second cross-linked carrier injection material in the sixth solvent.

8. (canceled)

9. The light-emitting substrate according to claim 4, wherein the third cross-linked light-emitting material is generated by cross-linking of a third quantum dot material under light radiation, and a solubility of the third quantum dot material in a seventh solvent is greater than a solubility of the third cross-linked light-emitting material in the seventh solvent; or the third cross-linked light-emitting material is generated by cross-linking of a third quantum dot material and a seventh photosensitive material under light radiation, and solubilities of the third quantum dot material and the seventh photosensitive material in a seventh solvent are greater than a solubility of the third cross-linked light-emitting material in the seventh solvent;
the third cross-linked carrier transport material is generated by cross-linking of a third carrier transport material under light radiation, and a solubility of the third carrier transport material in an eighth solvent is greater than a solubility of the third cross-linked carrier transport material in the eighth solvent; or the third cross-linked carrier transport material is generated by cross-linking of a third carrier transport material and an eighth photosensitive material under light radiation, and solubilities of the third carrier transport material and the eighth photosensitive material in an eighth solvent are greater than a solubility of the third cross-linked carrier transport material in the eighth solvent; and
in a case where the third sacrificial layer group includes the third carrier injection layer, the third cross-linked carrier injection material is generated by cross-linking of a third carrier injection material under light radiation, and a solubility of the third carrier injection material in a ninth solvent is greater than a solubility of the third cross-linked carrier injection material in the ninth solvent, or the third cross-linked carrier injection material is generated by cross-linking of a third carrier injection material and a ninth photosensitive material under light radiation, and solubilities of the third carrier injection material and the ninth photosensitive material in a ninth solvent are greater than a solubility of the third cross-linked carrier injection material in the ninth solvent.

10. (canceled)

11. The light-emitting substrate according to claim 4, wherein the at least one first light-emitting device is configured to emit light of a first wavelength; and
each first light-emitting device in the at least one first light-emitting device further includes a first pattern layer and a second pattern layer, the first pattern layer is disposed on a side of the first light-emitting pattern away from the substrate, the second pattern layer is disposed on a side of the first pattern layer away from the substrate, and the first light-emitting pattern, the first pattern layer and the second pattern layer are in contact in sequence.

12. The light-emitting substrate according to claim 11,
wherein in a case where the second sacrificial layer group includes the second carrier transport layer, a thickness of the first pattern layer is less than a thickness of the second carrier transport layer; and the second cross-linked carrier transport material is generated by cross-linking of a second carrier transport material under light radiation, a material of the first pattern layer includes the second carrier transport material; or the second cross-linked carrier transport material is generated by cross-linking of a second carrier transport material and a fifth photosensitive material under light radiation, a material of the first pattern layer includes the second carrier transport material and the fifth photosensitive material; or
in a case where the second sacrificial layer group includes the second carrier transport layer and the second carrier injection layer, a thickness of the first pattern layer is less than a thickness of the second carrier injection layer; and the second cross-linked carrier injection material is generated by cross-linking of a second carrier injection material under light radiation, a material of the first pattern layer includes the second carrier injection material; or the second cross-linked carrier injection material is generated by cross-linking of a second carrier injection material and a sixth photosensitive material under light radiation, a material of the first pattern layer includes the second carrier injection material and the sixth photosensitive material;
in a case where the third sacrificial layer group includes the third carrier transport layer, a thickness of the second pattern layer is less than a thickness of the third carrier transport layer; and the third cross-linked carrier transport material is generated by cross-linking of a third carrier transport material under light radiation, a material of the second pattern layer includes the thirds carrier transport material; or the third cross-linked carrier transport material is generated by cross-linking of a third carrier transport material and an eighth photosensitive material under light radiation, a material of the second pattern layer includes the third carrier transport material and the eighth photosensitive material; or
in a case where the third sacrificial layer group includes the third carrier transport layer and the third carrier injection layer, a thickness of the second pattern layer is less than a thickness of the third carrier injection layer; and the third cross-linked carrier injection material is generated by cross-linking of a third carrier injection material under light radiation, a material of the second pattern layer includes the third carrier injection material; or the third cross-linked carrier injection material is generated by cross-linking of a third carrier injection material and a ninth photosensitive material under light radiation, a material of the second pattern layer includes the third carrier injection material and the ninth photosensitive material.

13. (canceled)

14. The light-emitting substrate according to claim 4, wherein the at least one second light-emitting device is configured to emit light of a second wavelength; and
each second light-emitting device in the at least one second light-emitting device further includes a third pattern layer and a fourth pattern layer, the third pattern layer is disposed on a side of the second sacrificial layer group proximate to the substrate, the fourth pattern layer is disposed on a side of the second light-emitting pattern away from the substrate, and the third pattern layer, the second sacrificial layer group, the second light-emitting pattern and the fourth pattern layer are in contact in sequence.

15. The light-emitting substrate according to claim 14, wherein a thickness of the third pattern layer is less than a thickness of the first carrier injection layer; and a material of the third pattern layer includes the first cross-linked carrier injection material;
in a case where the third sacrificial layer group includes the third carrier transport layer, a thickness of the fourth pattern layer is less than a thickness of the third carrier transport layer; and the third cross-linked carrier transport material is generated by cross-linking of a third carrier transport material under light radiation, a material of the fourth pattern layer includes the third carrier transport material; or the third cross-linked carrier transport material is generated by cross-linking of a third carrier transport material and an eighth photosensitive material under light radiation, a material of the fourth pattern layer includes the third carrier transport material and the eighth photosensitive material; or
in a case where the third sacrificial layer group includes the third carrier transport layer and the third carrier injection layer, a thickness of the fourth pattern layer is less than a thickness of the third carrier injection layer; and the third cross-linked carrier injection material is generated by cross-linking of a third carrier injection material under light radiation, a material of the fourth pattern layer includes the third carrier injection material; or the third cross-linked carrier injection material is generated by cross-linking of a third carrier injection material and a ninth photosensitive material under light radiation, a material of the fourth pattern layer includes the third carrier injection material and the ninth photosensitive material.

16. The light-emitting substrate according to claim 4, wherein the at least one third light-emitting device is configured to emit light of a third wavelength; and
each third light-emitting device in the at least one third light-emitting device further includes a fifth pattern layer and a sixth pattern layer, the sixth pattern layer is disposed on a side of the third sacrificial layer group proximate to the substrate, the fifth pattern layer is disposed on a side of the sixth pattern layer proximate to the substrate, and the third sacrificial layer group, the sixth pattern layer and the fifth pattern layer are in contact in sequence.

17. The light-emitting substrate according to claim 16, wherein a thickness of the fifth pattern layer is less than a thickness of the first carrier injection layer; and a material of the fifth pattern layer includes the first cross-linked carrier injection material;
in a case where the second sacrificial layer group includes the second carrier transport layer, a thickness of the sixth pattern layer is less than a thickness of the second carrier transport layer; and a material of the sixth pattern layer includes the second cross-linked carrier transport material; or
in a case where the second sacrificial layer group includes the second carrier transport layer and the second carrier injection layer, a thickness of the sixth pattern layer is less than a thickness of the second carrier injection layer; and a material of the sixth pattern layer includes the second cross-linked carrier injection material.

18. (canceled)

19. The light-emitting substrate according to claim 4, further comprising a pixel defining layer, wherein the pixel defining layer is provided with a plurality of openings therein, and the plurality of light-emitting devices are disposed in the plurality of openings in one-to-one correspondence; and
the light-emitting substrate further comprises a seventh pattern layer, an eighth pattern layer and a ninth pattern layer that are disposed on a side of the pixel defining layer away from the substrate; the seventh pattern layer, the eighth pattern layer and the ninth pattern layer are disposed sequentially in a direction from the substrate to the pixel defining layer, and the seventh pattern layer, the eighth pattern layer and the ninth pattern layer are in contact in sequence.

20-21. (canceled)

22. The light-emitting substrate according to claim 4, wherein any of the first cross-linked light-emitting material, the second cross-linked light-emitting material and the third cross-linked light-emitting material includes any of structures shown in a following general formula (I-A); 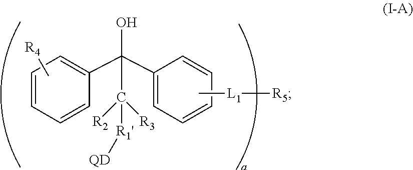
or
any of the first cross-linked light-emitting material, the second cross-linked light-emitting material and the third cross-linked light-emitting material includes any of structures shown in a following general formula (I-B); 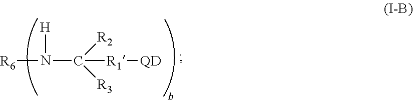
or
any of the first cross-linked light-emitting material, the second cross-linked light-emitting material and the third cross-linked light-emitting material includes any of structures shown in a following general formula (I-C); 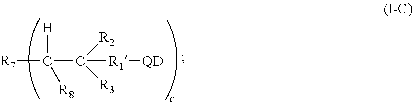
wherein L₁ is selected from any of a single bond, an ester bond, an ether bond and a thioether bond;
R₂, R₃, R₄, R₅, R₆, R₇ and R₈ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40;
QD represents any of quantum dot bodies, and the quantum dot bodies each include any of a II-VI group quantum dot, a III-V group quantum dot, a IV-VI group quantum dot, a quantum dot with core-shell structure and an ABX₃ type perovskite quantum dot; in the ABX₃ type perovskite quantum dot, A is one or more of CH₃NH₃⁺ (methylamine), NH₂CH═NH₂ (formamidine) and Cs⁺, B is one or two of Pb²⁺ and Sn²⁺, and X is one or more of Cl⁻, Br⁻ and I⁻;
and the ABX₃ type perovskite quantum dot includes CH₃NH₃PbBr₃, CH₃NH₃PbCl₃, CH₃NH₃PbI₃, CsPbBr₃, CsPbCl₃ and CsPbI₃;
R1′ is selected from a remaining structure of R₁ with one hydrogen removed from any of a carboxyl group, an amino group and a sulfhydryl group; R₁ is selected from any of a C1 to C40 carbon chain with a carboxyl group, a C1 to C40 carbon chain with an amino group, and a C1 to C40 carbon chain with a sulfhydryl group; and any of the carboxyl group, the amino group and the sulfhydryl group is connected to a quantum dot body by coordination; and
a, b and c are each independently selected from positive integers greater than or equal to 2.

23. The light-emitting substrate according to claim 4, wherein any of the first cross-linked carrier transport material, the second cross-linked carrier transport material and the third cross-linked carrier transport material includes any of structures shown in a following general formula (II-A); 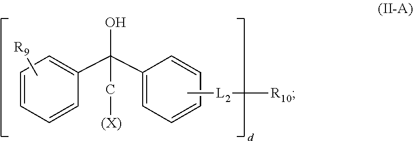
or
any of the first cross-linked carrier transport material, the second cross-linked carrier transport material and the third cross-linked carrier transport material includes any of structures shown in a following general formula (II-B); 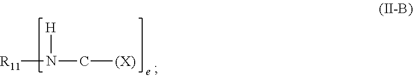
or
any of the first cross-linked carrier transport material, the second cross-linked carrier transport material and the third cross-linked carrier transport material includes any of structures shown in a following general formula (II-C); 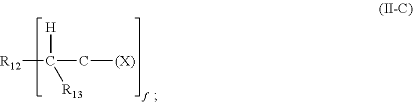
wherein L₂ is selected from any of a single bond, an ester bond, an ether bond and a thioether bond;
R₉, R₁₀, R₁₁, R₁₂ and R₁₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40;
X represents a remaining structure of any of a first carrier transport material, a second carrier transport material and a third carrier transport material with a C—H bond removed; the C—H bond is used to undergo a cross-linking reaction with a second photosensitive group of a second type of photosensitive material under light radiation, and the second type of photosensitive material is one of a second photosensitive material, a fifth photosensitive material and an eighth photosensitive material; and
d, e and f are each independently selected from positive integers greater than or equal to 2.

24. The light-emitting substrate according to claim 4, wherein any of the first cross-linked carrier injection material, the second cross-linked carrier injection material and the third cross-linked carrier injection material includes any of structures shown in a following general formula (III-A); 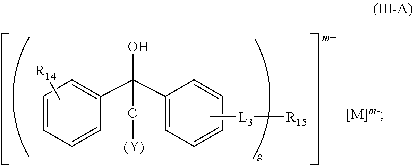
or
any of the first cross-linked carrier injection material, the second cross-linked carrier injection material and the third cross-linked carrier injection material includes any of structures shown in a following general formula (III-B); 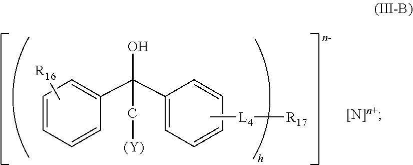
or
any of the first cross-linked carrier injection material, the second cross-linked carrier injection material and the third cross-linked carrier injection material includes any of structures shown in a following general formula (III-C); 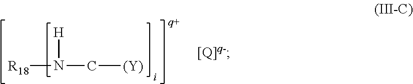
or
any of the first cross-linked carrier injection material, the second cross-linked carrier injection material and the third cross-linked carrier injection material includes any of structures shown in a following general formula (III-D); 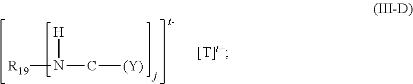
or
any of the first cross-linked carrier injection material, the second cross-linked carrier injection material and the third cross-linked carrier injection material includes any of structures shown in a following general formula (III-E); 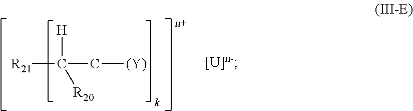
or
any of the first cross-linked carrier injection material, the second cross-linked carrier injection material and the third cross-linked carrier injection material includes any of structures shown in a following general formula (III-F); 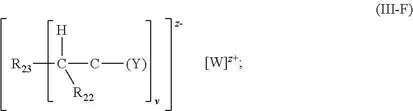
wherein L₃ and L₄ are each independently selected from any of a single bond, an ester bond, an ether bond and a thioether bond;
R₁₄, R₁₅, R₁₆, R₁₇, R₁₈, R₁₉, R₂₀, R₂₁, R₂₂ and R₂₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40;
Y represents a remaining structure of any of a first carrier injection material, a second carrier injection material and a third carrier injection material with a C—H bond removed;
the C—H bond is used to undergo a cross-linking reaction with a third photosensitive group of a third type of photosensitive material under light radiation, and the third type of photosensitive material is one of a third photosensitive material, a sixth photosensitive material and a ninth photosensitive material;
[M]^{m-}, [Q]^{q-} and [U]^{u-} are each independently selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions;
[N]ⁿ⁺, [T]^{t+} and [W]^{z+} are each independently selected from any of organic cations and inorganic cations; the organic cations include methylammonium ions; and the inorganic cations include sodium ions and potassium ions;
g, h, i, j, k and v are each independently selected from positive integers greater than or equal to 2; and
m, n, q, t, u and z are each independently selected from positive integers greater than or equal to 1.

25. The light-emitting substrate according to claim 2, wherein a first photosensitive material, a fourth photosensitive material and a seventh photosensitive material are each independently selected from any of first type of photosensitive materials; a first type of photosensitive material includes a first photosensitive group, the first photosensitive group undergoes a cross-linking reaction with a quantum dot material under light radiation; and the quantum dot material is one of a first quantum dot material, a second quantum dot material and a third quantum dot material;
a second photosensitive material, a fifth photosensitive material and a eighth photosensitive material are each independently selected from any of second type of photosensitive materials; a second type of photosensitive material includes a second photosensitive group, the second photosensitive group undergoes a cross-linking reaction with a carrier transport material under light radiation; and the carrier transport material is one of a first carrier transport material, a second carrier transport material and a third carrier transport material;
a third photosensitive material, a sixth photosensitive material and a ninth photosensitive material are each independently selected from any of third type of photosensitive materials; a third type of photosensitive material includes a third photosensitive group, the third photosensitive group undergoes a cross-linking reaction with a carrier injection material under light radiation; and the carrier injection material is one of a first carrier injection material, a second carrier injection material and a third carrier injection material; and
any two of the first photosensitive group, the second photosensitive group and the third photosensitive group are same or different.

26. (canceled)

27. The light-emitting substrate according to claim 25, wherein the first type of photosensitive material is selected from any of structures shown in a following general formula (IV-A); 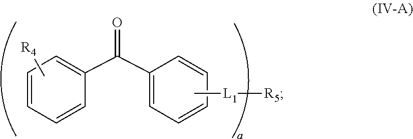
or
the first type of photosensitive material is selected from any of structures shown in a following general formula (IV-B); 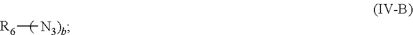
or
the first type of photosensitive material is selected from any of structures shown in a following general formula; 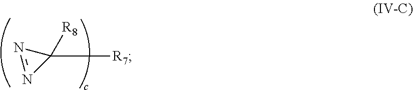
wherein in the general formula (IV-A), a benzophenone group is the first photosensitive group; in the general formula (IV-B), an azide group is the first photosensitive group; in the general formula (IV-C), a diazirine group is the first photosensitive group;
L₁ is selected from any of a single bond, an ester bond, an ether bond and a thioether bond;
R₂, R₃, R₄, R₅, R₆, R₇ and R₈ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40; and
a, b and c are each independently selected from positive integers greater than or equal to 2;
and/or
the second type of photosensitive material is selected from any of structures shown in a following general formula (V-A); 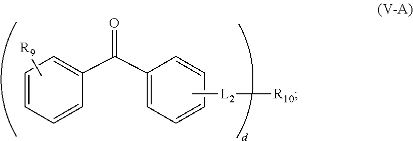
or
the second type of photosensitive material is selected from any of structures shown in a following general formula (V-B); 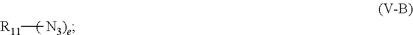
or
the second type of photosensitive material is selected from any of structures shown in a following general formula (V-C); 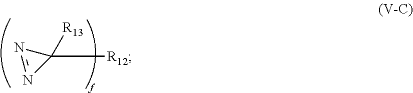
wherein in the general formula (V-A), a benzophenone group is the second photosensitive group; in the general formula (V-B), an azide group is the second photosensitive group; in the general formula (V-C), a diazirine group is the second photosensitive group;
L₂ is selected from any of a single bond, an ester bond, an ether bond and a thioether bond;
R₉, R₁₀, R₁₁, R₁₂ and R₁₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40;
d, e and f are each independently selected from positive integers greater than or equal to 2;
and/or
the third type of photosensitive material is selected from any of structures shown in a following general formula (VI-A); 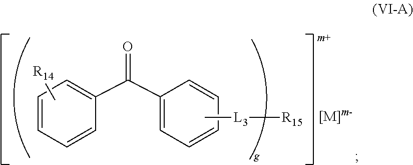
or
the third type of photosensitive material is selected from any of structures shown in a following general formula (VI-B); 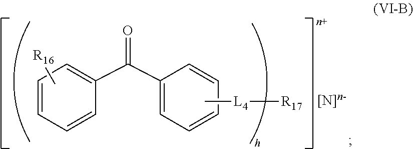
or
the third type of photosensitive material is selected from any of structures shown in a following general formula (VI-C); 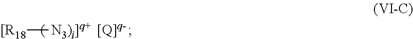
or
the third type of photosensitive material is selected from any of structures shown in a following general formula (VI-D); 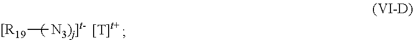
or
the third type of photosensitive material is selected from any of structures shown in a following general formula (VI-E); 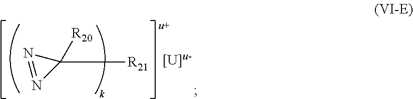
or
the third type of photosensitive material is selected from any of structures shown in a following general formula (VI-F); 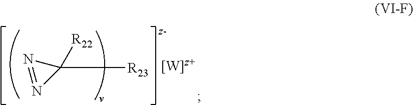
wherein in the general formula (VI-A) and the general formula (VI-B), a benzophenone group is the third photosensitive group; in the general formula (VI-C) and the general formula (VI-D), an azide group is the third photosensitive group; in the general formula (VI-E) and the general formula (VI-F), a diazirine group is the third photosensitive group;
L₃ and L₄ are each independently selected from any of a single bond, an ester bond, an ether bond and a thioether bond;
R₁₄, R₁₅, R₁₆, R₁₇, R₁₈, R₁₉, R₂₀, R₂₁, R₂₂ and R₂₃ are each independently selected from any of a hydrogen bond, a saturated or unsaturated straight or branched alkyl group with C1 to C40, a cycloalkyl group with C3 to C40, a heterocycloalkyl group with C3 to C40, an aryl group with C6 to C40, and a heteroaryl group with C6 to C40;
[M]^{m-}, [Q]^{q-} and [U]^{u-} are each independently selected from any of organic anions and inorganic anions; the organic anions include benzenesulfonate ions, salicylate ions and 3-hydroxy-2-naphthoic acid radical ions; and the inorganic anions include chloride ions, sulfate ions and nitrate ions;
[N]ⁿ⁺, [T]^{t+} and [W]^{z+} are each independently selected from any of organic cations and inorganic cations; the organic cations include methylammonium ions; and the inorganic cations include sodium ions and potassium ions;
g, h, i, j, k and v are each independently selected from positive integers greater than or equal to 2; and
m, n, q, t, u and z are each independently selected from positive integers greater than or equal to 1.

28-30. (canceled)

31. The light-emitting substrate according to claim 25, wherein any of the first quantum dot material, the second quantum dot material and the third quantum dot material includes a quantum dot body and a first ligand material coordinated on the quantum dot body; the first ligand material contains a carbon-hydrogen insertion group ZH; and the carbon-hydrogen insertion group ZH is configured to undergo a carbon-hydrogen insertion reaction with the first photosensitive group under light radiation; and/or
any of the first carrier transport material, the second carrier transport material and the third carrier transport material includes a carbon-hydrogen insertion group ZH; and the carbon-hydrogen insertion group ZH is configured to undergo a carbon-hydrogen insertion reaction with the second photosensitive group under light radiation; and/or
any of the first carrier injection material, the second carrier injection material and the third carrier injection material includes a carbon-hydrogen insertion group ZH; and the carbon-hydrogen insertion group ZH is configured to undergo a carbon-hydrogen insertion reaction with the third photosensitive group under light radiation; wherein
in the carbon-hydrogen insertion group ZH, Z is any of primary carbon, secondary carbon and tertiary carbon.

32-41. (canceled)

42. A light-emitting apparatus, comprising the light-emitting substrate according to claim 1, and a driver chip used for driving the light-emitting substrate to emit light.
